(19) United States
(12) Patent Application Publication
(10) Pub. No.: US 2026/0113979 A1
(43) Pub. Date: Apr. 23, 2026

(54) DEVICE, SEMICONDUCTOR DEVICE, AND METHOD FOR MANUFACTURING SEMICONDUCTOR DEVICE

(71) Applicant: SEMICONDUCTOR ENERGY LABORATORY CO., LTD., Atsugi-shi (JP)

(72) Inventors: Sachiaki TEZUKA, Atsugi (JP); Hiromi SAWAI, Kawasaki (JP)

(21) Appl. No.: 19/353,730

(22) Filed: Oct. 9, 2025

(30) Foreign Application Priority Data
Oct. 18, 2024 (JP) 2024-184255

(51) Int. Cl. H10D 30/67; G11C 11/401; H01L 23/00; H10B 12/00; H10D 1/68; H10D 30/01

(52) U.S. Cl. CPC H10D 30/6728; H10D 1/714; H10D 1/716; H10D 30/0312; H10D 30/0318; H10D 30/6706; H10D 30/6731; H10D 30/6736; H10D 30/6757; G11C 11/401; H10B 12/33; H10B 12/50; H10W 90/792

(57) ABSTRACT

A capacitor with large capacitance, a transistor with excellent electrical characteristics, a transistor with high on-state current, or a transistor with small parasitic capacitance is provided. A device includes a first insulating layer, a first conductive layer over the first insulating layer, a second insulating layer over the first insulating layer and the first conductive layer, and a capacitor over the first conductive layer. The second insulating layer includes an opening portion that reaches the first conductive layer and includes a narrowed upper portion. A lower electrode, an upper electrode, and a dielectric of the capacitor each include a portion positioned in the opening portion. The lower electrode includes a portion in contact with the top surface of the first conductive layer and a portion provided along the opening portion.

### BACKGROUND OF THE INVENTION

### 1. Field of the Invention

One embodiment of the present invention relates to a device, a semiconductor device, a memory device, a display device, and an electronic device. One embodiment of the present invention also relates to a method for manufacturing the semiconductor device.

Note that one embodiment of the present invention is not limited to the above technical field. Examples of the technical field of one embodiment of the present invention include a device, a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### 2. Description of the Related Art

A technique by which a transistor is formed over an insulating surface has been attracting attention. The transistor is used in a wide range of electronic devices such as an integrated circuit (IC) and a display device. A silicon-based semiconductor material is widely known as a material of a semiconductor thin film that can be used in a transistor. As another material, an oxide semiconductor has been attracting attention.

A transistor using an oxide semiconductor is known to have extremely low leakage current in a non-conduction state. For example, Patent Document 1 discloses a low-power CPU utilizing a characteristic of low leakage current. Furthermore, for example, Patent Document 2 discloses a memory device that can retain stored data for a long time.

Furthermore, the use of In₂O₃ for a thin film transistor has been reported (Non-Patent Document 1).

Examples of an oxide semiconductor that can be used for an active layer of a transistor include indium oxide and indium gallium zinc oxide. Non-Patent Document 2 discloses a thin film transistor in which hydrogenated polycrystal indium oxide formed by low-temperature solid phase crystallization is used for an active layer.

### REFERENCES

### Patent Documents

[Patent Document 1] Japanese Published Patent Application No. 2012-257187
[Patent Document 2] Japanese Published Patent Application No. 2011-151383

### Non-Patent Documents

[Non-Patent Document 1] Dhananjay & Chu, C. W. Realization of In₂O₃ thin film transistors through reactive evaporation process. Appl. Phys. Lett. 91, 1-4(2007)
[Non-Patent Document 2] Y. Magari et al., “High-mobility hydrogenated polycrystalline In₂O₃(In₂O₃:H) thin-film transistors”, Nature Communications 13, 1078, (2022).
[Non-Patent Document 3] Takashi Koida, “High-mobility transparent conductive film”, National Institute of Advanced Industrial Science and Technology, AIST Photovoltaic Technology Research Symposium 2019, Internet URL:https://unit.aist.go.jp/rpd-envene/PV/ja/results/2019/oral/T13.pdf

### SUMMARY OF THE INVENTION

An object of one embodiment of the present invention is to provide a capacitor with large capacitance. An object of one embodiment of the present invention is to provide a capacitor with excellent electrical characteristics. An object of one embodiment of the present invention is to provide a device including a capacitor with large capacitance. An object of one embodiment of the present invention is to provide a device with excellent electrical characteristics. An object of one embodiment of the present invention is to provide a transistor with excellent electrical characteristics. An object of one embodiment of the present invention is to provide a transistor with high on-state current. An object of one embodiment of the present invention is to provide a transistor with small parasitic capacitance. An object of one embodiment of the present invention is to provide a highly reliable capacitor, device, transistor, semiconductor device, memory device, or display device. An object of one embodiment of the present invention is to provide a transistor, a semiconductor device, or a memory device which can be miniaturized or highly integrated. An object of one embodiment of the present invention is to provide a semiconductor device, a memory device, or a display device with low power consumption. An object of one embodiment of the present invention is to provide a memory device with high operating speed. An object of one embodiment of the present invention is to provide a display device with a high resolution or a high aperture ratio. An object of one embodiment of the present invention is to provide a method for manufacturing the above-described transistor, semiconductor device, memory device, or display device.

Note that the description of these objects does not preclude the existence of other objects. One embodiment of the present invention does not necessarily achieve all of these objects. Other objects can be derived from the description of the specification, the drawings, and the claims.

One embodiment of the present invention is a device including a first insulating layer, a first conductive layer over the first insulating layer, a second insulating layer over the first insulating layer and the first conductive layer, and a capacitor over the first conductive layer. The capacitor includes a second conductive layer, a third insulating layer, and a third conductive layer. The second insulating layer includes an opening portion reaching the first conductive layer and comprising a narrowed upper portion. The second insulating layer includes a first portion protruding inward from the opening portion in the upper portion of the opening portion. The second conductive layer includes a second portion in contact with a top surface of the first conductive layer, a third portion in contact with a side surface of the opening portion in the second insulating layer, and a fourth portion in contact with a bottom surface of the first portion. The third insulating layer includes, in the opening portion, a fifth portion in contact with the third portion of the second conductive layer and a sixth portion in contact with the fourth portion. The third conductive layer includes a portion positioned in the opening portion. The fifth portion and the sixth portion of the third insulating layer are sandwiched between the second conductive layer and the third conductive layer.

In the above embodiment, it is preferable that the second insulating layer have a stacked-layer structure of a first layer and a second layer over the first layer, that a width of the opening portion be larger in the first layer than in the second layer, and that the second layer include the first portion of the second insulating layer.

In the above embodiment, it is preferable that the first layer contain silicon oxide and the second layer contain silicon nitride.

In the above embodiment, it is preferable that a lower portion of the opening portion be narrowed; the second insulating layer include a seventh portion protruding inward from the opening portion in the lower portion of the opening portion; that the second insulating layer have a stacked-layer structure of a first layer, a second layer over the first layer, and a third layer over the second layer; that a width of the opening portion be larger in the second layer than in the first layer and the third layer; that the third layer include the first portion of the second insulating layer; and that the first layer include the seventh portion of the second insulating layer.

In the above embodiment, it is preferable that the second layer contain silicon oxide and the first layer and the third layer each contain silicon nitride.

One embodiment of the present invention is a semiconductor device including a first insulating layer, a transistor over the first insulating layer, and a second insulating layer over the first insulating layer. The transistor includes a first conductive layer over the first insulating layer, a semiconductor layer, a second conductive layer over the second insulating layer, a third insulating layer, and a third conductive layer. The second insulating layer includes a first opening portion reaching the first conductive layer and including a narrowed upper portion and lower portion. The second conductive layer includes a second opening portion overlapping with the first opening portion in a plan view. The second insulating layer includes a first portion protruding inward from the first opening portion in the upper portion of the first opening portion and a second portion protruding inward from the first opening portion in the lower portion of the first opening portion. The semiconductor layer includes a third portion in contact with a top surface of the first conductive layer, a fourth portion in contact with a side surface of the first opening portion in the second insulating layer, a fifth portion in contact with a bottom surface of the first portion, a sixth portion in contact with a top surface of the second portion, and a seventh portion in contact with a side surface of the second opening portion in the second conductive layer. The third insulating layer includes a portion in contact with the semiconductor layer in the first opening portion. The third conductive layer includes, in the first opening portion, a portion facing the semiconductor layer with the third insulating layer therebetween. The second conductive layer has a stacked-layer structure of a first layer and a second layer over the first layer. The first layer includes one or more of a metal, an alloy of the metal, and a metal nitride. The second layer contains an oxide.

In the above embodiment, it is preferable that the second insulating layer have a stacked-layer structure of a third layer, a fourth layer over the third layer, and a fifth layer over the fourth layer; that a width of the first opening portion be larger in the fourth layer than in the third layer and the fifth layer; that the fifth layer include the first portion of the second insulating layer; and that the third layer include the second portion of the second insulating layer.

In the above embodiment, it is preferable that the fourth layer contain silicon oxide and the third layer and the fifth layer each contain silicon nitride.

One embodiment of the present invention is a method for manufacturing a semiconductor device, the method including the steps of forming a first conductive layer over a first insulating layer; forming a second insulating layer, a third insulating layer, and a fourth insulating layer sequentially over the first insulating layer and the first conductive layer; forming a second conductive layer over the fourth insulating layer; forming an opening portion reaching the first conductive layer with use of first etching treatment in the second conductive layer, the fourth insulating layer, the third insulating layer, and the second insulating layer; performing etching of the third insulating layer with use of second etching treatment such that a width of the opening portion is larger in the third insulating layer than in the second insulating layer and the fourth insulating layer; forming a semiconductor layer; forming a fifth insulating layer over the semiconductor layer; and forming a third conductive layer over the fifth insulating layer. The first etching treatment is anisotropic. The second etching treatment is isotropic.

In the above embodiment, it is preferable that the first etching treatment be dry etching treatment and the second etching treatment be wet etching treatment.

With one embodiment of the present invention, a capacitor with large capacitance can be provided. With one embodiment of the present invention, a capacitor with excellent electrical characteristics can be provided. With one embodiment of the present invention, a device including a capacitor with large capacitance can be provided. With one embodiment of the present invention, a device with excellent electrical characteristics can be provided. With one embodiment of the present invention, a transistor with excellent electrical characteristics can be provided. With one embodiment of the present invention, a transistor with high on-state current can be provided. With one embodiment of the present invention, a transistor with small parasitic capacitance can be provided. With one embodiment of the present invention, a highly reliable capacitor, device, transistor, semiconductor device, memory device, or display device can be provided. With one embodiment of the present invention, a transistor, a semiconductor device, or a memory device which can be miniaturized or highly integrated can be provided. With one embodiment of the present invention, a semiconductor device, a memory device, or a display device with low power consumption can be provided. With one embodiment of the present invention, a memory device with high operating speed can be provided. With one embodiment of the present invention, a display device with a high resolution or a high aperture ratio can be provided. With one embodiment of the present invention, a method for manufacturing the above-described transistor, semiconductor device, memory device, or display device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device, and FIGS. 1B to 1D are cross-sectional views illustrating examples of the semiconductor device;

FIGS. 2A and 2B are cross-sectional views illustrating examples of a semiconductor device;

FIGS. 3A and 3B are cross-sectional views illustrating examples of a semiconductor device;

FIG. 4 is a cross-sectional view illustrating an example of a semiconductor device;

FIG. 5A is a plan view illustrating an example of a semiconductor device, and FIG. 5B is a cross-sectional view illustrating the example of the semiconductor device;

FIGS. 6A and 6B are cross-sectional views illustrating an example of a semiconductor device;

FIG. 7A is a plan view illustrating an example of a semiconductor device, and FIG. 7B is a cross-sectional view illustrating the example of the semiconductor device;

FIG. 8 is a cross-sectional view illustrating an example of a semiconductor device;

FIGS. 9A and 9B are cross-sectional views illustrating examples of a semiconductor device;

FIGS. 10A and 10B are cross-sectional views illustrating examples of a semiconductor device;

FIG. 11 is a cross-sectional view illustrating an example of a semiconductor device;

FIG. 12 is a cross-sectional view illustrating an example of a semiconductor device;

FIG. 13 is a cross-sectional view illustrating an example of a semiconductor device;

FIGS. 14A and 14B are cross-sectional views showing an example of a method for manufacturing a semiconductor device;

FIGS. 15A and 15B are cross-sectional views showing the example of the method for manufacturing the semiconductor device;

FIG. 16 is a cross-sectional view showing the example of the method for manufacturing the semiconductor device;

FIGS. 17A and 17B are cross-sectional views illustrating examples of a semiconductor device;

FIGS. 18A and 18B illustrate a structure example of a memory device;

FIGS. 19A and 19B illustrate a structure example of a memory device;

FIG. 20 illustrates a structure example of a memory device;

FIG. 21 is a block diagram showing a structure example of a semiconductor device;

FIGS. 22A to 22H each illustrate a circuit structure example of a memory cell;

FIGS. 23A to 23C are perspective views of a semiconductor device;

FIGS. 24A and 24B are perspective views of a semiconductor device;

FIG. 25 is a perspective view of a semiconductor device;

FIGS. 26A and 26B illustrate examples of electronic components;

FIGS. 27A to 27C illustrate an example of a large computer, FIG. 27D illustrates an example of a device for space, and FIG. 27E illustrates an example of a storage system that can be used in a data center;

FIGS. 28A and 28B each show carrier concentration dependence of Hall mobility, and FIG. 28C is a cross-sectional view illustrating an indium oxide film;

FIGS. 29A and 29B show a cross-sectional STEM image;

FIGS. 30A and 30B show a cross-sectional STEM image;

FIGS. 31A and 31B show a cross-sectional STEM image;

FIGS. 32A and 32B show a cross-sectional STEM image; and

FIGS. 33A and 33B show a cross-sectional STEM image.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of current or voltage, a switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an OS transistor. In this specification and the like, a transistor including silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as Vo) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The contents of elements such as hydrogen, oxygen, carbon, and nitrogen in a film can be analyzed by secondary ion mass spectrometry (SIMS) or X-ray photoelectron spectroscopy (XPS), for example. Note that XPS is suitable when the content percentage of a target element is high (e.g., 0.5 atomic % or higher, or 1 atomic % or higher). By contrast, SIMS is suitable when the content percentage of a target element is low (e.g., 0.5 atomic % or lower, or 1 atomic % or lower). To compare the contents of elements, analysis with a combination of SIMS and XPS is preferably used.

Note that in this specification and the like, the term “content percentage” refers to the proportion of a component contained in a film. In the case where an oxide semiconductor layer contains a metal element X, a metal element Y, and a metal element Z whose atomic numbers are respectively represented by A_{X}, A_{Y}, and A_{Z}, the content percentage of the metal element X can be represented by A_{X}/(A_{X}+A_{Y}+A_{Z}). Moreover, in the case where the atomic ratio between the metal element X, the metal element Y, and the metal element Z contained in an oxide semiconductor layer is represented by B_{X}: B_{Y}: B_{Z}, the content percentage of the metal element X can be represented by B_{X}/(B_{X}+B_{Y}+B_{Z}).

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 70° and less than or equal to 110°.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

Note that in this specification and the like, a tapered shape refers to a shape in which at least part of a side surface of a component is inclined with respect to a substrate surface or a formation surface of the component. For example, a tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially flat with a slight curvature or with slight unevenness.

In this specification and the like, when the expression “A is positioned over B” is used, at least part of A is positioned over B. In other words, A includes a region positioned over B, for example. Similarly, when the expression “A is in contact with B” or “A overlaps with B” is used, at least part of A is in contact with or overlaps with B. In other words, A includes a region in contact with B or A includes a region overlapping with B. Similarly, in this specification and the like, when the expression “A covers B” is used, at least part of A covers B. In other words, A includes a region covering B, for example.

In this specification and the like, a device manufactured using a metal mask or a fine metal mask (FMM, a high-resolution metal mask) may be referred to as a device having a metal mask (MM) structure. In this specification and the like, a device manufactured without using a metal mask or an FMM may be referred to as a device having a metal maskless (MML) structure.

In this specification and the like, a structure in which light-emitting layers of light-emitting elements (also referred to as light-emitting devices) having different emission wavelengths are separately formed may be referred to as a side-by-side (SBS) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the carrier-injection layer, the carrier-transport layer, and the carrier-blocking layer cannot be clearly distinguished from each other. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, one of the pair of electrodes may be referred to as a pixel electrode and the other may be referred to as a common electrode.

In this specification and the like, a sacrificial layer (which may also be referred to as a mask layer) refers to a layer that is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of its formation surface (e.g., a step).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

In this embodiment, a semiconductor device of one embodiment of the present invention and a method for manufacturing the semiconductor device will be described.

### Structure Example 1 of Semiconductor Device

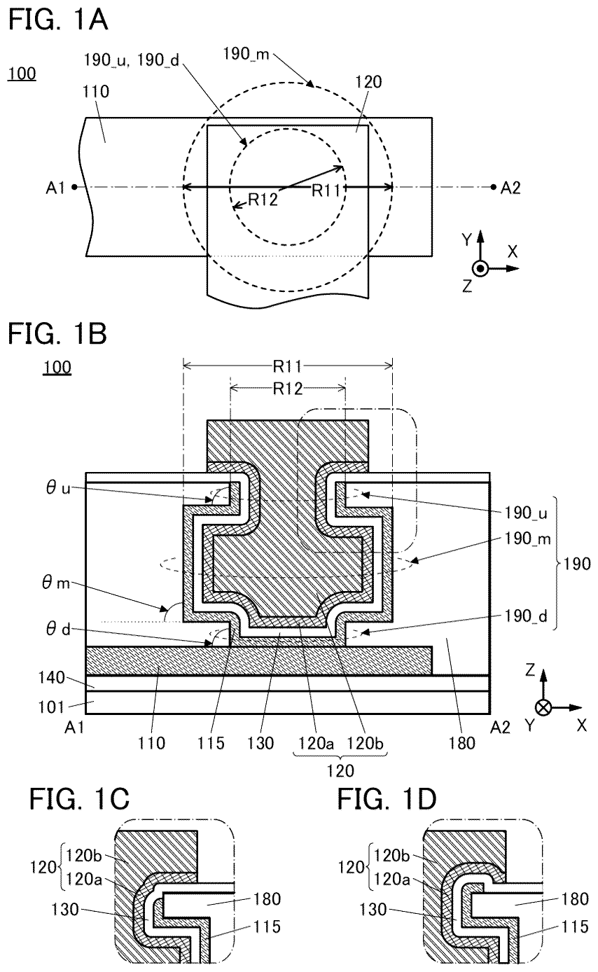

A structure of the semiconductor device of one embodiment of the present invention is described with reference to FIGS. 1A to 1D, FIGS. 2A and 2B, FIGS. 3A and 3B, and FIG. 4.

### [Capacitor 100]

FIG. 1A is a plan view of a device including a capacitor 100. FIG. 1B is a cross-sectional view taken along a dashed-dotted line A1-A2 in FIG. 1A. Note that for simplification of the drawing, some components are not illustrated in the plan view in FIG. 1A or the like. Some components may be omitted also in the following plan views.

The structure illustrated in FIGS. 1A and 1B can be referred to as a stack including a conductive layer and an insulating layer. Alternatively, the structure illustrated in FIGS. 1A and 1B can be referred to as a device including a conductive layer and an insulating layer. Alternatively, the structure illustrated in FIGS. 1A and 1B can be referred to as an electronic device including a conductive layer and an insulating layer.

Note that although the capacitor 100 is illustrated as a component in FIGS. 1A and 1B, the semiconductor device of one embodiment of the present invention can include semiconductor elements such as a transistor, a diode, and a photodiode in addition to the capacitor, and the capacitor can be used by being connected to these semiconductor elements. Thus, FIGS. 1A and 1B is referred to as a semiconductor device in some cases.

The capacitor 100 includes a conductive layer 115, an insulating layer 130, and a conductive layer 120. A conductive layer 110 is provided below the conductive layer 115. The conductive layer 115 includes a region in contact with the conductive layer 110. The conductive layer 120 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 is a metal-insulator-metal (MIM) capacitor.

The semiconductor device illustrated in FIGS. 1A and 1B includes a substrate 101, an insulating layer 140 over the substrate 101, and the capacitor 100 over the insulating layer 140. Note that the semiconductor device does not necessarily include the substrate 101.

The conductive layer 110 is provided over the insulating layer 140, and the conductive layer 115 and an insulating layer 180 are provided over the conductive layer 110.

The insulating layer 180 includes an opening portion 190 reaching the conductive layer 110. In the opening portion 190, the conductive layer 115 includes a region in contact with the top surface of the conductive layer 110 and a region in contact with a side surface of the insulating layer 180. The insulating layer 130 is placed so that at least part of the insulating layer 130 is positioned in the opening portion 190. The conductive layer 120 is placed so that at least part of the conductive layer 120 is positioned in the opening portion 190.

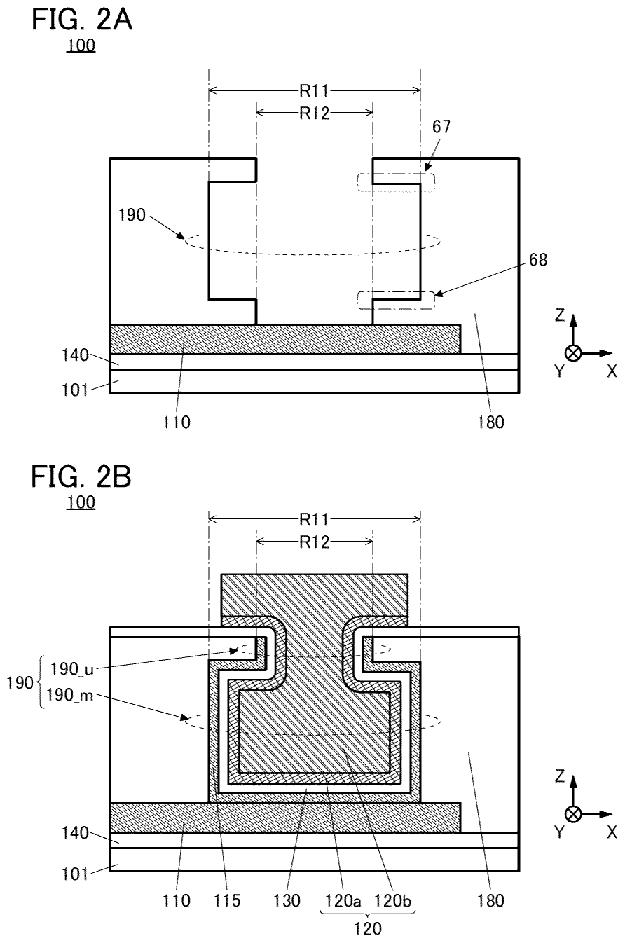

The insulating layer 140, the conductive layer 110, and the insulating layer 180 are extracted from FIG. 1B and illustrated in FIG. 2A.

The opening portion 190 has a shape whose upper portion is narrowed. In other words, the opening portion 190 has a bottleneck-like shape.

As illustrated in FIGS. 1B and 2A, a width R11 of a portion (sometimes referred to as a portion deeper than the upper portion) positioned below the narrowed upper portion of the opening portion 190 can be larger than a width R12 of the upper portion of the opening portion 190. When the width R11 is larger than the width R12, the surface area of a side surface of the opening portion 190 in the insulating layer 180 can be increased.

In the structure example illustrated in FIGS. 1B and 2A, the opening portion 190 has a shape whose upper portion and lower portion are narrowed. In FIGS. 1B and 2A, the width of the lower portion of the opening portion 190 is substantially the same as the width R12 of the upper portion of the opening portion 190. The narrowed upper portion of the opening portion 190 is referred to as an opening portion 190_u, the narrowed lower portion of the opening portion 190 is referred to as an opening portion 190_d, and a portion including a middle position between the highest position and the lowest position of the insulating layer 180 is referred to as an opening portion 190_m.

Since the upper portion and the lower portion of the opening portion 190 in the insulating layer 180 each have a narrowed shape, the insulating layer 180 includes a portion protruding to the opening portion 190 at the upper portion of the opening portion 190 and a portion protruding to the opening portion 190 at the lower portion of the opening portion 190. A region 67 illustrated in FIG. 2A is the bottom surface of the protruding portion at the upper portion of the opening portion 190, and a region 68 is the top surface of the protruding portion at the lower portion of the opening portion 190.

In the opening portion 190, the conductive layer 115 includes a portion in contact with the top surface of the conductive layer 110 and a portion in contact with the side surface of the opening portion 190 in the insulating layer 180. The conductive layer 115 is in contact with the region 67 and the region 68.

As illustrated in FIG. 1B, the width of a portion that is positioned between the upper portion and the lower portion of the opening portion 190 in the insulating layer 180 is large so that the surface area of the side surface of the opening portion 190 in the insulating layer 180 increases. Moreover, when the insulating layer 180 includes protruding portions at the upper portion and the lower portion of the opening portion, the surface area of the opening portion 190 in the insulating layer 180 increases.

Since the surface area of the opening portion 190 in the insulating layer 180 is increased, the surface area of the conductive layer 115 covering the opening portion 190 also increases. Thus, the capacitance value of the capacitor 100 can be increased.

FIGS. 1C and 1D each show a variation example of the structure illustrated in FIG. 1B; specifically show a structure example of a portion surrounded by a dashed-dotted line in FIG. 1B different from that in FIG. 1B.

Although FIG. 1B shows an example in which an upper end of the conductive layer 115 is aligned with the top surface of the insulating layer 180, when the upper end of the conductive layer 115 is lower than the upper end of the opening portion 190 in the insulating layer 180 as illustrated in FIG. 1C, electric field concentration between the conductive layer 115 and the conductive layer 120 can be reduced. Moreover, the upper end of the conductive layer 115 is rounded, whereby electric field concentration can be further reduced in some cases.

Alternatively, as illustrated in FIG. 1D, the conductive layer 115 can be provided not only in the opening portion 190 in the insulating layer 180 but also over the insulating layer 180. In FIG. 1D, the insulating layer 130 covers an end portion of the conductive layer 115 over the insulating layer 180. The conductive layer 120 covers the end portion of the conductive layer 115 with the insulating layer 130 therebetween. Over the insulating layer 180, an end portion of the conductive layer 120 is positioned outward from the end portion of the conductive layer 115 when seen from the center of the opening portion 190. In the structure illustrated in FIG. 1D, the conductive layer 115 covers the top surface of the insulating layer 180.

Note that as illustrated in FIG. 2B, a structure may be employed where only the upper portion of the opening portion 190 has a narrowed shape and the lower portion thereof does not have a narrowed shape.

The upper portion of the opening portion 190 can be rephrased as, for example, a portion above the middle position between the highest position of the insulating layer 180 and the lowest position thereof. In the insulating layer 180, the narrowed portion of the opening portion 190 can be positioned in a region within 50%, preferably in a region within 40%, further preferably in a region within 30%, still further preferably in a region within 20% of the thickness of the insulating layer 180 from the top surface of the insulating layer 180.

The lower portion of the opening portion 190 can be rephrased as, for example, a portion below the middle position between the highest position of the insulating layer 180 and the lowest position thereof. In the insulating layer 180, the narrowed portion of the opening portion 190 can be positioned in a region within 50%, preferably in a region within 40%, further preferably in a region within 30%, still further preferably in a region within 20% of the thickness of the insulating layer 180 from the bottom surface of the insulating layer 180.

An angle formed by a sidewall of the opening portion 190_u and a plane parallel to a surface of the substrate 101 is an angle θu, an angle formed by a sidewall of the opening portion 190_d and the plane parallel to the surface of the substrate 101 is an angle θd, and an angle formed by a sidewall of the opening portion 190_m and the plane parallel to the surface of the substrate 101 is an angle θm. FIG. 1B shows an example where the angle θu, the angle θd, and the angle θm are each 90°. In that case, the upper portion, the lower portion, and the portion including the middle position of the opening portion 190 each have a cylindrical shape. Here, as a plane parallel to the surface of the substrate 101, the top surface of a layer provided over the substrate 101 can be used, for example.

The angle θu, the angle θd, and the angle θm in FIG. 1B and the like are each preferably greater than or equal to 45° and less than or equal to 90°. When the angle θu is greater than or equal to 80° and less than or equal to 90°, for example, the device can be integrated. When the angle θm is less than 80°, coverage with a side surface of the opening portion 190_m of the conductive layer 115 and the like is improved in some cases.

The angle θm is sometimes greater than 90°. Also in such a case, when the conductive layer 115 and the like are formed by a film formation method that provides good coverage, the side surface of the opening portion 190_m can be favorably covered.

Since the opening portion 190 has a narrowed shape, the conductive layer 115, the insulating layer 130, and the conductive layer 120 are preferably formed by a film formation method that provides good coverage with respect to an inner wall of the opening portion 190. The conductive layer 115, the insulating layer 130, and the conductive layer 120 can be formed by an atomic layer deposition (ALD) method, for example.

The conductive layer 110 can extend to function as a wiring. FIG. 1A shows an example in which the conductive layer 110 extends in the X direction. The conductive layer 110 may be provided in a planar shape; when a plurality of capacitors 100 are arranged in a matrix in the X direction and the Y direction, the plurality of capacitors 100 can share the conductive layer 110.

The conductive layer 120 is provided in contact with part of the top surface of the insulating layer 130. In FIGS. 1B and 2B and the like, the conductive layer 120 is provided to fill the opening portion 190 and has a portion higher than the top surface of the insulating layer 180. When the conductive layer 120 extends over the insulating layer 180, the conductive layer 120 can function as a wiring. FIG. 1A shows an example in which the conductive layer 120 extends in the Y direction.

The conductive layer 110, the conductive layer 115, and the conductive layer 120 can each have a stacked-layer structure.

For example, the conductive layer 120 can have a stacked-layer structure by a combination of a film formation method that provides good coverage and a film formation method with high film formation rate and high productivity. In the example shown in FIGS. 1B and 2B and the like, the conductive layer 120 has a stacked-layer structure of a conductive layer 120a and a conductive layer 120b over the conductive layer 120a. When a film formation method that provides good coverage is used for the conductive layer 120a and a film formation method with high film formation rate is used for the conductive layer 120b, the coverage of the insulating layer 130 with the conductive layer 120 can be improved and the conductive layer 120 can be favorably embedded in the opening portion 190. When a material with high conductivity is used for the conductive layer 120b having a large thickness, the conductivity of the conductive layer 120 can be increased and thus the conductive layer 120 can be suitably used as a wiring.

The conductive layer 120a is preferably formed using a conductive material that is not easily oxidized. Thus, the conductive layer 120b can be inhibited from being oxidized by the insulating layer 130 in the case of using an oxide for the insulating layer 130.

The above-described conductive layers included in the semiconductor device of one embodiment of the present invention, such as the conductive layer 110, the conductive layer 115, and the conductive layer 120, are described.

For each of the conductive layers, it is preferable to use a metal element selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, lanthanum, and the like; an alloy containing any of the above metal elements as a component; an alloy containing a combination of the above metal elements; or the like. Alternatively, a nitride of the alloy containing any of the above metal elements as a component or an oxide of the alloy may be used. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. As examples of the conductive material containing oxygen, indium oxide containing tungsten oxide, indium oxide containing titanium oxide, indium tin oxide, indium tin oxide containing titanium oxide, indium tin oxide containing silicon (also referred to as In—Si—Sn oxide or ITSO), indium zinc oxide, indium zinc oxide containing tungsten oxide, and the like can be given. In this specification and the like, a conductive film formed using the conductive material containing oxygen may be referred to as an oxide conductive film.

A conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

A conductive material with high conductivity such as tungsten can be used for the conductive layer 110. With use of a conductive material with high conductivity, the conductivity of the conductive layer 110 can be improved and the conductive layer 110 can function adequately as a wiring.

For the conductive layer 115, a single layer or stacked layers of a conductive material that is unlikely to be oxidized, a conductive material having a function of inhibiting diffusion of oxygen, or the like is preferably used. For example, titanium nitride or ITSO can also be used. Alternatively, a structure in which titanium nitride is stacked over tungsten can be used, for example. Alternatively, a structure in which tungsten is stacked over first titanium nitride and second titanium nitride is stacked over the tungsten can be used, for example. With such a structure, when an oxide is used for the insulating layer 130, the conductive layer 110 can be inhibited from being oxidized by the insulating layer 130. When an oxide is used for the insulating layer 180, the conductive layer 110 can be inhibited from being oxidized by the insulating layer 180.

For example, one or more selected from tantalum nitride and titanium nitride can be used for the conductive layer 120a, and tungsten can be used for the conductive layer 120b.

The insulating layers included in the semiconductor device of one embodiment of the present invention, such as the insulating layer 180 and the insulating layer 130, are described.

An inorganic insulating film can be used as each of the insulating layers. Examples of the inorganic insulating film include an oxide insulating film, a nitride insulating film, an oxynitride insulating film, and a nitride oxide insulating film. Examples of a material that can be used for the oxide insulating film include oxides such as silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of a material that can be used for the nitride insulating film include nitrides such as silicon nitride and aluminum nitride. Examples of a material that can be used for the oxynitride insulating film include oxynitrides such as silicon oxynitride, aluminum oxynitride, gallium oxynitride, yttrium oxynitride, and hafnium oxynitride. Examples of a material that can be used for the nitride oxide insulating film include nitride oxides such as silicon nitride oxide and aluminum nitride oxide.

For the insulating layer 130, a material with a high relative dielectric constant (a high-k material) is preferably used. Using a high-k material for the insulating layer 130 allows the insulating layer 130 to be thick enough to inhibit leakage current and the capacitor 100 to have a sufficiently high capacitance.

The insulating layer 180 functions as an interlayer film. When a material with a low relative dielectric constant is used for the insulating layer functioning as an interlayer film, the parasitic capacitance generated between wirings can be reduced. Thus, a material is preferably selected depending on the function of an insulating layer. Note that a material with a low relative dielectric constant is a material with high dielectric strength.

Examples of the material with a high relative dielectric constant include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low relative dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of the inorganic insulating material with a low relative dielectric constant include silicon oxide containing fluorine, silicon oxide containing carbon, and silicon oxide containing carbon and nitrogen. Another example is porous silicon oxide. Note that these silicon oxides may contain nitrogen.

Alternatively, as each of the insulating layers, an organic insulating film can be used.

The insulating layer 130 can have a stacked-layer structure of a high-k material and a material with higher dielectric strength than the high-k material. For example, as the insulating layer 130, an insulating film in which zirconium oxide, aluminum oxide, and zirconium oxide are stacked in this order can be used. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The stacking of such an insulating layer with relatively high dielectric strength, such as aluminum oxide, can increase the dielectric strength and inhibit electrostatic breakdown of the capacitor 100.

Alternatively, a material that can have ferroelectricity may be used for the insulating layer 130. The detail of the material that can have ferroelectricity will be described later.

A ferroelectric refers to an insulator having a property of causing internal polarization by application of an electric field from the outside and maintaining the polarization even after the electric field is made zero. Thus, with use of a capacitor that contains this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is connected to one terminal of the ferroelectric capacitor. Thus, in the case of using a ferroelectric capacitor as the capacitor 100, the memory device described in this embodiment functions as a ferroelectric memory.

As the insulating layer 180, an insulating layer containing a material with a low relative dielectric constant is preferably used. Silicon oxide and silicon oxynitride can be suitably used because of their thermal stability. In the case where the insulating layer 180 has a stacked-layer structure, one or more selected from silicon oxide and silicon oxynitride are preferably used as one or more of the insulating layers forming the stacked-layer structure.

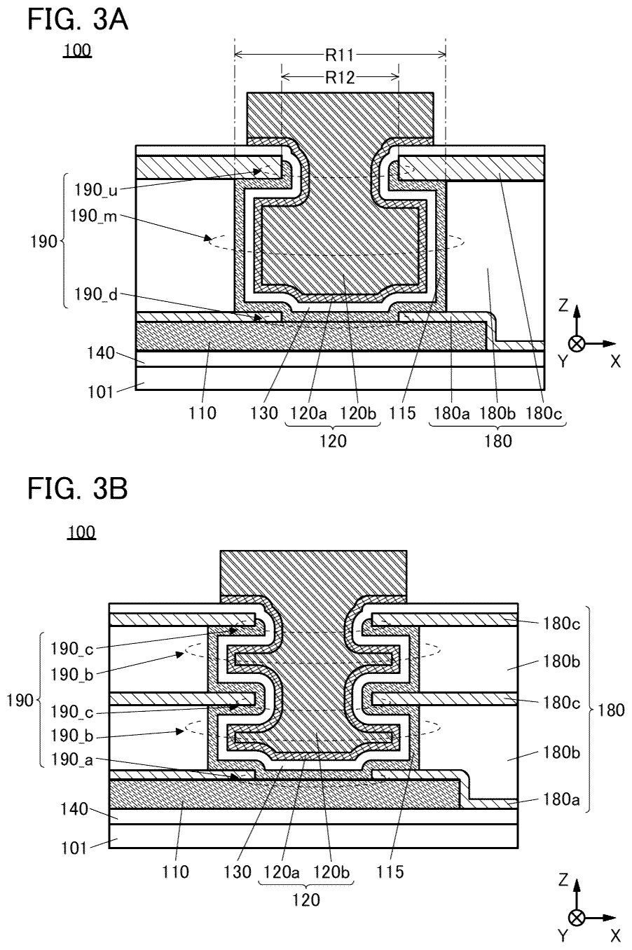

When the insulating layer 180 has a stacked-layer structure as illustrated in FIG. 3A and the like, the insulating layer 180 including a narrowed portion can be formed.

The capacitor 100 illustrated in FIG. 3A is different from the capacitor 100 illustrated in FIG. 1B mainly in that the insulating layer 180 has a stacked-layer structure of an insulating layer 180a, an insulating layer 180b over the insulating layer 180a, and an insulating layer 180c over the insulating layer 180b. The width of the opening portion 190 in the insulating layer 180b is preferably larger than the width of the opening portion 190 in the insulating layer 180a. In addition, the width of the opening portion 190 in the insulating layer 180b is preferably larger than the width of the opening portion 190 in the insulating layer 180c. Here, the width of the opening portion 190 in the insulating layer 180a and the width of the opening portion 190 in the insulating layer 180c can be represented by the width R12 described above, and the width of the opening portion 190 in the insulating layer 180b can be represented by the width R11 described above, for example. In other words, the width R11 is preferably larger than the width R12. Although FIG. 3A and the like show an example in which the width of the opening portion 190 in the insulating layer 180a is substantially the same as the width of the opening portion 190 in the insulating layer 180c, the width of the opening portion 190 in the insulating layer 180a may be different from the width of the opening portion 190 in the insulating layer 180c.

Although the details will be described later, when an opening portion is formed in the insulating layers 180a, 180b, and 180c and then etching for increasing the opening width is performed only in the insulating layer 180b, the insulating layer 180 can have a shape including a narrowed portion.

The thickness of the insulating layer 180b is preferably larger than that of each of the insulating layer 180a and the insulating layer 180c. With such a structure, the capacitance value of the capacitor 100 can be increased.

For the insulating layer 180b, a material with a lower relative dielectric constant than that of the material for each of the insulating layer 180a and the insulating layer 180c can be used, for example.

In etching for increasing the opening width in the insulating layer 180b, materials for the insulating layers 180a, 180b, and 180c are preferably selected so that the insulating layers 180a and 180c are not etched or the etching rates of the insulating layers 180a and 180c are sufficiently low in the etching.

For each of the insulating layers 180a, 180b, and 180c, an inorganic material can be used. Alternatively, one or more of the insulating layers 180a, 180b, and 180c can be formed using an organic material. For the insulating layers 180a and 180c, a material that can sufficiently reduce the etching rates of the insulating layers 180a and 180c in the etching treatment of the insulating layer 180b is preferably used. For example, one or more selected from silicon nitride and silicon nitride oxide can be used for the insulating layers 180a and 180c, and one or more selected from silicon oxide and silicon oxynitride can be used for the insulating layer 180b.

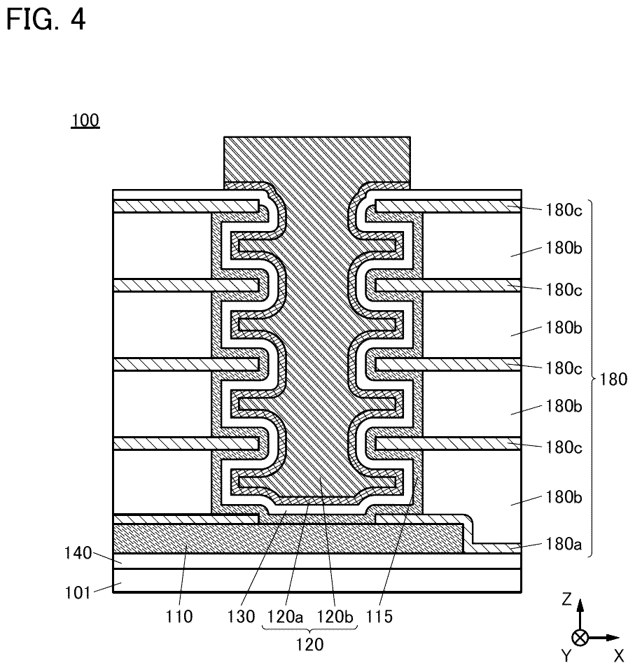

FIGS. 3B and 4 each illustrate an example in which a plurality of large-width portions are provided in the opening portion 190 in the insulating layer 180.

FIG. 3B illustrates an example of the capacitor 100 in which the insulating layers 180b and 180c are alternately stacked twice over the insulating layer 180a in the insulating layer 180. In FIG. 3B, the opening portion 190 provided in the insulating layer 180a, the opening portion 190 provided in the insulating layer 180b, and the opening portion 190 provided in the insulating layer 180c are an opening portion 190_a, an opening portion 190_b, and an opening portion 190_c, respectively. The opening portion 190_b has a larger width than each of the opening portion 190_a and the opening portion 190_c.

When the opening portion 190 includes a plurality of large-width portions, the surface area of the opening portion 190 can be increased.

Although FIG. 3B shows an example in which the opening portion 190 in the insulating layer 180 includes two large-width portions, the opening portion 190 can include three or more large-width portions. FIG. 4 shows an example in which four insulating layers 180b and four insulating layers 180c are provided and the insulating layers 180b and 180c are alternately stacked four times over the insulating layer 180a. In FIG. 4, the opening portion 190 includes four large-width portions.

Although an example where the opening portion 190 is circular in the plan view is described, the present invention is not limited thereto. The opening portion 190 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be a concave polygonal shape (a polygonal shape having at least one interior angle greater than 180°) or a convex polygonal shape (a polygonal shape having all the interior angles less than or equal to) 180°. As illustrated in FIG. 1A and the like, the opening portion 190 preferably has a circular shape in the plan view. When the opening portion is circular, the processing accuracy in forming the opening portion can be increased; thus, the opening portion can be formed to have a minute size. Note that in this specification and the like, a circular shape is not necessarily a perfect circular shape.

The shape and the size of the opening portion 190 in the plan view may differ from layer to layer. When the opening portion 190 has a circular top-view shape, the opening portions of the layers may be, but not necessarily, concentrically arranged.

### Structure Example 2 of Semiconductor Device

The semiconductor device of one embodiment of the present invention includes a transistor. In the transistor of one embodiment of the present invention, a source electrode and a drain electrode are positioned at different levels (e.g., heights in a direction perpendicular to a substrate plane or an insulating plane where the transistor is provided), so that current flows in a semiconductor layer in the height direction. In other words, the channel length direction includes a height (vertical) component, so that the transistor of one embodiment of the present invention can also be referred to as a vertical field effect transistor (VFET), a vertical transistor, a vertical-channel transistor, or the like.

In the transistor of one embodiment of the present invention, the source electrode, the semiconductor layer, and the drain electrode can be provided to overlap with each other. Thus, the area occupied by the transistor can be significantly smaller than the area occupied by what is called a planar transistor in which a planar semiconductor layer is provided.

The channel length of the transistor of one embodiment of the present invention can be controlled by the thicknesses of a first insulating layer, for example. Thus, a transistor with an extremely small channel length, which is difficult to achieve in a planar transistor, can be achieved. Accordingly, a transistor with a small occupation area and high on-state current can be provided.

The transistor including an oxide semiconductor has low off-state current, and thus enables long-term retention of stored contents when used for a memory device, for example. In other words, such a memory device does not require refresh operation or has an extremely low frequency of refresh operation, leading to a sufficient reduction in power consumption. When the transistor of one embodiment of the present invention is used for a memory device, the memory device can be highly integrated and reduced in power consumption.

### [Transistor 200]

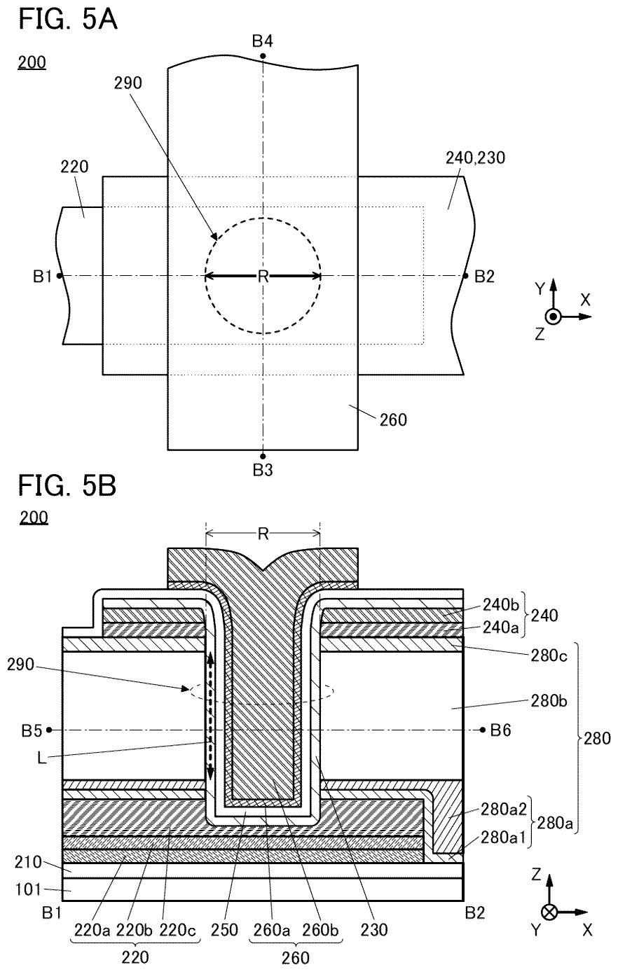

Structures of the semiconductor device of one embodiment of the present invention are described with reference to FIGS. 5A and 5B, FIGS. 6A and 6B, FIGS. 7A and 7B, FIG. 8, FIGS. 9A and 9B, FIGS. 10A and 10B, FIG. 11, FIG. 12, and FIG. 13.

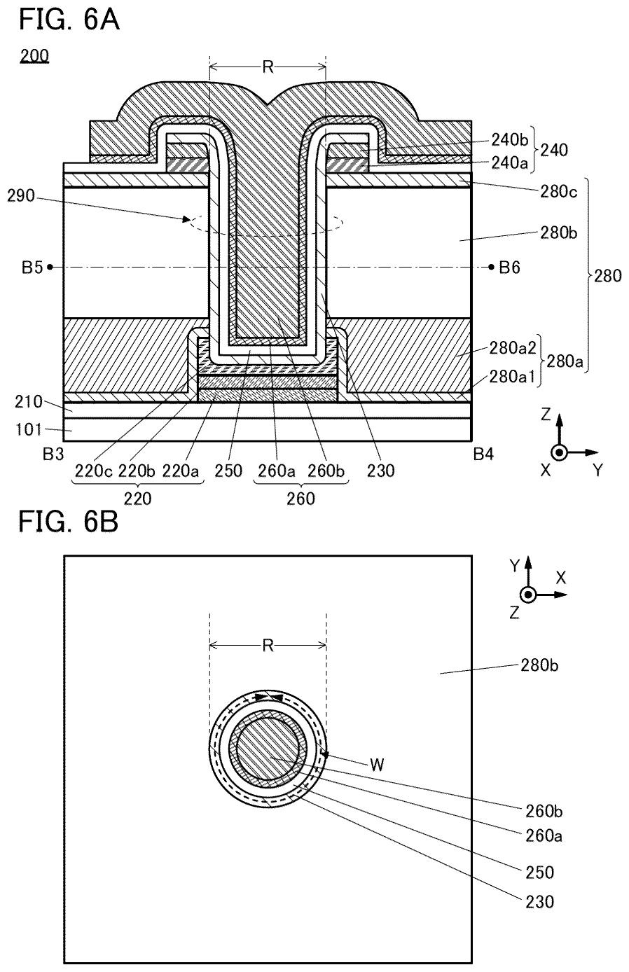

FIG. 5A is a plan view of a semiconductor device including a transistor 200. FIG. 5B illustrates a cross-sectional view taken along a dashed-dotted line B1-B2 in FIG. 5A. FIG. 6A is a cross-sectional view taken along a dashed-dotted line B3-B4 in FIG. 5A. FIG. 6B is a cross-sectional view taken along a dashed-dotted line B5-B6 in FIGS. 5B and 6A. FIG. 6B is a diagram seen from the Z direction.

The semiconductor device illustrated in FIGS. 5A and 5B and FIGS. 6A and 6B includes an insulating layer 210 over the substrate 101, the transistor 200 over the insulating layer 210, and an insulating layer 280 over the insulating layer 210. The insulating layer 210 and the insulating layer 280 can function as interlayer films. Thus, a material with a low relative dielectric constant is preferably used for each of the insulating layers 210 and 280.

The transistor 200 includes a conductive layer 220, a conductive layer 240 over the insulating layer 280, an oxide semiconductor layer 230, an insulating layer 250 over the oxide semiconductor layer 230, and a conductive layer 260 over the insulating layer 250. The insulating layer 280 is positioned over the conductive layer 220.

In the transistor 200, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode. The conductive layer 260 includes a region functioning as a gate wiring. The conductive layer 220 includes a region having a function of one of a source wiring and a drain wiring, and the conductive layer 240 includes a region having a function of the other of the source wiring and the drain wiring. When a material with a high relative dielectric constant is used for the insulating layer 250, the voltage at the time of operation of the transistor can be reduced while the physical thickness is maintained. Furthermore, the equivalent oxide thickness (EOT) of the gate insulating layer can be reduced. Alternatively, a material that can have ferroelectricity can also be used for the insulating layer 250.

As illustrated in FIGS. 5B and 6A, an opening portion 290 reaching the conductive layer 220 is provided in the insulating layer 280 and the conductive layer 240.

As illustrated in FIGS. 5B and 6A, the conductive layer 220 is provided with a depressed portion overlapping with the opening portion 290.

The shape and the size of the opening portion 290 in the plan view may differ from layer to layer. When the opening portion 290 has a circular top-view shape, the opening portions of the layers may be, but not necessarily, concentrically arranged.

At least part of the components of the transistor 200 is provided in the opening portion 290. Specifically, at least part of each of the oxide semiconductor layer 230, the insulating layer 250, and the conductive layer 260 is placed in the opening portion 290. Portions of the oxide semiconductor layer 230, the insulating layer 250, and the conductive layer 260 which are placed in the opening portion 290 reflect the shape of the opening portion 290.

The oxide semiconductor layer 230 is provided to cover a bottom portion and a sidewall of the opening portion 290. The oxide semiconductor layer 230 has a depressed portion reflecting the shape of the opening portion 290.

The conductive layer 240 can have a function of a wiring of the semiconductor device. Increasing the conductivity of the conductive layer 240 can improve the characteristics of the semiconductor device. For example, the operation speed can be increased. Thus, for the conductive layer 240, a material with high conductivity is preferably used.

Further, the conductive layer 240 can function as one of a source and a drain of the transistor. The conductive layer 240 includes a region in contact with the oxide semiconductor layer 230. Thus, the conductive layer 240 preferably has low contact resistance with the oxide semiconductor layer 230.

FIGS. 5B and 6A each illustrate an example where the conductive layer 240 has a two-layer structure of a conductive layer 240a and a conductive layer 240b over the conductive layer 240a. FIGS. 5B and 6A each also illustrate an example in which the conductive layer 220 has a stacked-layer structure of a conductive layer 220a, a conductive layer 220b over the conductive layer 220a, and a conductive layer 220c over the conductive layer 220b. For each of the conductive layers 240a and 220b, a material with high conductivity can be used, for example.

For the conductive layers 240b and 220c, which are layers on the side in contact with the oxide semiconductor layer 230, a material with low contact resistance with the oxide semiconductor layer 230 can be used, for example. Indium tin oxide can be suitably used for the conductive layer 220c, for example. In the case where silicon oxide or silicon oxynitride is used for an insulating layer 280b, the selectivity with respect to indium tin oxide is likely to be high in wet etching for making the insulating layer 280b recede, for example. The high selectivity here means that the etching rate of indium tin oxide can be sufficiently lower than that of the insulating layer 280b in the wet etching.

On the other hand, as a material that can be suitably used for the conductive layer 240b, a conductive material containing oxygen can be given. Since the conductive material containing oxygen can maintain a stable state even when being in contact with the oxide semiconductor layer 230, oxygen extraction from the oxide semiconductor layer 230 by the conductive layer 240b is unlikely to occur.

For the conductive layer 220a that is a layer on the side in contact with the insulating layer 210, a conductive material containing nitrogen and a conductive material containing oxygen can be used, for example.

The insulating layer 250 is provided to cover the oxide semiconductor layer 230. The insulating layer 250 is provided over the insulating layer 280 to cover the top surface and a side surface of the oxide semiconductor layer 230. The insulating layer 250 has a depressed portion reflecting the shape of the depressed portion of the oxide semiconductor layer 230.

The conductive layer 260 is provided to fill at least part of the depressed portion of the insulating layer 250. In the opening portion 290, the conductive layer 260 includes a region facing the oxide semiconductor layer 230 with the insulating layer 250 therebetween.

FIGS. 5B and 6A each show an example where the conductive layer 260 has a stacked-layer structure of a conductive layer 260a and a conductive layer 260b over the conductive layer 260a. For example, the conductive layer 260a is formed by a film formation method that provides good coverage, and the conductive layer 260b is formed by a film formation method with a higher film formation rate than the conductive layer 260a. For example, a material with high conductivity can be used for the conductive layer 260b, and a conductive material that is less likely to be oxidized, a conductive material having a function of inhibiting diffusion of oxygen, or the like can be used for the conductive layer 260a. For example, it is preferable to use titanium nitride for the conductive layer 260a and tungsten for the conductive layer 260b. For example, the conductive layer 120a and the conductive layer 120b can be referred to for materials that can be used for the conductive layer 260a and the conductive layer 260b, respectively.

The oxide semiconductor layer 230 includes a region facing the conductive layer 260 with the insulating layer 250 therebetween. At least part of the region functions as a channel formation region of the transistor 200. A region of the oxide semiconductor layer 230 in the vicinity of the conductive layer 220 functions as one of a source region and a drain region, and a region of the oxide semiconductor layer 230 in the vicinity of the conductive layer 240 functions as the other of the source region and the drain region. That is, the channel formation region is sandwiched between the source region and the drain region.

The oxide semiconductor layer 230 is provided in the opening portion 290. The transistor 200 has a structure in which current flows in the vertical direction since one of a source electrode and a drain electrode (here, the conductive layer 220) is positioned below and the other of the source electrode and the drain electrode (here, the conductive layer 240) is positioned above. That is, a channel is formed along a side surface of the opening portion 290.

In the oxide semiconductor layer 230, at least part of a region in contact with the conductive layer 240 can function as the other of the source region and the drain region of the transistor, for example.

In the oxide semiconductor layer 230, for example, at least part of a region in contact with the insulating layer 280, that is, part of a region that is not in contact with the conductive layer 240 or the conductive layer 220, can function as the channel formation region of the transistor. In particular, a region in contact with the insulating layer 280b preferably functions as the channel formation region of the transistor.

The transistor 200 includes the oxide semiconductor layer 230 in the channel formation region. That is, the transistor 200 can be regarded as an OS transistor.

Oxygen vacancies and impurities in the channel formation region in the oxide semiconductor may easily vary the electrical characteristics of the OS transistor and may worsen the reliability thereof. In some cases, a defect that is an oxygen vacancy into which hydrogen enters (hereinafter, sometimes referred to as VOH) is formed and an electron functioning as a carrier is generated. Thus, when the channel formation region of the oxide semiconductor includes oxygen vacancies, the OS transistor tends to have normally-on characteristics. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

FIGS. 5B and 6A each show an example in which the insulating layer 280 has a stacked-layer structure of an insulating layer 280a, the insulating layer 280b over the insulating layer 280a, and an insulating layer 280c over the insulating layer 280b. An example is shown in which the insulating layer 280a has a stacked-layer structure of an insulating layer 280al and an insulating layer 280a2 over the insulating layer 280al.

An insulating layer that supplies a large amount of oxygen can be used as the insulating layer 280b, and an insulating layer that supplies a smaller amount of oxygen than the insulating layer 280b can be used as each of the insulating layer 280a and the insulating layer 280c. The contact region between the oxide semiconductor layer 230 and the insulating layer 280b is supplied with a large amount of oxygen, so that oxygen vacancies can be suitably reduced. Meanwhile, the contact region between the oxide semiconductor layer 230 and the insulating layer 280a and the contact region between the oxide semiconductor layer 230 and the insulating layer 280c are supplied with a smaller amount of oxygen from the insulating layer 280 and the like than the contact region between the oxide semiconductor layer 230 and the insulating layer 280b. Thus, in the contact region between the oxide semiconductor layer 230 and the insulating layer 280a and the contact region between the oxide semiconductor layer 230 and the insulating layer 280c, the resistance of the oxide semiconductor layer 230 is reduced in some cases. The low-resistance region can function as one of a source region and a drain region.

The channel length of the transistor 200 is a distance between the source region and the drain region. In the case where the resistance of each of the contact region between the oxide semiconductor layer 230 and the insulating layer 280a and the contact region between the oxide semiconductor layer 230 and the insulating layer 280c is reduced, the channel length of the transistor 200 can be regarded as the thickness of the insulating layer 280b, for example. In FIG. 5B, a channel length L of the transistor 200 is indicated by a dashed double-headed arrow.

Although a planar transistor is difficult to further miniaturize since its channel length is limited by the light exposure limit of photolithography, the channel length of the transistor 200 can be set by the thickness of the insulating layer 280. Thus, the transistor 200 can have an extremely small channel length less than or equal to the light exposure limit of photolithography (e.g., preferably less than or equal to 60 nm, further preferably less than or equal to 50 nm, still further preferably less than or equal to 40 nm, yet still further preferably less than or equal to 30 nm, yet still further preferably less than or equal to 20 nm, yet still further preferably less than or equal to 10 nm, and preferably greater than or equal to 0.1 nm, further preferably greater than or equal to 1 nm, still further preferably greater than or equal to 5 nm). Accordingly, the transistor 200 can have higher on-state current and higher frequency characteristics.

The channel length of the transistor 200 is determined by the thickness of the insulating layer 280 over the conductive layer 220, and thus does not affect the area occupied by the transistor 200, for example, the area of the transistor 200 in the plan view. When the channel length of the transistor 200 is, for example, less than or equal to 1 μm, preferably less than or equal to 500 nm, further preferably less than or equal to 300 nm, the productivity, yield, and the like can be improved in formation of the insulating layer 280 and formation of the opening portion 290 in the insulating layer 280, for example.

From the above, the channel length of the transistor included in the semiconductor device of one embodiment of the present invention can be greater than or equal to 0.1 nm, preferably greater than or equal to 1 nm, further preferably greater than or equal to 5 nm, and less than or equal to 1 μm, preferably less than or equal to 500 nm, further preferably less than or equal to 300 nm.

The channel length L of the transistor 200 can be smaller than a channel width W of the transistor 200, for example. The channel length L of the transistor 200 can be, for example, greater than or equal to 0.1 times and less than or equal to 0.99 times, preferably greater than or equal to 0.5 times and less than or equal to 0.8 times the channel width W of the transistor 200. This structure enables the transistor to have excellent electrical characteristics and high reliability.

As illustrated in FIG. 6B, the oxide semiconductor layer 230, the insulating layer 250, and the conductive layer 260 are provided concentrically. Therefore, a side surface of the conductive layer 260 provided at the center faces the side surface of the oxide semiconductor layer 230 with the insulating layer 250 therebetween. That is, in the plan view, all the circumference of the oxide semiconductor layer 230 serves as the channel formation region. In this case, for example, the channel width of the transistor 200 is determined by the length of all the circumference of the oxide semiconductor layer 230. That is, the channel width of the transistor 200 is determined by the width of the opening portion 290 (the diameter in the case where the opening portion 290 is circular in the plan view). FIGS. 5A and 5B and FIG. 6A illustrate a width R of the opening portion 290, and FIG. 6B illustrates the channel width W of the transistor 200.

When the width of the opening portion 290 in the insulating layer 280 that is in contact with the region where the channel is formed in the oxide semiconductor layer 230 is increased, the channel width per unit area can be increased and the on-state current can be increased. In the case where the opening portion 290 is circular in the plan view, the channel width W is the product of “the width of the opening portion 290 in the insulating layer 280 that is in contact with the region where the channel is formed in the oxide semiconductor layer 230” and “the circular constant x”.

The width of the opening portion 290 sometimes varies in the depth direction. The width of the opening portion 290 at the highest position, the width of the opening portion 290 at the lowest position, the width of the opening portion 290 at the intermediate position, or the average value of these three widths can be used as the width of the opening portion 290. As the width of each of the opening portions in the layers where the opening portion 290 is provided, the width of the opening portion at the highest position in the layer, the width of the opening portion at the lowest position in the layer, the width of the opening portion at the intermediate position between these two positions, or the average value of these three widths can be used, for example.

In the case where the opening portion 290 is formed by a photolithography method, the width of the opening portion 290 is sometimes limited by the light exposure limit of photolithography, for example. In addition, the width R of the opening portion 290 is determined by the thicknesses of the oxide semiconductor layer 230, the insulating layer 250, and the conductive layer 260, which are provided in the opening portion 290. The width of the opening portion 290 can be, for example, greater than or equal to 5 nm, preferably greater than or equal to 10 nm, further preferably greater than or equal to 20 nm and less than or equal to 100 nm, preferably less than or equal to 60 nm, further preferably less than or equal to 50 nm, still further preferably less than or equal to 40 nm, yet still further preferably less than or equal to 30 nm.

As described above, when the opening portion 290 is formed to be circular in the plan view, the oxide semiconductor layer 230, the insulating layer 250, and the conductive layer 260 are provided concentrically. This makes the distance between the conductive layer 260 and the oxide semiconductor layer 230 substantially uniform, so that a gate electric field can be substantially uniformly applied to the oxide semiconductor layer 230.

Although an example where the opening portion 290 is circular in the plan view is described in this embodiment, the present invention is not limited thereto. The opening portion 290 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be either a concave polygonal shape or a convex polygonal shape. As illustrated in FIG. 1A and the like, the opening portion 290 in the plan view preferably has a circular shape. When the opening portion is circular, the processing accuracy in forming the opening portion can be increased; thus, the opening portion can be formed to have a minute size.

For the conductive layer 240b, a conductive material containing oxygen, a conductive material containing nitrogen, and the like can be used. For the conductive layer 240b, a metal oxide having conductivity (also referred to as an oxide conductor) can be suitably used. For the conductive layer 240b, indium tin oxide (also referred to as In—Sn oxide or ITO), indium tin oxide containing titanium oxide, ITSO, or indium zinc oxide (also referred to as In—Zn oxide or IZO (registered trademark)) can be suitably used, for example.

A conductive material with low electric resistance is preferably used for the conductive layer 240a. For the conductive layer 240a, it is possible to use a metal element selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, lanthanum, and the like; an alloy containing any of the above metal elements as a component; an alloy containing a combination of the above metal elements; or the like. The conductive layer 240a is preferably formed using a conductive material with low electric resistance, in which case the speed of circuit operation can be increased when the conductive layer 240 is used for a wiring or the like. A conductive material with lower electric resistance than the material for the conductive layer 240b is preferably used for the conductive layer 240a, for example. For example, tungsten, copper, aluminum, or an alloy containing aluminum can be suitably used for the conductive layer 240a.

When the conductive layer 220 includes the depressed portion in a position overlapping with the opening portion 290, unlike in the case where the depressed portion is not provided, the levels of the bottom surfaces of the insulating layer 250 and the conductive layer 260 in the opening portion 290 can be lower than the level of the top surface of the conductive layer 220 which is in contact with the insulating layer 280, with the top surface of the insulating layer 210 used as a reference. The levels of the surfaces can be determined using the formation surface of the transistor as a reference. Here, the top surface of the insulating layer 210 is used as the reference. The surface used as the reference is not limited to the formation surface of the transistor. For example, the top surface of the substrate where the transistor or the semiconductor device is provided may be used as the reference.

The oxide semiconductor layer 230 is in contact with the bottom surface and a side surface of the depressed portion of the conductive layer 220 and the top surface of the conductive layer 240b. When the conductive layer 220 has the depressed portion, the contact area between the oxide semiconductor layer 230 and the conductive layer 220 can be increased. Thus, the contact resistance between the oxide semiconductor layer 230 and the conductive layer 220 can be reduced.

FIGS. 5B and 6A each illustrate a structure where an end portion of the conductive layer 240 and an end portion of the oxide semiconductor layer 230 are aligned with each other outside the opening portion 290. The conductive layer 240 and the oxide semiconductor layer 230 can be formed by being processed using the same mask. This is preferable because the number of masks required for manufacturing the semiconductor device can be reduced. Note that the present invention is not limited thereto. For example, in the X direction or the Y direction, the end portion of the oxide semiconductor layer 230 or the end portion of the conductive layer 240 may be positioned inward or outward from the others.

As described above, the channel formation region, the source region, and the drain region can be formed in the opening portion 290. Thus, the area occupied by the transistor 200 can be reduced as compared with a planar transistor in which the channel formation region, the source region, and the drain region are provided separately on the XY plane. Accordingly, the semiconductor device can be highly integrated. In the case where the semiconductor device of one embodiment of the present invention is used for a memory device, the memory capacity per unit area can be increased. In the case where the semiconductor device of one embodiment of the present invention is used for a display device, the resolution of a display portion can be increased.

### Structure Example 3 of Semiconductor Device

Part of the transistor 200 included in the semiconductor device is provided in the opening portion 290 in the insulating layer 280 and the conductive layer 240. When the opening portion 290 has a narrowed portion, the channel width of the transistor 200 can be increased in some cases.

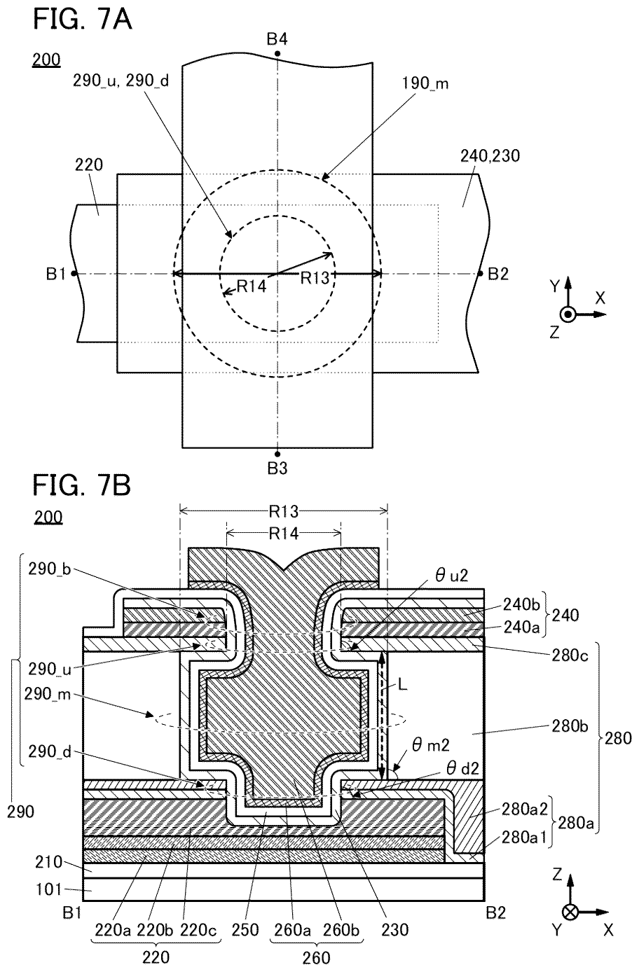

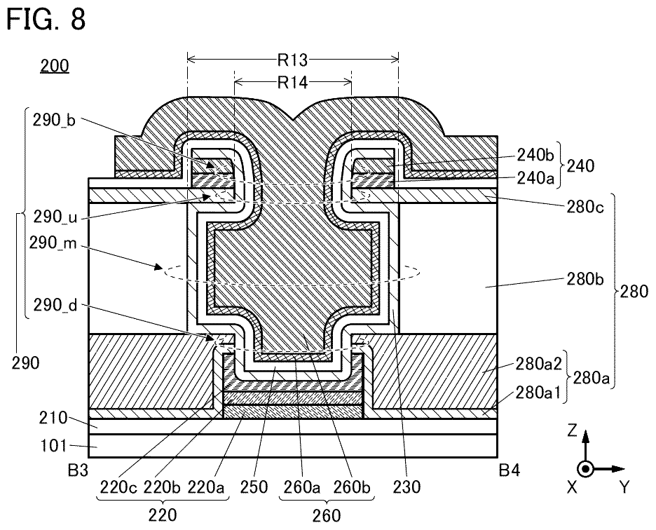

FIGS. 7A and 7B and FIG. 8 illustrate an example of a semiconductor device including the transistor 200. The semiconductor device illustrated in FIGS. 7A and 7B and FIG. 8 is different from that illustrated in FIGS. 5A and 5B and FIG. 6A mainly in that the widths of the upper portion and the lower portion of the opening portion in the insulating layer 280 are narrowed.

The width of the opening portion 290 in the insulating layer 280b is preferably larger than the width of the opening portion 290 in the insulating layer 280c. In addition, the width of the opening portion 290 in the insulating layer 280b is preferably larger than the width of the opening portion 290 in the insulating layer 280a.

In FIGS. 7A and 7B and FIG. 8, the opening portion 290 in the insulating layer 280a, the opening portion 290 in the insulating layer 280b, the opening portion 290 in the insulating layer 280c, and the opening portion 290 in the conductive layer 240 are referred to as an opening portion 290_d, an opening portion 290_m, an opening portion 290_u, and an opening portion 290_b, respectively. In the structure illustrated in FIGS. 7A and 7B and FIG. 8, the width of the opening portion 290_m is denoted by a width R13, and each of the width of the opening portion 290_d and the width of the opening portion 290_u is denoted by a width R14. The width R13 is larger than the width R14. Although FIGS. 7A and 7B and FIG. 8 show an example in which the width of the opening portion 290_d and the width of the opening portion 290_u are substantially the same, the width of the opening portion 290_d and the width of the opening portion 290_u may be different from each other. Here, when the thickness of the oxide semiconductor layer 230 is d[230], the thickness of the insulating layer 250 is d[250], and the thickness of the conductive layer 260a is d[260a], the width R14 is greater than or equal to a value represented by (d[230]+d[250]+d[260a])×2(R14≥ (d[230]+d[250]+d[260a])×2), for example. When the thickness of the insulating layer 280b is d[280b], d[280b] is also greater than or equal to a value represented by (d[230]+d[250]+d[260a])×2(d[280b] >(d[230]+d[250]+d[260a])×2).

Furthermore, the width R14 can be smaller than the thickness d[280b], for example. When the width R14 is small, the transistor can be miniaturized. In the semiconductor device of one embodiment of the present invention, even when the width R14 is small, the on-state current of the transistor can be sufficiently increased by increasing the width R13 of the opening portion in the insulating layer 280b.

An angle formed by a sidewall of the opening portion 290_u and the plane parallel to the surface of the substrate 101 is an angle θu2, an angle formed by a sidewall of the opening portion 290_d and the plane parallel to the surface of the substrate 101 is an angle θd2, and an angle formed by a sidewall of the opening portion 290_m and the plane parallel to the surface of the substrate 101 is an angle θm2. FIG. 7B shows an example where the angle θu2, the angle θd2, and the angle θm2 are each 90°. In that case, the upper portion, the lower portion, and the portion including the middle position of the opening portion 290 each have a cylindrical shape. Here, as a plane parallel to the surface of the substrate 101, the top surface of a layer provided over the substrate 101 can be used, for example.

The angle θu2, the angle θd2, and the angle θm2 in FIG. 7B and the like are each preferably greater than or equal to 45° and less than or equal to 90°. When the angle θu2 is greater than or equal to 80° and less than or equal to 90°, for example, the device can be integrated. When the angle θm2 is less than 80°, coverage of a side surface of the opening portion 290_m with the oxide semiconductor layer 230, the insulating layer 250, and the like can be improved in some cases.

The angle θm2 is sometimes greater than 90°. Also in such a case, when the oxide semiconductor layer 230, the insulating layer 250, and the like are each formed by a film formation method that provides good coverage, the side surface of the opening portion 290_m can be favorably covered.

In etching for increasing the opening width in the insulating layer 280b, materials for the insulating layers 280a, 280b, and 280c are preferably selected so that the insulating layers 280a and 280c are not etched or the etching rates of the insulating layers 280a and 280c are sufficiently low in the etching. As described above, an insulating layer that supplies a large amount of oxygen can be used as the insulating layer 280b, and an insulating layer that supplies a smaller amount of oxygen than the insulating layer 280b can be used as each of the insulating layers 280a and 280c.

For example, one or more selected from silicon nitride and silicon nitride oxide are used for each of the insulating layers 280a and 280c, and one or more selected from silicon oxide and silicon oxynitride are used for the insulating layer 280b. Silicon nitride and silicon nitride oxide each have a relative dielectric constant higher than those of silicon oxide and silicon oxynitride. Thus, when the proportion of the thickness of the insulating layer 280b in the insulating layer 280 is increased, the relative dielectric constant of the insulating layer 280 can be reduced, so that the parasitic capacitance between the conductive layer 220 and the conductive layer 240 can be reduced.

For the materials, structures, thicknesses, and the like that can be used for the insulating layers 280a, 280b, and 280c, the descriptions of the insulating layers 180a, 180b, and 180c can be referred to, respectively, in some cases.

Note that FIG. 5B and the like show an example of a structure in which the insulating layer 280a has a stacked-layer structure of the insulating layer 280al and the insulating layer 280a2 and the top surface of the insulating layer 280a2 is planarized. The insulating layer 280al can be formed by a film formation method that provides good coverage and is preferably formed by an ALD method or the like, for example. The insulating layer 280a2 can be formed by a method with a high film formation rate and is preferably formed by a sputtering method or the like, for example. The insulating layer 280al and the insulating layer 280a2 can be formed using the same material, for example. Alternatively, the insulating layer 280al and the insulating layer 280a2 may be formed using different materials.

In the opening portion 290 in the insulating layer 280, the channel formation region is provided in contact with a large-width portion, whereby the channel width of the transistor can be increased.

In the case where the region of the insulating layer 280 that is in contact with the region where the channel is formed in the oxide semiconductor layer 230 is the insulating layer 280b, the channel width W of the transistor 200 can be expressed as “width R13×π”. In the structure illustrated in FIGS. 7A and 7B and FIG. 8, the channel width of the transistor 200 can be larger than that in the structure illustrated in FIGS. 5A and 5B and FIGS. 6A and 6B.

In the case where the conductive layer 240 and the conductive layer 260 are each used as a wiring, the wiring width depends on the opening width of the upper portion of the opening portion 290; that is, the width R14 of the opening portion 290_u here, for example. By contrast, even when the width R13 of the opening portion 290_m is large, the wiring width is not necessarily large. That is, even when the width R13 is large, the area occupied by the transistor 200 is not necessarily large.

Thus, in the structure illustrated in FIGS. 7A and 7B and FIG. 8, the channel width can be increased while the area occupied by the transistor 200 is kept small.

In FIG. 7B and the like, the oxide semiconductor layer 230 includes a portion in contact with a side surface of the opening portion 290_m in the insulating layer 280b, a portion in contact with a side surface of the opening portion 290_u in the insulating layer 280c, a portion in contact with the bottom surface of the insulating layer 280c in the opening portion 290, a portion in contact with a side surface of the opening portion 290_d in the insulating layer 280a, a portion in contact with the top surface of the insulating layer 280a in the opening portion 290, and a portion in contact with the top surface of the conductive layer 220. The oxide semiconductor layer 230 includes a portion in contact with a side surface of the opening portion 290_b in the conductive layer 240 and a portion in contact with the top surface of the conductive layer 240.

In the oxide semiconductor layer 230, a portion in contact with the bottom surface of the insulating layer 280c and a portion in contact with the top surface of the conductive layer 240 overlap with each other with the insulating layer 280c and the conductive layer 240 therebetween.

The insulating layer 250 includes a portion facing the opening portion in the insulating layer 280 and the conductive layer 240 with the oxide semiconductor layer 230 therebetween. In the structure illustrated in FIG. 7B and the like, a portion covering the bottom surface of the insulating layer 280c and a portion covering the top surface of the conductive layer 240 overlap with each other in the insulating layer 250 with the oxide semiconductor layer 230, the insulating layer 280c, and the conductive layer 240 therebetween.

The conductive layer 260 includes a portion facing the opening portion in the insulating layer 280 and the conductive layer 240 with the oxide semiconductor layer 230 and the insulating layer 250 therebetween. In the structure illustrated in FIG. 7B and the like, a portion covering the bottom surface of the insulating layer 280c and a portion covering the top surface of the conductive layer 240 overlap with each other in the conductive layer 260 with the insulating layer 250, the oxide semiconductor layer 230, the insulating layer 280c, and the conductive layer 240 therebetween.

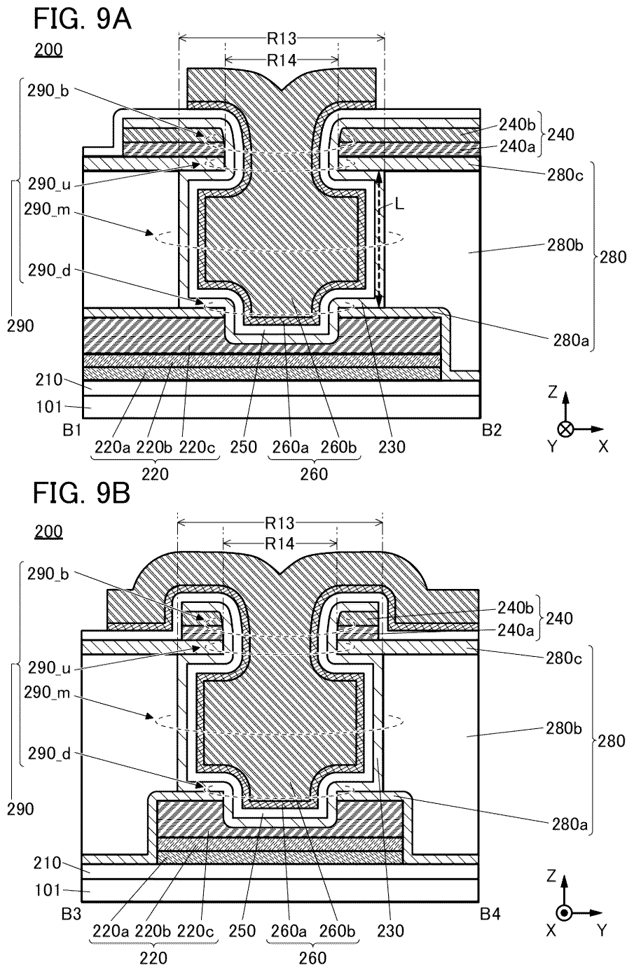

FIGS. 9A and 9B illustrate a variation of FIGS. 7B and 8.

Although FIGS. 7B and 8 illustrate an example in which the insulating layer 280a has a stacked-layer structure of the insulating layer 280al and the insulating layer 280a2 and the top surface of the insulating layer 280a2 is planarized, a structure may be employed where the insulating layer 280a has a single-layer structure and the top surface of the insulating layer 280a is not planarized as illustrated in FIGS. 9A and 9B.

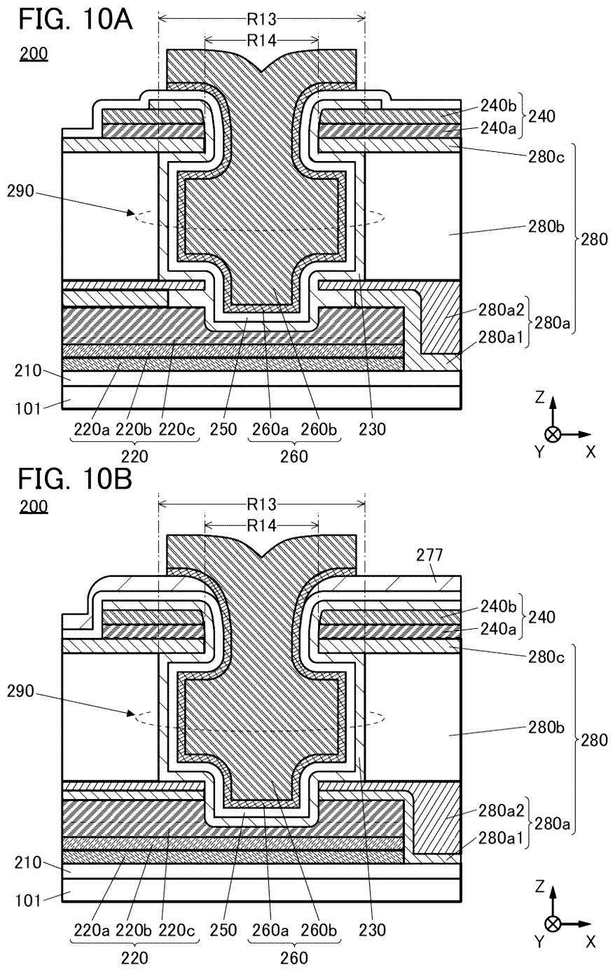

The structure illustrated in FIG. 10A is an example in which the width of the opening portion 290 in the insulating layer 280al is different from that of the opening portion 290 in the insulating layer 280a2. The structure in FIG. 10A can be formed in the following manner, for example: an opening portion is provided in the insulating layers 280a1, 280a2, 280b, and 280c, and then etching is performed to increase the width of the opening portion in each of the insulating layers 280al and 280b.

A material that can be used for the insulating layer 280b can be used for the insulating layer 280al, for example. A material that can be used for the insulating layer 280c can be used for the insulating layer 280a2, for example.

In the structure illustrated in FIG. 10A, the width of the opening portion 290 in the insulating layer 280a1 that is over and in contact with the conductive layer 220 is large, so that the contact area between the oxide semiconductor layer 230 and the top surface of the conductive layer 220 can be large.

In FIG. 10A, the oxide semiconductor layer 230 includes a portion in contact with the side surface of the opening portion 290 in the insulating layer 280b, a portion in contact with the side surface of the opening portion 290 in the insulating layer 280c, a portion in contact with the bottom surface of the insulating layer 280c in the opening portion 290, a portion in contact with the side surface of the opening portion 290 in the insulating layer 280a2, a portion in contact with the top surface of the insulating layer 280a2 in the opening portion 290, a portion in contact with the bottom surface of the insulating layer 280a2 in the opening portion 290, a portion in contact with the side surface of the opening portion 290 in the insulating layer 280a1, and a portion in contact with the top surface of the conductive layer 220. The oxide semiconductor layer 230 includes a portion in contact with the side surface of the opening portion 290 in the conductive layer 240 and a portion in contact with the top surface of the conductive layer 240.

Note that FIG. 10A illustrates, as an example, a structure in which the end portion of the oxide semiconductor layer 230 and the end portion of the conductive layer 240 are not aligned with each other; the conductive layer 240 includes an end portion outside the opening portion 290, and the end portion is positioned outward from the oxide semiconductor layer 230 when seen from the opening portion 290 side.

The semiconductor device illustrated in FIG. 10B is different from that in FIG. 7B mainly in that an insulating layer 277 is provided between a portion of the conductive layer 260 that is positioned over the top surface of the conductive layer 240 and the top surface of the conductive layer 240.

The semiconductor device illustrated in FIG. 10B includes the insulating layer 277. The insulating layer 277 is provided over the insulating layer 250. The insulating layer 277 covers the top surface of the conductive layer 240 with the insulating layer 250 therebetween.

The insulating layer 277 can be formed over the insulating layer 250 after the insulating layer 250 is formed to cover inside the opening portion 290, a side surface of the conductive layer 240, and the top surface of the conductive layer 240. When the insulating layer 277 is formed by an anisotropic film formation method, the insulating layer 277 is not formed in a region covering the side surface of the opening portion, and the insulating layer 277 can be selectively formed in a region covering the top surface of the conductive layer 240. A sputtering method can be given as the anisotropic film formation method, for example.

When the semiconductor device illustrated in FIG. 10B includes the insulating layer 277, the distance between the conductive layer 240 and the conductive layer 260 can be increased. Thus, parasitic capacitance between the conductive layer 240 and the conductive layer 260 can be reduced. When the insulating layer 277 includes a material with a low relative dielectric constant, the parasitic capacitance can be further reduced.

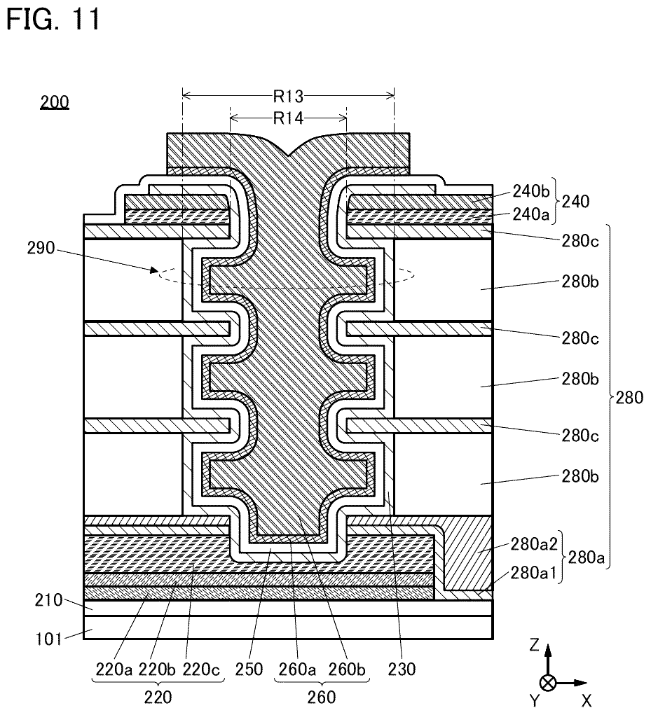

As illustrated in FIG. 11, the opening portion 290 in the insulating layer 280 may include a plurality of large-width portions. In the structure illustrated in FIG. 11, an example is shown in which the insulating layers 280b and 280c are alternately stacked three times over the insulating layer 280a in the insulating layer 280. The width of the opening portion 290 in the insulating layer 280b is larger than each of the width of the opening portion 290 in the insulating layer 280a and the width of the opening portion 290 in the insulating layer 280c. With such a structure, the channel formation region can be divided into a plurality of regions and a low-resistance region can provided therebetween in the case where the contact area between the oxide semiconductor layer 230 and the insulating layer 280a and the contact area between the oxide semiconductor layer 230 and the insulating layer 280c serve as low-resistance regions: for example, in the oxide semiconductor layer 230, a “low-resistance region”, a “channel formation region”, a “low-resistance region”, a “channel formation region”, and a “low-resistance region” can be provided in this order. Such a structure may improve the reliability of the transistor, for example.

Although FIG. 11 illustrates an example in which the insulating layer 280 includes three large-width portions, the insulating layer 280 may include two large-width portions or four or more large-width portions.

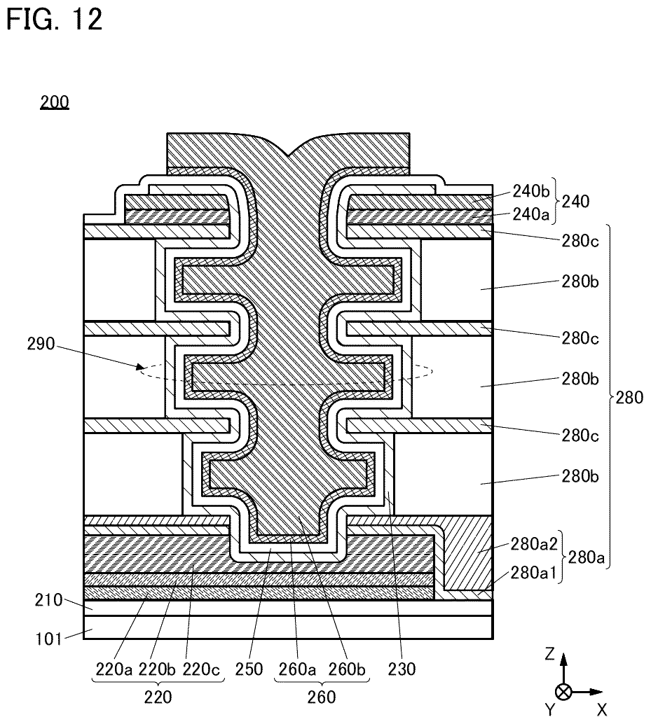

Although FIG. 11 illustrates an example in which the width of the opening portion 290 does not change depending on the depth of the opening portion 290, the deeper the opening portion 290 is, the lower the etching rate in the etching for increasing the opening width of the insulating layer 280b may be. As illustrated in FIG. 12, the deeper the opening portion 290 is, the smaller the width of the opening portion 290 positioned on a side surface of the insulating layer 280b may be, for example.

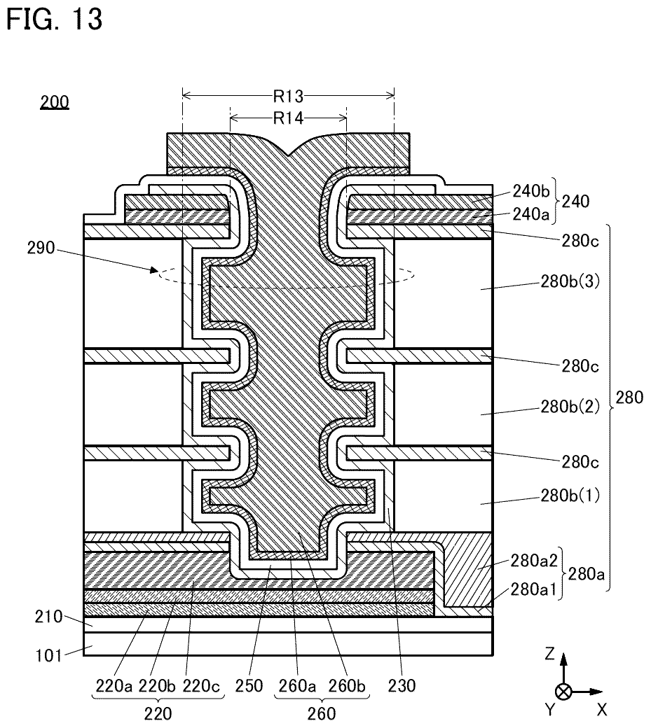

Here, at a deep position of the opening portion 290, reducing the thickness of the insulating layer 280b increases the etching rate in the etching for increasing the opening width of the insulating layer 280b in some cases. As illustrated in FIG. 13, an insulating layer 280b(1), an insulating layer 280b(2), and an insulating layer 280b(3) are provided in this order from the conductive layer 220 side in the three pairs of the insulating layers 280b and 280c. When the insulating layer 280b(2) is thinner than the insulating layer 280b(3) and the insulating layer 280b(1) is thinner than the insulating layer 280b(2), the difference in the width of the opening portion 290 in the insulating layer 280b(1), the width of the opening portion 290 in the insulating layer 280b(2), and the width of the opening portion 290 in the insulating layer 280b(3) can be small in some cases. Thus, the difference in the width of the opening portion in the upper portion and the width of the opening portion in the lower portion (bottom portion) can be reduced.

### [Insulating Layers]

An inorganic insulating film is preferably used as each of the insulating layers (e.g., the insulating layers 180, 130, 210, 250, 280, and 277) included in the semiconductor device. Examples of the inorganic insulating film include an oxide insulating film, a nitride insulating film, an oxynitride insulating film, and a nitride oxide insulating film. Examples of a material that can be used for the oxide insulating film include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of a material that can be used for the nitride insulating film include silicon nitride and aluminum nitride. Examples of a material that can be used for the oxynitride insulating film include silicon oxynitride, aluminum oxynitride, gallium oxynitride, yttrium oxynitride, and hafnium oxynitride. Examples of a material that can be used for the nitride oxide insulating film include silicon nitride oxide and aluminum nitride oxide. An organic insulating film may be used as each of the insulating layers included in the semiconductor device.

Examples of a material with a high relative dielectric constant include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low relative dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of the inorganic insulating material with a low relative dielectric constant include silicon oxide containing fluorine, silicon oxide containing carbon, and silicon oxide containing carbon and nitrogen. Another example is porous silicon oxide. Note that these silicon oxides may contain nitrogen.

A material that can show ferroelectricity may be used for each of the insulating layers included in the semiconductor device. Examples of the material that can show ferroelectricity include metal oxides such as hafnium oxide, zirconium oxide, and hafnium zirconium oxide. Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2(the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, curopium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a K-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can show ferroelectricity, a mixture or compound containing a plurality of materials selected from the above-listed materials can be used, for example. Alternatively, the insulating layer 130 that will be described in Embodiment 3 can have a stacked-layer structure of a plurality of materials selected from the above-listed materials. Since the above-listed materials and the like may change their crystal structures (characteristics) according to a variety of processes and the like as well as film formation conditions, a material that exhibits ferroelectricity is referred to not only as a ferroelectric but also as a material that can show ferroelectricity in this specification and the like.

A metal oxide containing one or both of hafnium and zirconium can have ferroelectricity even when being a thin film of several nanometers. A metal oxide containing one or both of hafnium and zirconium can have ferroelectricity even when having a minute area. Accordingly, the use of a metal oxide containing one or both of hafnium and zirconium enables miniaturization of the semiconductor device.

Note that in this specification and the like, the material that can show ferroelectricity processed into a layer shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer 130 needs to include a crystal. It is particularly preferable that the insulating layer include a crystal having an orthorhombic crystal structure, in which case ferroelectricity is exhibited. A crystal included in the insulating layer may have one or more of crystal structures selected from tetragonal, orthorhombic, monoclinic, and hexagonal crystal structures. Alternatively, the insulating layer may have an amorphous structure. In that case, the insulating layer may have a composite structure including an amorphous structure and a crystal structure.

Addition of a Group 3 element in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

A metal oxide containing one or both of hafnium and zirconium is preferable because the metal oxide can have ferroelectricity even when being a thin film of several nanometers. The thickness of the metal oxide used for the insulating layer 130 is preferably less than or equal to 100 nm, further preferably less than or equal to 50 nm, still further preferably less than or equal to 20 nm, yet still further preferably less than or equal to 10 nm (typically, greater than or equal to 2 nm and less than or equal to 9 nm). For example, the thickness is preferably greater than or equal to 8 nm and less than or equal to 12 nm. With use of the ferroelectric layer that can have a small thickness, the capacitor 100 can be combined with a miniaturized semiconductor element such as a transistor to manufacture a semiconductor device.

A metal oxide containing one or both of hafnium and zirconium is preferable because the metal oxide can have ferroelectricity even with a minute area. For example, a ferroelectric layer can have ferroelectricity even with an area (occupation area) less than or equal to 100 μm², preferably less than or equal to 10 μm², further preferably less than or equal to 1 μm², or still further preferably less than or equal to 0.1 μm² in the plan view. Furthermore, even with an area less than or equal to 10000 nm², preferably less than or equal to 1000 nm², the metal oxide can have ferroelectricity in some cases. With a small-area ferroelectric layer, the area occupied by the capacitor 100 can be reduced.

A transistor including a metal oxide can have stable electrical characteristics when surrounded by an insulating layer having a function of inhibiting transmission of impurities and oxygen. The insulating layer having a function of inhibiting transmission of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for an insulating layer having a function of inhibiting transmission of impurities and oxygen, an oxide such as aluminum oxide, magnesium oxide, gallium oxide, germanium oxide, yttrium oxide, zirconium oxide, lanthanum oxide, neodymium oxide, hafnium oxide, or tantalum oxide; a nitride such as aluminum nitride or silicon nitride; or a nitride oxide such as silicon nitride oxide.

Specific examples of the material for the insulating layer having a function of inhibiting transmission of oxygen and impurities such as water and hydrogen include a metal oxide such as aluminum oxide, magnesium oxide, gallium oxide, germanium oxide, yttrium oxide, zirconium oxide, lanthanum oxide, neodymium oxide, hafnium oxide, tantalum oxide, and an oxide containing aluminum and hafnium (hafnium aluminate). Other examples include nitrides such as aluminum nitride, aluminum titanium nitride, and silicon nitride. Other examples include a nitride oxide such as silicon nitride oxide.

An insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, oxygen vacancies in the oxide semiconductor layer can be reduced. Examples of a material for an insulating layer in which a region containing excess oxygen is easily formed include silicon oxide, silicon oxynitride, and porous silicon oxide.

As the insulating layer in contact with the oxide semiconductor layer or the insulating layer provided in the vicinity of the oxide semiconductor layer, a hydrogen-barrier insulating layer is preferably used. When the insulating layer has a barrier property against hydrogen, diffusion of hydrogen into the oxide semiconductor layer can be inhibited.

Examples of a material for an insulating layer having a function of capturing or fixing hydrogen include metal oxides such as an oxide containing hafnium, an oxide containing magnesium, an oxide containing aluminum, an oxide containing aluminum and hafnium (hafnium aluminate), and an oxide containing hafnium and silicon (hafnium silicate). Furthermore, these metal oxides may further contain zirconium, and an example of such a metal oxide is an oxide containing hafnium and zirconium.

The insulating layer having a function of capturing or fixing hydrogen preferably has an amorphous structure. In a metal oxide having an amorphous structure, some oxygen atoms have a dangling bond, which allows the metal oxide to have a high property of capturing or fixing hydrogen. Thus, when the insulating layer has an amorphous structure, the function of capturing or fixing hydrogen can be enhanced. For example, the amorphous structure of the metal oxide may be achieved by addition of silicon. For example, an oxide containing hafnium and silicon (hafnium silicate) is preferably used.

When the insulating layer has an amorphous structure, formation of a crystal grain boundary can be inhibited. Inhibiting formation of a crystal grain boundary can increase the planarity of the insulating layer. This enables the insulating layer to have uniform thickness distribution and a reduced number of extremely thin portions, so that the withstand voltage of the insulating layer can be increased. In addition, the thickness distribution of the film provided over the insulating layer can be uniform. Furthermore, inhibiting formation of a crystal grain boundary in the insulating layer can reduce leakage current due to the defect states in the crystal grain boundary. Thus, the insulating layer can function as an insulating film with low leakage current.

Note that the insulating layer may partly include one or both of a crystal region and a crystal grain boundary.

Note that a function of capturing or fixing a target substance can also be referred to as a property that does not easily allow diffusion of a target substance. Thus, a function of capturing or fixing a target substance can be rephrased as a barrier property.

In this specification and the like, a barrier insulating layer refers to an insulating layer having a barrier property. In addition, the barrier property refers to a property that does not easily allow diffusion of a target substance (also referred to as a property that does not easily allow transmission of a target substance, a property with low permeability of a target substance, or a function of inhibiting diffusion of a target substance). Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

Examples of a material for the hydrogen-barrier insulating layer include aluminum oxide, magnesium oxide, hafnium oxide, gallium oxide, silicon nitride, and silicon nitride oxide.

Examples of a material for an oxygen-barrier insulating layer include an oxide containing one or both of aluminum and hafnium, magnesium oxide, gallium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

As the insulating layer 210, a hydrogen-barrier insulating layer is preferably used. When the insulating layer 210 provided below the oxide semiconductor layer 230 has a barrier property against hydrogen, diffusion of hydrogen into the oxide semiconductor layer 230 from below the transistor 200 can be inhibited. For example, a silicon nitride film is preferably used as the insulating layer 210.

An insulating layer having a function of capturing or fixing hydrogen is preferably used as the insulating layer 210. When the insulating layer 210 has a function of capturing or fixing hydrogen, hydrogen in the oxide semiconductor layer 230 can diffuse into the insulating layer 210 through the conductive layer 220 and the hydrogen can be captured or fixed. Thus, the hydrogen concentration in the oxide semiconductor layer 230 can be reduced.

The concentration of impurities such as water and hydrogen in the insulating layer 210 is preferably reduced. This can inhibit entry of impurities such as water and hydrogen into the channel formation region of the oxide semiconductor layer 230.

The insulating layer 210 can have a stacked-layer structure of two or more layers. For example, the insulating layer 210 can have a two-layer structure of a first insulating layer and a second insulating layer over the first insulating layer. In that case, a hydrogen-barrier insulating layer is preferably used as the first insulating layer, and an insulating layer having a function of capturing or fixing hydrogen is preferably used as the second insulating layer, for example. Specifically, a silicon nitride film is preferably used as the first insulating layer, and a hafnium oxide film, a hafnium silicate film, or an aluminum oxide film is preferably used as the second insulating layer.

The insulating layer 280 functions as an interlayer film and thus is preferably formed using any of the above-described materials with a low relative dielectric constant. In the case where a material with a low relative dielectric constant is used for an interlayer film, the parasitic capacitance generated between wirings can be reduced. Silicon oxide or silicon oxynitride can be used for the insulating layer 280, for example.

The concentration of impurities such as water and hydrogen in the insulating layer 280 is preferably reduced. This can inhibit entry of impurities such as water and hydrogen into the channel formation region of the oxide semiconductor layer 230.

For example, the insulating layer including a region containing excess oxygen can be formed by a sputtering method in an oxygen-containing atmosphere. Since a molecule containing hydrogen is not used as a film formation gas in the sputtering method, the concentration of hydrogen in the insulating layer 280 can be reduced. When at least part of layer in the insulating layer 280 is formed by a sputtering method in this manner, oxygen can be supplied from the insulating layer 280 to the channel formation region of the oxide semiconductor layer 230, so that oxygen vacancies and V_{O}H therein can be reduced.

As the insulating layer 250, a hydrogen-barrier insulating layer is preferably used. When the insulating layer 250 provided over the oxide semiconductor layer 230 has a barrier property against hydrogen, diffusion of hydrogen contained in the conductive layer 260 into the oxide semiconductor layer 230 can be inhibited. For example, a silicon nitride film is suitable as the insulating layer 250 because of its high barrier property against hydrogen.

Since the insulating layer 250 is in contact with the oxide semiconductor layer 230, an insulating layer having a function of capturing or fixing hydrogen is preferably used. In this case, hydrogen contained in the oxide semiconductor layer 230 can be captured or fixed more effectively. Thus, the hydrogen concentration in the oxide semiconductor layer 230 (in particular, the hydrogen concentration in the channel formation region of the transistor) can be reduced. Accordingly, V_{O}H in the channel formation region can be reduced, so that the channel formation region can be an i-type or substantially i-type region.

As the insulating layer 250, an insulating layer including a region containing excess oxygen is preferably used. Accordingly, oxygen can be supplied from the insulating layer 250 to the oxide semiconductor layer 230, so that oxygen vacancies in the oxide semiconductor layer 230 can be reduced. A silicon oxide film, a silicon oxynitride film, or the like has a thermally stable structure and is thus suitable for the insulating layer 250.

The insulating layer 250 can have a stacked-layer structure of two or more layers. In that case, the insulating layer 250 is preferably formed of two or more kinds of films. When the insulating layer 250 is formed of two or more kinds of films, the insulating layer 250 can have a plurality of functions. Examples of the functions of the insulating layer 250 include a function of extracting hydrogen from the oxide semiconductor layer 230 and a function of inhibiting diffusion of hydrogen into the oxide semiconductor layer 230.

For example, the insulating layer 250 can have a two-layer structure of a first insulating layer and a second insulating layer over the first insulating layer. In this case, the first insulating layer is in contact with the oxide semiconductor layer 230. For example, an insulating layer having a function of capturing or fixing hydrogen is preferably used as the first insulating layer, and a hydrogen-barrier insulating layer is preferably used as the second insulating layer. With such a structure, the hydrogen concentration in the oxide semiconductor layer 230 can be reduced and diffusion of hydrogen into the oxide semiconductor layer 230 can be inhibited. Accordingly, the transistor can have high reliability.

Alternatively, for example, an insulating layer including a region containing excess oxygen is preferably used as the first insulating layer, and a hydrogen-barrier insulating layer is preferably used as the second insulating layer. Alternatively, for example, an insulating layer including a region containing excess oxygen is preferably used as the first insulating layer, and an insulating layer having a function of capturing or fixing hydrogen is preferably used as the second insulating layer. With such a structure, the amount of oxygen vacancies and the hydrogen concentration in the oxide semiconductor layer 230 can be reduced, so that diffusion of hydrogen into the oxide semiconductor layer 230 can be inhibited. Accordingly, the transistor can have high reliability.

The insulating layer 250 can include a third insulating layer between the oxide semiconductor layer 230 and the first insulating layer, for example. In other words, the insulating layer 250 can have a three-layer structure of the third insulating layer, the first insulating layer over the third insulating layer, and the second insulating layer over the first insulating layer.

For example, an insulating layer including a region containing excess oxygen or an insulating layer containing a material with a low relative dielectric constant is preferably used as the third insulating layer, an insulating layer having a function of capturing or fixing hydrogen is preferably used as the first insulating layer, and an insulating layer having a barrier property against hydrogen and oxygen is preferably used as the second insulating layer. A silicon oxide film or a silicon oxynitride film is preferably used as the third insulating layer. When an oxide film is used as the third insulating layer in contact with the oxide semiconductor layer 230, oxygen can be supplied to the oxide semiconductor layer 230. Providing the second insulating layer can inhibit oxygen contained in the third insulating layer from diffusing into the conductive layer 260 and inhibit the conductive layer 260 from being oxidized. Furthermore, a reduction in the amount of oxygen supplied from the third insulating layer to the oxide semiconductor layer 230 can be inhibited.

The insulating layer 250 can include a fourth insulating layer between the oxide semiconductor layer 230 and the third insulating layer, for example. In other words, the insulating layer 250 can have a four-layer structure of the fourth insulating layer, the third insulating layer over the fourth insulating layer, the first insulating layer over the third insulating layer, and the second insulating layer over the first insulating layer.

As the fourth insulating layer, an insulating layer having a barrier property against oxygen is preferably used. Note that the first to third insulating layers can have a structure similar to that of the layers used in the above three-layer structure. The fourth insulating layer is in contact with the oxide semiconductor layer 230 and the conductive layer 240. When the fourth insulating layer has a barrier property against oxygen, release of oxygen from the oxide semiconductor layer 230 can be inhibited. This inhibits formation of an oxide film on the side surface of the conductive layer 240 due to oxidization of the side surface. It is thus possible to inhibit a reduction in the on-state current or field-effect mobility of the transistor 200.

As the fourth insulating layer, an aluminum oxide film is preferably used, for example. An aluminum oxide film has a function of capturing or fixing hydrogen, and thus is suitably used as the fourth insulating layer in contact with the oxide semiconductor layer 230. Specifically, the insulating layer 250 preferably has a four-layer structure where an aluminum oxide film, a silicon oxide film, a hafnium oxide film, and a silicon nitride film are stacked in this order from the oxide semiconductor layer 230 side.

The insulating layer 250 is preferably thin. For example, when the insulating layer 250 has a thickness greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in a subthreshold region when drain voltage is constant and drain current is changed by one order of magnitude.

The thickness of each layer included in the insulating layer 250 is preferably greater than or equal to 0.1 nm and less than or equal to 10 nm, further preferably greater than or equal to 0.1 nm and less than or equal to 5 nm, still further preferably greater than or equal to 0.5 nm and less than or equal to 5 nm, yet further preferably greater than or equal to 1 nm and less than 5 nm, yet still further preferably greater than or equal to 1 nm and less than or equal to 3 nm. Note that each layer included in the insulating layer 250 at least partly includes a region with the above-described thickness.

Typically, the thicknesses of the fourth insulating layer, the third insulating layer, the first insulating layer, and the second insulating layer are 1 nm, 2 nm, 2 nm, and 1 nm, respectively. Such a structure enables the transistor to have excellent electrical characteristics even when the transistor is miniaturized or highly integrated.

In addition, it is acceptable that the second insulating layer is not provided in the insulating layer 250 having the four-layer structure. For example, an insulating layer having a barrier property against oxygen can be used as the fourth insulating layer, an insulating layer including a material with a low relative dielectric constant can be used as the third insulating layer, and an insulating layer having a function of capturing or fixing hydrogen can be used as the first insulating layer. Specifically, it is possible to employ a three-layer structure where an aluminum oxide film, a silicon oxide film, and a hafnium oxide film are stacked in this order from the oxide semiconductor layer 230 side.

Note that in formation of the insulating layer 250 having a stacked-layer structure of a plurality of insulating films, an ALD process is preferably performed twice or more. For example, two or more kinds of the insulating films in the insulating layer 250 are preferably formed through an ALD process. When at least two kinds of insulating films are formed through an ALD process, the coverage with the insulating layer 250 and the thickness uniformity of the insulating layer 250 can be improved. When two or more kinds of films, e.g., two or more kinds of insulating films are successively formed through an ALD process, the productivity can be increased.

For the insulating layer, an organic material can also be used. As the organic material, a photosensitive resin is preferably used, and for example, a photosensitive resin composite containing an acrylic resin can be used. In this specification and the like, an acrylic resin refers not only to a polymethacrylic acid ester or a methacrylic resin, but also to all the acrylic polymer in a broad sense in some cases.

The organic material is not limited to the above. For example, an acrylic resin, a polyimide resin, an epoxy resin, a polyamide resin, a polyimide-amide resin, a silicone resin, a siloxane resin, a benzocyclobutene-based resin, a phenol resin, or precursors of these resins can be used in some cases. An organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used in some cases. As another example, a photoresist can be used as the photosensitive resin in some cases. Examples of the photosensitive resin include positive-type materials and negative-type materials.

### [Conductive Layers]

For the conductive layers (e.g., the conductive layers 110, 115, 120, 220, 240, and 260) included in the semiconductor device, it is preferable to use a metal element selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, lanthanum, and the like; an alloy containing any of the above metal elements as a component; an alloy containing a combination of the above metal elements; or the like. A nitride of the alloy containing any of the above metal elements as a component or an oxide of the alloy may be used. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. As examples of the conductive material containing oxygen, indium oxide containing tungsten oxide, indium oxide containing titanium oxide, indium tin oxide, indium tin oxide containing titanium oxide, ITSO, indium zinc oxide, indium zinc oxide containing tungsten oxide, and the like can be given. In this specification and the like, a conductive film formed using the conductive material containing oxygen may be referred to as an oxide conductive film.

A conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

The conductive layer 260 includes a region functioning as a gate wiring. The conductive layer 260 is preferably formed using a material with high conductivity such as tungsten. For the conductive layer 260, a conductive material that is not easily oxidized, a conductive material having a function of inhibiting diffusion of oxygen, or the like is preferably used. As described above, examples of the conductive material include a conductive material containing nitrogen (e.g., titanium nitride or tantalum nitride) and a conductive material containing oxygen (e.g., ruthenium oxide). Thus, a decrease in conductivity of the conductive layer 260 can be inhibited.

It is preferable to use, for the conductive layer 260, a conductive material containing oxygen and a metal element contained in the metal oxide where a channel is formed. Alternatively, a conductive material containing any of the above metal elements and nitrogen (e.g., titanium nitride or tantalum nitride) may be used. One or more of ITO, indium oxide containing tungsten oxide, indium zinc oxide containing tungsten oxide, indium oxide containing titanium oxide, indium tin oxide containing titanium oxide, In—Zn oxide, and ITSO may be used. Indium gallium zinc oxide containing nitrogen may also be used. With use of such a material, hydrogen contained in the metal oxide where a channel is formed can be captured in some cases. Alternatively, hydrogen entering from a surrounding insulating layer or the like can be captured in some cases.

### [Substrate]

As the substrate (e.g., the substrate 101) over which the transistor is formed, for example, an insulator substrate, a semiconductor substrate, or a conductor substrate can be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include the above semiconductor substrate including an insulator region, e.g., a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include a substrate which is an insulator substrate provided with a conductor or a semiconductor, a substrate which is a semiconductor substrate provided with a conductor or an insulator, and a substrate which is a conductor substrate provided with a semiconductor or an insulator. Alternatively, these substrates provided with elements may be used. Examples of the element provided over the substrate include a capacitor, a resistor, a switching element, a light-emitting element, and a memory element.

The above is the description of materials that can be used for the semiconductor device of this embodiment.

### Manufacturing Method Example of Semiconductor Device

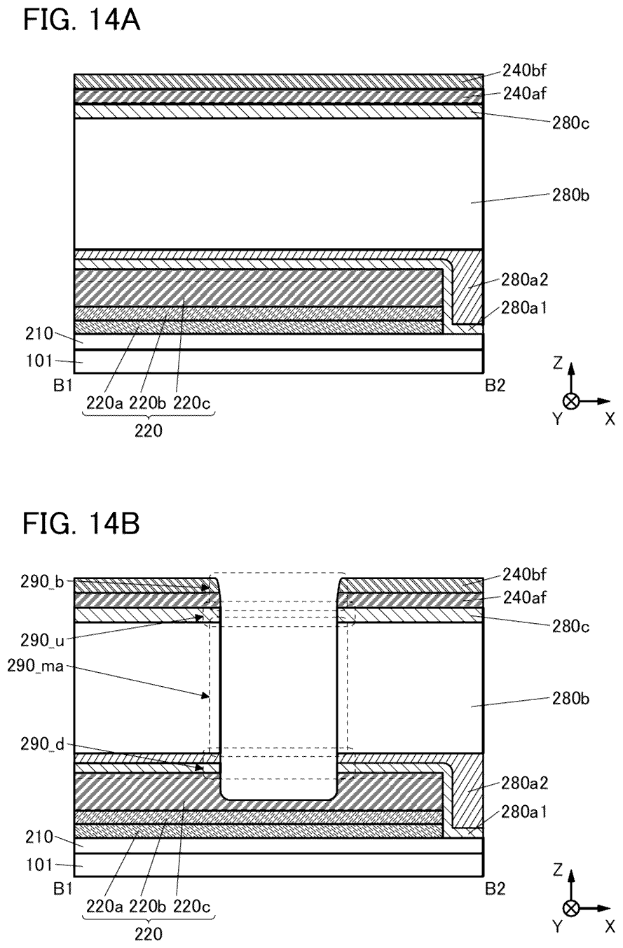

A method for manufacturing the semiconductor device is described with reference to FIGS. 14A and 14B, FIGS. 15A and 15B, and FIG. 16. Here, a method for manufacturing the structure illustrated in FIG. 7B is described as an example. As for a material and a formation method of each component, portions similar to those described in the above embodiment are not described in some cases.

Thin films included in the semiconductor device (e.g., insulating films, semiconductor films, and conductive films) can be formed by any of a sputtering method, a chemical vapor deposition (CVD) method, an ALD method, a pulsed laser deposition (PLD) method, a molecular beam epitaxy (MBE) method, a vacuum evaporation method, and the like.

Examples of the sputtering method include an RF sputtering method in which a high-frequency power source is used for a sputtering power source, a DC sputtering method in which a DC power source is used, and a pulsed DC sputtering method in which voltage applied to an electrode is changed in a pulsed manner. Furthermore, an RF superimposed DC sputtering method can be given. For film formation using an insulating target, an RF sputtering method is preferably used. A DC sputtering method is used mainly in the case of formation using a conductive target. In a DC sputtering method, not only formation of a conductive film but also formation of an insulating film is possible by reactive sputtering using a pulsed DC sputtering method. The pulsed DC sputtering method can be specifically used mainly for forming a film of a compound such as an oxide, a nitride, or a carbide by a reactive sputtering method. In an RF superimposed DC sputtering method, the ion energy and the potential on the target side can be controlled during formation. Thus, damage due to formation can be reduced as compared with that in the case of an RF sputtering method. Moreover, a high-quality film can be obtained.

A sputtering method is a film formation method using deposition of particles ejected from a target and can be regarded as a film formation method that easily has an anisotropic deposition rate.

As the sputtering method, an ionization sputtering method can be used, for example. The ionization sputtering method is a highly anisotropic film formation method by a self bias or the like in which a sputtering particle generated from a target is ionized by RF or the like.

When a long throw sputtering method or a collimator sputtering method is used as the sputtering method, for example, highly anisotropic film formation can be performed. In the long throw sputtering method, the distance between a sputtering target and a substrate is long to enable highly anisotropic film formation.

Note that CVD methods can be classified into a plasma-enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object to be processed. A wiring, an electrode, an element (e.g., a transistor or a capacitor), or the like included in a semiconductor device might be charged up by receiving charge from plasma, for example. In that case, the accumulated charge might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during formation.

As an ALD method, a thermal ALD method, in which a precursor and a reactant react with each other only by a thermal energy, a plasma-enhanced ALD (PEALD) method, in which a reactant excited by plasma is used, and the like can be used.

An ALD method enables atomic layers to be deposited one by one, and has advantages such as formation of an extremely thin film, formation on a component with a high aspect ratio, formation of a film with few defects such as pinholes, formation with excellent coverage, and low-temperature formation. A PEALD method utilizing plasma is preferable because formation at lower temperatures is possible in some cases. Note that a precursor used in an ALD method sometimes contains an impurity such as carbon. For that reason, a film provided by an ALD method may contain an impurity such as carbon in a larger quantity than a film provided by another film formation method. Note that impurities can be quantified by X-ray photoelectron spectroscopy (XPS) or secondary ion mass spectrometry (SIMS). The film formation method of a metal oxide of one embodiment of the present invention, which employs an ALD method and one or both of a formation condition with a high substrate temperature and impurity removal treatment, can sometimes form a film with smaller amounts of carbon and chlorine than a method employing an ALD method without the formation condition with a high substrate temperature or the impurity removal treatment.

Unlike in a film formation method in which particles ejected from a target or the like are deposited, an ALD method and a CVD method are film formation methods in which a film is formed by reaction at a surface of an object to be processed. Thus, an ALD method and a CVD method can provide good step coverage, almost regardless of the shape of an object to be processed. In particular, an ALD method allows excellent step coverage and excellent thickness uniformity and can be suitably used to cover a surface of an opening portion with a high aspect ratio, for example. Isotropic film formation can be performed by an ALD method. An ALD method can also be expressed as a film formation method with low deposition rate anisotropy. Note that an ALD method has a relatively low film formation rate; hence, in some cases, the ALD method is preferably combined with another film formation method with a high film formation rate, such as a sputtering method or a CVD method. For example, when the metal oxide has a stacked-layer structure of a first metal oxide and a second metal oxide, a method in which a sputtering method is used to form the first metal oxide, and an ALD method is used to form the second metal oxide over the first metal oxide can be given. For example, in the case where the first metal oxide has a crystal part, crystal growth occurs in the second metal oxide with use of the crystal part as a nucleus.

When a CVD method or an ALD method is used, the composition of a film to be formed can be controlled with the flow rate ratio of the source gases. For example, in a CVD method and an ALD method, a film with a certain composition can be formed by adjusting the flow rate ratio of the source gases. Moreover, for example, when the flow rate ratio of the source gases is changed during film formation in a CVD method and an ALD method, a film whose composition is continuously changed can be formed. In the case where a film is formed while the flow rate ratio of the source gases is changed, as compared with the case where a film is formed using a plurality of film formation chambers, the time taken for the formation can be shortened because the time taken for transfer and pressure adjustment is omitted. Hence, the productivity of the semiconductor device can be improved in some cases.

A film with a certain composition can be formed by adjusting the amount of introduced source gases, the number of times of introduction (also referred to as the number of pulses), the time required for one pulse (also referred to as the pulse time), and the like in an ALD method. An ALD method in which a plurality of different kinds of precursors are used enables formation of a film with a desired composition. In the case where a plurality of different kinds of precursors are used, the number of cycles for each precursor is controlled, whereby a film with a desired composition can be formed.

Alternatively, thin films included in the semiconductor device (e.g., insulating films, semiconductor films, and conductive films) can be formed by a wet process such as a spin coating method, a dip coating method, a spray coating method, an inkjet method, dispensing, screen printing, offset printing, doctor blade coating, slit coating, roll coating, curtain coating, or knife coating.

In processing thin films included in the semiconductor device, a lithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of lithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a lithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by a liquid immersion exposure technique. As the light for exposure, extreme ultraviolet (EUV) light or X-rays may also be used. Furthermore, instead of the light used for the exposure, an electron beam can also be used. EUV, X-rays, or an electron beam is preferably used to enable extremely minute processing. Note that a photomask is not needed when exposure is performed by scanning with a beam such as an electron beam.

For etching of the thin film, dry etching treatment, wet etching treatment, ashing treatment, plasma treatment, inverse sputtering treatment, or the like can be used. Alternatively, sandblasting treatment may be used for the etching of the thin film.

As an etching gas for the dry etching treatment, for example, a gas containing halogen can be used.

As the gas containing halogen, for example, an etching gas containing one or more of fluorine, chlorine, and bromine can be used. A fluorocarbon gas, a hydrofluorocarbon gas, a SF₆ gas, a Cl₂ gas, a BCl₃ gas, a SiCl₄ gas, a BBr₃ gas, and the like can be used alone or in combination. As the fluorocarbon gas, a gas represented by CₓF_{y} (y≤2x+2) can be used. Examples of the fluorocarbon gas satisfying y=2x+2 include saturated carbon fluoride compounds such as CF₄, C₂F₆, C₃F₈, C₄F₁₀, and C₅F₁₂. Examples of the fluorocarbon gas satisfying y<2x+2 include unsaturated carbon fluoride compounds such as C₂F₄, C₂F₂, C₃F₇, C₃F₄, C₄F₈, C₄F₆, C₄F₄, C₄F₂, C₅F₁₀, C₅F₈, C₅F₆, and C₅F₄. Examples of the hydrofluorocarbon gas include a CHF₃ gas and a CH₂F₂ gas.

In the case where the gas containing a halogen is used as the etching gas, an oxygen (O₂) gas, a carbonic acid gas, a nitrogen (N₂) gas, a helium gas, an argon gas, a hydrogen gas, a hydrocarbon gas, or the like can be added as appropriate.

A gas containing a hydrocarbon gas or a hydrogen gas and not containing a halogen gas can be used as the etching gas.

As the hydrocarbon gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used, for example.

In the case where the hydrocarbon gas is used as the etching gas, a nitrogen gas, a helium gas, an argon gas, a hydrogen gas, or the like can be added as appropriate.

As a dry etching apparatus, a capacitively coupled plasma (CCP) etching apparatus including parallel plate electrodes can be used. The capacitively coupled plasma etching apparatus including parallel plate electrodes may have a structure where high-frequency voltage is applied to one of the parallel plate electrodes. Alternatively, different high-frequency voltages may be applied to one of the parallel plate electrodes. Alternatively, high-frequency voltages with the same frequency may be applied to the parallel plate electrodes. Still further alternatively, high-frequency voltages with different frequencies may be applied to the parallel plate electrodes. A dry etching apparatus including a high-density plasma source can be used. As the dry etching apparatus including a high-density plasma source, an inductively coupled plasma (ICP) etching apparatus can be used, for example. The etching apparatus can be set as appropriate depending on an object to be etched.

First, the conductive layer 220 is formed over the insulating layer 210, and the insulating layer 280al, the insulating layer 280a2, the insulating layer 280b, the insulating layer 280c, a conductive film 240af, and a conductive film 240bf are sequentially formed over the conductive layer 220 (FIG. 14A).

Note that it is preferable that the top surface of the formed insulating layer 280 be planarized by planarization treatment by a chemical mechanical polishing (CMP) method (also referred to as CMP treatment). By the planarization treatment of the insulating layer 280, the surface on which the conductive layer 240 functioning as a wiring is to be formed can be made flat, whereby disconnection of the conductive layer 240 can be inhibited. Incidentally, it is acceptable that the planarization treatment is not performed, in which case the manufacturing cost can be reduced.

Next, an opening portion is formed in the conductive film 240bf, the conductive film 240af, the insulating layer 280c, the insulating layer 280b, the insulating layer 280a2, and the insulating layer 280al in a position overlapping with the conductive layer 220 (FIG. 14B). The opening portion 290_b is formed in the conductive film 240af and the conductive film 240bf, the opening portion 290_u is formed in the insulating layer 280c, an opening portion 290_ma is formed in the insulating layer 280b, and the opening portion 290_d is formed in the insulating layer 280a. In the subsequent etching, the width of the opening portion 290_ₘₐ is widened to be the opening portion 290_m. A depressed portion is formed in the conductive layer 220 at a position overlapping with the opening portion 290.

In FIG. 14B, it can be expressed that an opening portion having a continuous side surface is formed in the stacked-layer structure including the insulating layer 280al and the components thereover up to the conductive film 240bf. Since the opening portion has a high aspect ratio, anisotropic etching is preferably used for the formation of the opening portion. It is particularly preferable to use a dry etching method because it is suitable for microfabrication. The processing may be performed on the layers under different conditions.

Next, heat treatment may be performed. The heat treatment can be performed at higher than or equal to 100° C. and lower than or equal to 800° C., preferably higher than or equal to 250° C. and lower than or equal to 650° C., further preferably higher than or equal to 350° C. and lower than or equal to 550° C., for example. For example, the treatment time at a temperature higher than or equal to 350° C. and lower than or equal to 550° C. can be longer than or equal to 1 minute and shorter than or equal to 1 hour, or longer than or equal to 10 minutes and shorter than or equal to 30 minutes.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. By the above-described heat treatment, impurities such as water contained in the insulating layer 280, for example, can be reduced before the oxide semiconductor layer 230 is formed.

The gas used in the heat treatment preferably has high purity. For example, the amount of moisture contained in the gas used in the above heat treatment is preferably 1 ppb (0.001 ppm) or less, further preferably 0.1 ppb or less, still further preferably 0.05 ppb or less. The heat treatment using a highly purified gas can prevent the entry of moisture or the like into the insulating layer 280 or the like as much as possible.

In addition to or instead of the heat treatment, microwave plasma treatment may be performed.

In this specification and the like, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

The impurity concentration in the oxide semiconductor layer 230 is preferably reduced by performing microwave plasma treatment in an oxygen-containing atmosphere. Specific examples of impurities include hydrogen and carbon. Although the microwave plasma treatment in an oxygen-containing atmosphere is performed on the metal oxide in the above-described example, one embodiment of the present invention is not limited thereto. For example, the microwave plasma treatment in an oxygen-containing atmosphere may be performed on an insulating film, more specifically a silicon oxide film, which is positioned in the vicinity of the metal oxide. Furthermore, the crystallinity of the oxide semiconductor layer is sometimes increased by heat in the microwave plasma treatment.

The microwave plasma treatment is preferably performed under a reduced pressure, and the pressure is preferably higher than or equal to 10 Pa and lower than or equal to 1000 Pa, further preferably higher than or equal to 50 Pa and lower than or equal to 700 Pa, still further preferably higher than or equal to 100 Pa and lower than or equal to 400 Pa. The treatment temperature is preferably higher than or equal to room temperature (25° C.) and lower than or equal to 750° C., further preferably higher than or equal to 300° C. and lower than or equal to 500° C., and can be higher than or equal to 400° C. and lower than or equal to 450° C.

In the microwave plasma treatment, substrate heating may be performed. The substrate heating temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C.

The microwave plasma treatment can be performed using an oxygen gas and an argon gas, for example. For example, the oxygen flow rate ratio (O₂/(O2+Ar)) in the microwave plasma treatment is preferably higher than 0% and lower than or equal to 10%, further preferably higher than or equal to 0.5% and lower than or equal to 5%, still further preferably higher than or equal to 0.5% and lower than or equal to 3%, and is typically preferably 1%.

The microwave plasma treatment in an oxygen-containing atmosphere can convert an oxygen gas into plasma by using a high-frequency wave such as a microwave or an RF, and apply, to the oxide semiconductor layer, oxygen radicals that are generated by conversion of the oxygen gas into plasma. By the effects of plasma, a microwave, oxygen radicals, and the like, a defect in which hydrogen enters an oxygen vacancy (also referred to as V_{O}H in some cases) in the oxide semiconductor layer can be divided into an oxygen vacancy and hydrogen, and hydrogen which is an impurity can be removed from the oxide semiconductor layer. In this manner, V_{O}H contained in the oxide semiconductor layer can be reduced. At this time, carbon bonded to oxygen, hydrogen, or the like can also be removed in some cases. Performing the microwave plasma treatment in such a manner can reduce impurities such as carbon and hydrogen. Supplying the oxygen radicals to oxygen vacancies formed in the oxide semiconductor layer can further reduce oxygen vacancies in the oxide semiconductor layer.

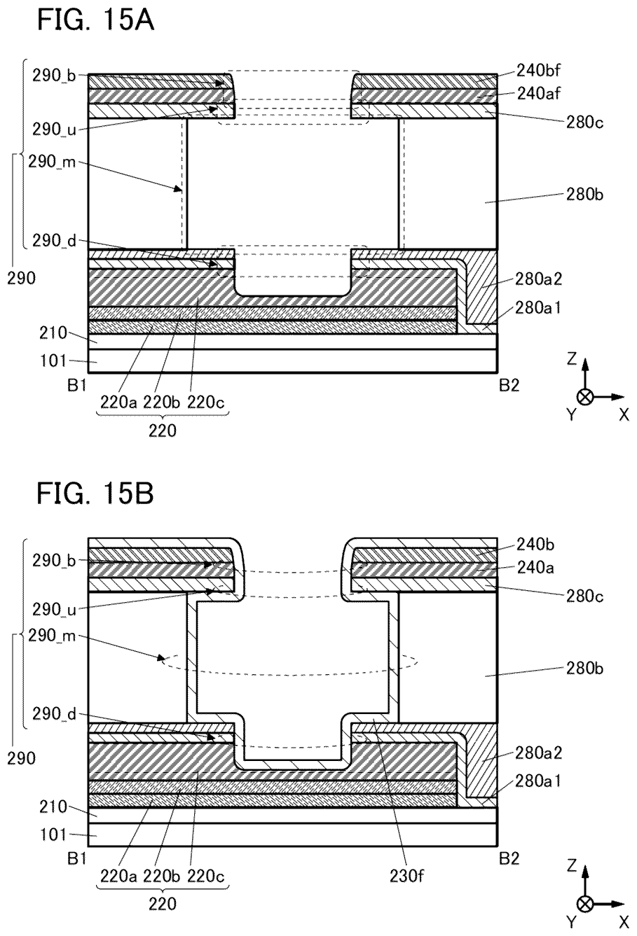

Next, etching treatment for increasing the width of the opening portion 290_ma in the insulating layer 280b is performed, so that the opening portion 290_m is formed in the insulating layer 280b(FIG. 15A). The etching treatment performed here is preferably isotropic etching. For example, in the case where silicon oxide or silicon oxynitride is used for the insulating layer 280b and silicon nitride is used for each of the insulating layers 280a1, 280a2, and 280c, the insulating layer 280b can be selectively etched by performing wet etching treatment using a solution containing hydrofluoric acid.

In the solution used for the wet etching, ammonium fluoride or the like may be mixed in addition to hydrofluoric acid.

Next, an oxide semiconductor film 230f is formed to cover the side surface of the opening portion 290_b in the conductive layers 240a and 240b, the side surface of the opening portion 290_u in the insulating layer 280c, the bottom surface of the insulating layer 280c, the side surface of the opening portion 290_m in the insulating layer 280b, the top surface of the insulating layer 280a2, the side surface of the opening portion 290_d in the insulating layer 280a2, and the depressed portion of the conductive layer 220 (FIG. 15B). The oxide semiconductor film 230f is a layer to be the oxide semiconductor layer 230.

The oxide semiconductor film 230f can also be formed by stacking a plurality of layers. The oxide semiconductor film 230f preferably has a high aspect ratio and high coverage on the sidewall and the bottom portion of the opening portion 290 with a minute opening diameter. Thus, at least some layers of the plurality of layers formed as the oxide semiconductor film 230f are preferably formed by a method that provides good coverage. Here, the oxide semiconductor film 230f is formed by an ALD method.

Heat treatment may be performed subsequent to the formation of the oxide semiconductor film 230f. By performing the heat treatment, impurities in the oxide semiconductor film 230f can be reduced, for example. In addition, the crystallinity of the oxide semiconductor film 230f is increased in some cases. Microwave plasma treatment may be performed subsequent to the formation of the oxide semiconductor film 230f. The microwave plasma treatment can reduce the impurities in the oxide semiconductor film 230f, for example. In addition, the crystallinity of the oxide semiconductor film 230f is increased in some cases.

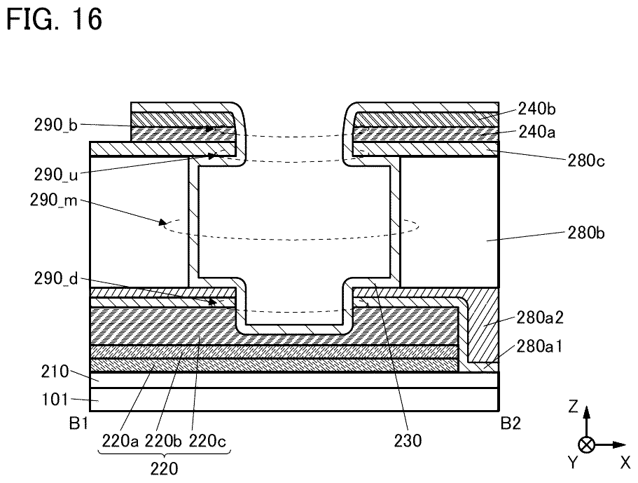

Next, the oxide semiconductor film 230f, the conductive film 240bf, and the conductive film 240af are processed into island shapes to form the oxide semiconductor layer 230, the conductive layer 240b, and the conductive layer 240a, respectively (FIG. 16). Here, the oxide semiconductor layer 230, the conductive layer 240b, and the conductive layer 240a can be processed collectively with use of the same mask.

Note that the steps of processing the oxide semiconductor film 230f, the conductive film 240bf, and the conductive film 240af into island shapes can be independently performed.

Next, the insulating layer 250 is formed over the oxide semiconductor layer 230 and the insulating layer 280. The insulating layer 250 is formed in contact with the oxide semiconductor layer 230.

Heat treatment may be performed subsequent to the formation of the insulating layer 250. Microwave plasma treatment may be performed subsequent to the formation of the insulating layer 250.

Then, the conductive layer 260 is formed over the insulating layer 250.

Through the above process, the semiconductor device illustrated in FIG. 7B can be manufactured.

### Variation Example 1 of Semiconductor Device

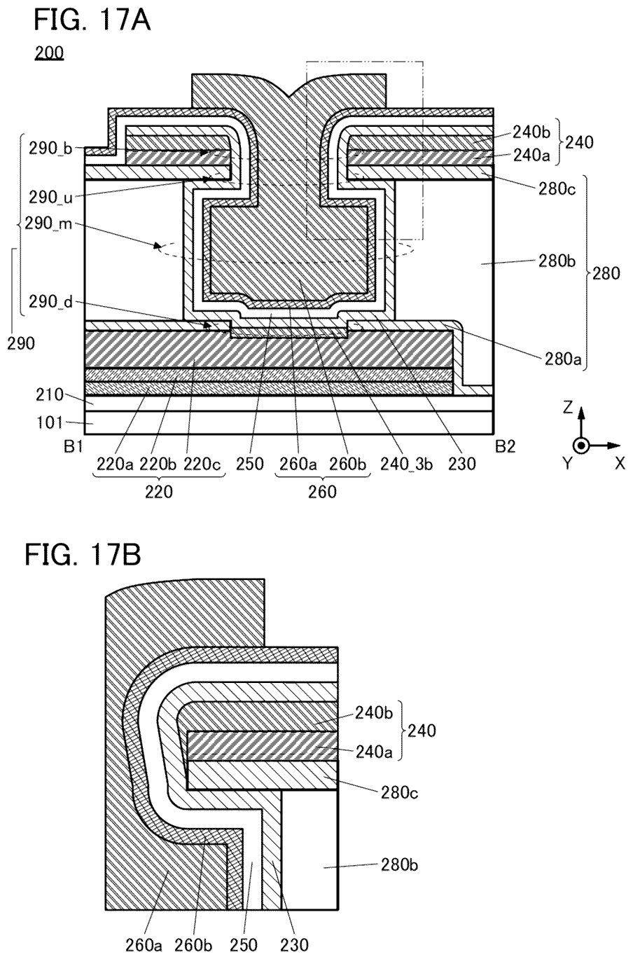

Next, a variation example of the semiconductor device is described with reference to FIGS. 17A and 17B.

The semiconductor device illustrated in FIG. 17A includes the transistor 200. In the transistor 200, the conductive film 240bf is not formed in the manufacturing process shown in FIG. 14A, and after an opening portion is provided in the insulating layer 280 and the conductive film 240af with reference to FIG. 14B, the conductive film 240bf is formed in the opening portion and over the conductive film 240af. At this time, when a highly anisotropic film formation method is employed for forming the conductive film 240bf, the conductive film 240bf is less likely to be formed on the side surface of the opening portion in the insulating layer 280, and the conductive film 240bf is formed over the conductive film 240af and the bottom of the opening portion.

With use of the above manufacturing method, the transistor 200 illustrated in FIG. 17A can be formed. In FIG. 17A, a conductive layer 240_3b is formed over the conductive layer 220. At the time of forming the conductive film 240bf, a portion formed over the conductive film 240af is the conductive layer 240b illustrated in FIG. 17A, and a portion formed over the conductive layer 220 at the bottom of the opening portion is the conductive layer 240_3b illustrated in FIG. 17A.

Note that the conductive film 240bf is not formed on the bottom of the opening portion in some cases depending on the depth of the opening portion and the width of the opening portion.

As illustrated in FIG. 17B, the conductive film 240bf may also be formed on the side surface of the opening portion in the conductive film 240af at the time of forming the conductive film 240bf. In that case, the conductive layer 240b covers a side surface of the conductive layer 240a as well as the top surface of the conductive layer 240a.

In FIG. 17B, the conductive layer 240b covers not only the side surface of the conductive layer 240a but also a side surface of the insulating layer 280c.

In the case where a conductive layer that is easily oxidized is used as the conductive layer 240a, oxidation of the conductive layer 240a can be inhibited with use of a conductive layer that is unlikely to be oxidized and covers the side surface of the conductive layer 240a as the conductive layer 240b.

This embodiment can be combined with any of the other embodiments and examples as appropriate. In this specification, in the case where a plurality of structure examples are shown in one embodiment, the structure examples can be combined as appropriate.

### Embodiment 2

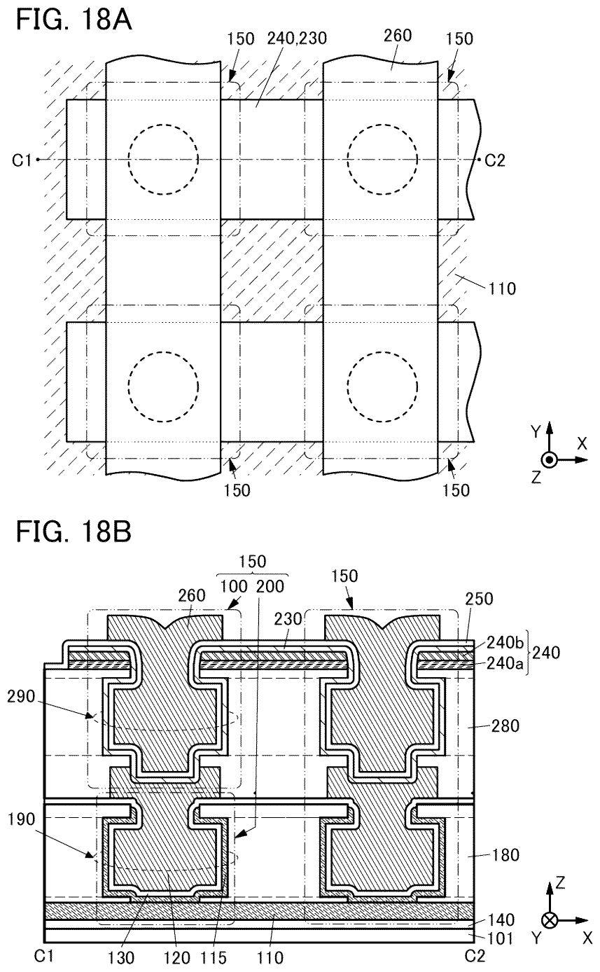

In this embodiment, memory devices of one embodiment of the present invention will be described with reference to FIGS. 18A and 18B, FIGS. 19A and 19B, and FIG. 20. The memory devices of one embodiment of the present invention each include a memory cell. The memory cell includes a transistor and a capacitor.

### Structure Example 1 of Memory Device

A structure of a memory device including a transistor and a capacitor is described with reference to FIGS. 18A and 18B. FIG. 18A is a plan view of a memory device including the transistor 200 and the capacitor 100. FIG. 18B is a cross-sectional view taken along a dashed-dotted line C1-C2 in FIG. 18A. FIG. 18A is a plan view showing an example in which four memory cells 150 are arranged in two rows in the Y direction and two columns in the X direction.

Each of the memory cells 150 includes the capacitor 100 and the transistor 200 over the capacitor 100.

The memory device illustrated in FIGS. 18A and 18B includes the insulating layer 140 over the substrate 101, the conductive layer 110 over the insulating layer 140, the plurality of memory cells 150 over the conductive layer 110, the insulating layer 180 over the conductive layer 110, and the insulating layer 280.

The conductive layer 110 functions as a wiring. The conductive layer 110 is shared by the plurality of memory cells 150.

The memory cell 150 includes the capacitor 100 over the conductive layer 110 and the transistor 200 over the capacitor 100.

The capacitor 100 includes the conductive layer 115 over the conductive layer 110, the insulating layer 130 over the conductive layer 115, and the conductive layer 120 over the insulating layer 130. The capacitor 100 described in the above embodiment can be used as the capacitor 100.

The insulating layer 280 is placed over the capacitor 100.

As the transistor 200, the transistor 200 described in the above embodiment can be used. Note that FIG. 18B shows an example in which the conductive layer 120 of the capacitor is used instead of the conductive layer 220 of the transistor 200 described in Embodiment 1. Alternatively, the conductive layer 220 can be formed to overlap with the conductive layer 120 without omitting the conductive layer 220.

As illustrated in FIG. 18B and the like, the transistor 200 is provided to overlap with the capacitor 100. The opening portion 290 where part of the components of the transistor 200 is provided includes a region overlapping with the opening portion 190 where part of the components of the capacitor 100 is provided. In particular, since the conductive layer 120 has a function of one of the source electrode and the drain electrode of the transistor 200 and a function of the upper electrode of the capacitor 100, the transistor 200 and the capacitor 100 share part of the structure. With such a structure, the transistor 200 and the capacitor 100 can be provided without a significant increase in the occupation area in the plan view. Thus, the area occupied by the memory cell 150 can be reduced, so that the memory cells 150 can be arranged densely and the memory capacity of the memory device can be increased. In other words, the memory device can be highly integrated.

When the transistor 200 is provided above the capacitor 100, the transistor 200 is not affected by heat treatment in manufacturing the capacitor 100. Thus, in the transistor 200, degradation of electrical characteristics such as variation in threshold voltage and an increase in parasitic resistance, and an increase in variation in electrical characteristics due to the degradation of the electrical characteristics can be inhibited.

### Structure Example 2 of Memory Device

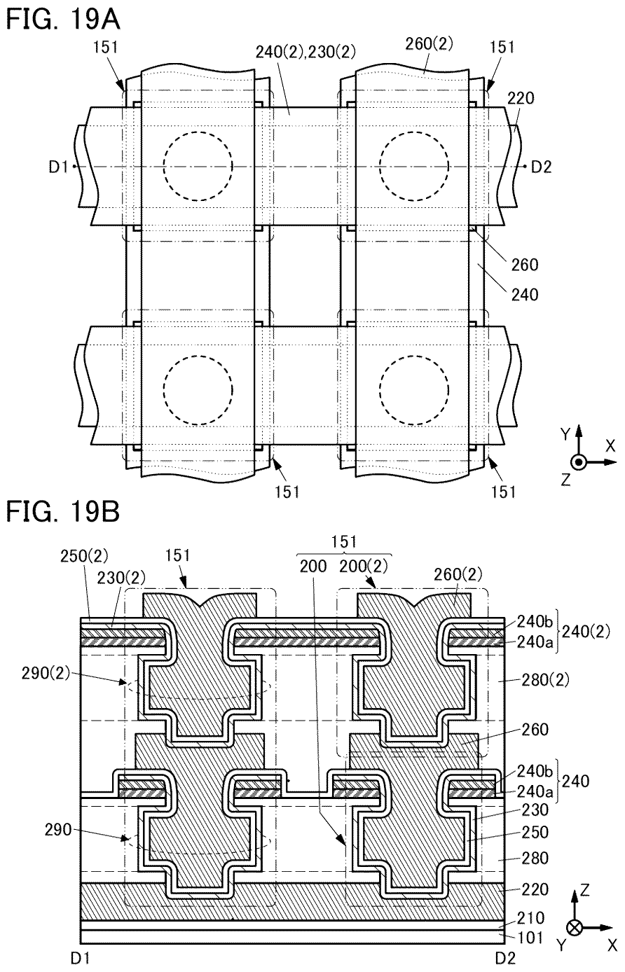

A structure of a memory device including two transistors is described with reference to FIGS. 19A and 19B. FIG. 19A is a plan view of a memory device including two transistors 200. FIG. 19B is a cross-sectional view taken along a dashed-dotted line D1-D2 in FIG. 19A. FIG. 19A is a plan view showing an example in which four memory cells 151 are arranged in two rows in the Y direction and two columns in the X direction.

Each of the memory cells 151 includes two transistors 200 (the transistor 200 and a transistor 200(2)).

The memory device illustrated in FIGS. 19A and 19B includes the insulating layer 210 over the substrate 101, the plurality of memory cells 151 over the insulating layer 210, the insulating layer 180 over the insulating layer 210, and the insulating layer 280.

The memory cell 151 includes the transistor 200 over the insulating layer 210 and the transistor 200(2) over the transistor 200.

The transistor 200 described in the above embodiment can be used as each of the transistor 200 and the transistor 200(2).

An insulating layer 280(2) is placed over the transistor 200. For the structure, material, and the like of the insulating layer 280(2), the structure, material, and the like of the insulating layer 280 can be referred to.

The oxide semiconductor layer 230, the conductive layer 240, the conductive layer 260, and the insulating layer 250 included in the transistor 200(2) are referred to as an oxide semiconductor layer 230(2), a conductive layer 240(2), a conductive layer 260(2), and an insulating layer 250(2), respectively. The oxide semiconductor layer 230(2), the insulating layer 250(2), and the conductive layer 260(2) each include a portion positioned in an opening portion 290(2) included in the insulating layer 280(2) and the conductive layer 240.

Note that the transistor 200(2) illustrated in FIG. 19B uses the conductive layer 260 of the transistor 200 without providing the conductive layer 220 described in Embodiment 1. Alternatively, the conductive layer 220 of the transistor 200(2) can be formed to overlap with the conductive layer 260 of the transistor 200 without omitting the conductive layer 220 of the transistor 200(2).

As illustrated in FIGS. 19A and 19B and the like, two transistors 200 are provided to overlap with each other. The opening portion 290 where part of the components of the transistor 200 is provided includes a region overlapping with the opening portion 290(2) where part of the components of the transistor 200(2) is provided. With such a structure, two transistors 200 can be provided without a significant increase in the occupation area in the plan view. Thus, the area occupied by the memory cell 151 can be reduced, so that the memory cells 151 can be arranged densely and the memory capacity of the memory device can be increased.

### Structure Example 3 of Memory Device

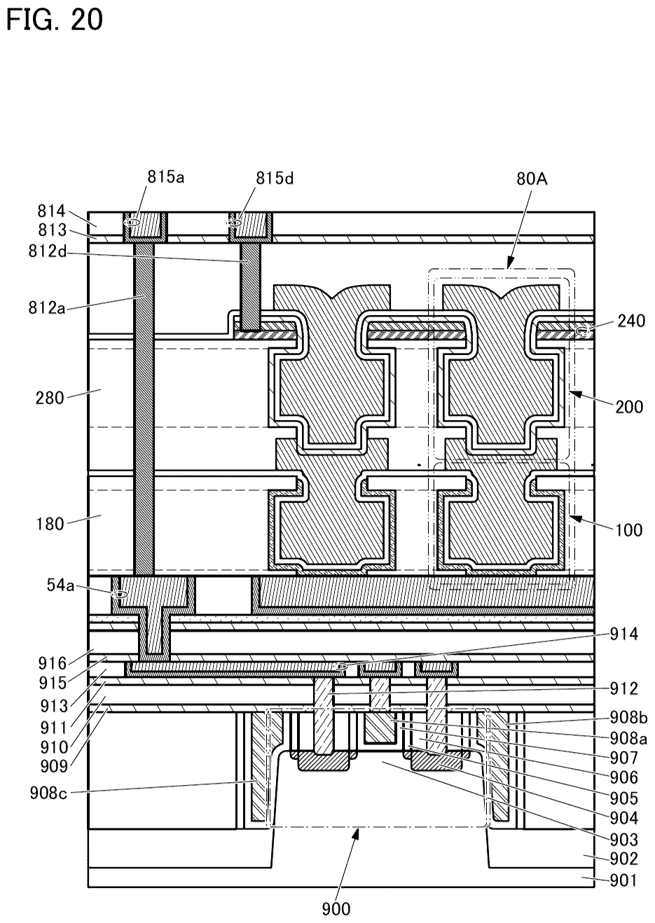

The memory device of one embodiment of the present invention is described with reference to FIG. 20. The memory device illustrated in FIG. 20 includes a memory cell 80A. The structure of the memory cell 150 illustrated in FIGS. 18A and 18B can be used as the structure of the memory cell 80A, for example.

The memory device illustrated in FIG. 20 includes the memory cell 80A above a Si transistor 900. The Si transistor 900 is one of transistors included in a peripheral circuit of the memory cell, for example.

The Si transistor 900 is described. The Si transistor 900 is a Fin-type transistor. FIG. 20 shows a schematic cross-sectional view of the Si transistor 900 in the channel length direction. The Si transistor 900 is provided on a substrate 901 and includes a conductive layer 908a functioning as a gate electrode, an insulating layer 907 functioning as a gate insulating film, a semiconductor region 903 functioning as a channel formation region, and a low-resistance region 904 functioning as a source region or a drain region.

As the substrate 901, a silicon substrate or an SOI substrate can be used, for example.

An element isolation layer 902, an insulating layer 905, a dummy gate electrode 908b, and a dummy gate electrode 908c are provided over the substrate 901. The insulating layer 905 functions as a sidewall. An insulating layer 906, an insulating layer 909, an insulating layer 910, an insulating layer 911, an insulating layer 913, an insulating layer 915, and an insulating layer 916 are provided, and the insulating layers each function as an interlayer insulating film. The insulating layer 909, the insulating layer 911, and the insulating layer 915 each function also as a barrier film. A conductive layer 912 and a conductive layer 914 each function as a plug, an electrode, or a wiring.

One of a source and a drain of the Si transistor 900 (here, the low-resistance region 904) is connected to the memory cell 80A through the conductive layer.

Part of a conductive layer 54a is provided so as to be embedded in the insulating layer 916. The conductive layer 54a is connected to the Si transistor 900 through the conductive layer 914.

An insulating layer 813 and an insulating layer 814 are provided over the memory cell 80A. As each of the insulating layer 813 and the insulating layer 814, an insulating film having a function of inhibiting transmission of oxygen and impurities such as water and hydrogen, an insulating film having a function of capturing or fixing hydrogen, an insulating film having a barrier property against hydrogen, or an insulating film having a barrier property against oxygen is preferably used. With use of these insulating films, diffusion of hydrogen into the semiconductor layer of the transistor included in the memory cell 80A can be inhibited.

A conductive layer 815a and a conductive layer 815d are provided to be embedded in the insulating layer 813 and the insulating layer 814. The conductive layer 815a and the conductive layer 815d can each be formed as a single layer or a stacked layer. For example, the conductive layer 815a and the conductive layer 815d can each have a two-layer structure including tungsten over titanium nitride. Since a conductive material with high conductivity, such as tungsten, can be used, wiring resistance of each of the conductive layers 815a and 815d can be reduced. The conductive layer 815a and the conductive layer 815d can each have a three-layer structure including tantalum nitride, titanium nitride, and tungsten from the lower layer. Alternatively, the conductive layer 815a and the conductive layer 815d can each have a four-layer structure including tantalum nitride, tantalum, titanium nitride, and tungsten from the lower layer. Alternatively, the conductive layer 815a and the conductive layer 815d can each have a four-layer structure including tantalum, tantalum nitride, titanium nitride, and tungsten from the lower layer.

A conductive layer 812a is provided to connect the conductive layer 815a and the conductive layer 54a.

A conductive layer 812d is provided to connect the conductive layer 815d and the conductive layer 240.

This embodiment can be combined with any of the other embodiments and examples as appropriate.

### Embodiment 3

In this embodiment, an oxide semiconductor layer that can be used as a semiconductor layer of a transistor will be described.

Materials that can be used for the semiconductor layer of the transistor are described.

A semiconductor material is not particularly limited. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor (OS). These semiconductor materials may contain an impurity as a dopant.

There is no particular limitation on the crystallinity of a semiconductor material, and any of an amorphous semiconductor, a single crystal semiconductor, and a semiconductor having crystallinity other than single crystal (a microcrystalline semiconductor, a polycrystalline semiconductor, or a semiconductor partly including crystal regions) can be used. A single crystal semiconductor or a semiconductor having crystallinity is preferably used, in which case deterioration of the transistor characteristics can be inhibited.

For example, silicon can be used for the semiconductor layer. Examples of silicon include single crystal silicon, polycrystalline silicon, microcrystalline silicon, and amorphous silicon. An example of polycrystalline silicon is low-temperature polysilicon (LTPS).

A metal oxide that is suitable for an oxide semiconductor layer included in an OS transistor is described.

There is no particular limitation on the crystallinity of the metal oxide, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

When oxygen vacancies (V_{O}) and impurities are in a channel formation region of a metal oxide in an OS transistor, electrical characteristics of the OS transistor easily vary and the reliability thereof might worsen. In some cases, a defect that is an oxygen vacancy into which hydrogen enters (hereinafter, sometimes referred to as V_{O}H) is formed and an electron functioning as a carrier is generated. Thus, if the channel formation region of the metal oxide includes oxygen vacancies, the OS transistor tends to be normally on. Therefore, the oxygen vacancies and the impurities are preferably reduced as much as possible in the channel formation region in the metal oxide. In other words, the metal oxide preferably includes an i-type (intrinsic) or substantially i-type channel formation region with a low carrier concentration.

Meanwhile, preferably, a source region and a drain region of the OS transistor include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

The band gap of a metal oxide functioning as a semiconductor is preferably greater than or equal to 2.0 eV, further preferably greater than or equal to 2.5 eV. The use of a metal oxide having a wide band gap for the oxide semiconductor layer can reduce the off-state current of the transistor. The off-state current of the OS transistor is small, so that power consumption of the semiconductor device can be sufficiently reduced. The OS transistor has high frequency characteristics, which enables the semiconductor device to operate at high speed.

Examples of the metal oxide that can be used for the semiconductor layer of the OS transistor include indium oxide.

Examples of the metal oxide that can be used for the semiconductor layer of the OS transistor include an oxide containing one or more elements selected from In, Sn, Zn, Ga, Al, W, and Ti. In these oxides, the content percentage of one or more elements selected from In, Sn, Zn, Ga, Al, W, and Ti is preferably higher than or equal to 1 atomic %, for example.

As the metal oxide, in addition to indium oxide described above, it is possible to use zinc oxide, tin oxide, indium zinc oxide (In—Zn oxide), indium tin oxide (In—Sn oxide), indium tungsten oxide (In—W oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO), for example. Alternatively, indium tin oxide containing silicon, gallium tin oxide (Ga—Sn oxide), aluminum tin oxide (Al—Sn oxide), or the like can be used.

Specifically, an atomic ratio of In:Zn=1:1 or in the neighborhood thereof, an atomic ratio of In:Zn=2:1 or in the neighborhood thereof, or an atomic ratio of In:Zn=4:1 or in the neighborhood thereof can be employed as the composition. Note that the neighborhood of the atomic ratio includes ±30% of an intended atomic ratio.

Specifically, an In-M-Zn metal oxide having an atomic ratio of In:M:Zn=1:1:1 or the neighborhood thereof, In:M:Zn=1:1:1.2 or the neighborhood thereof, In:M:Zn=1:1:0.5 or the neighborhood thereof, In:M:Zn=1:1:2 or the neighborhood thereof, In:M:Zn=4:2:3 or the neighborhood thereof, In:M:Zn=1:3:2 or the neighborhood thereof, or In:M:Zn=1:3:4 or the neighborhood thereof is used as the composition. Alternatively, a metal oxide containing a slight amount of the element M can have an atomic ratio of, for example, In:M:Zn=4:0.1:1 or the neighborhood thereof, In:M:Zn=2:0.1:1 or the neighborhood thereof, or In:M:Zn=1:0.1:1 or the neighborhood thereof. Examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

Analysis of the composition of a metal oxide can be performed by energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES), for example. Alternatively, these methods may be combined to be employed for analysis. As for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

Amorphous (including a completely amorphous structure), c-axis-aligned crystalline (CAAC), nanocrystalline (nc), cloud-aligned composite (CAC), single-crystal, polycrystalline (poly crystal) structures, and the like can be given as examples of the crystal structure of the metal oxide functioning as a semiconductor.

Increasing the proportion of zinc atoms to the sum of atoms of the metal elements that are the main components in the metal oxide enables the metal oxide to have high crystallinity, so that diffusion of impurities in the metal oxide can be inhibited. Consequently, a change in the electrical characteristics of the transistor can be reduced to improve the reliability of the transistor.

Increasing the proportion of the element M atoms to the sum of atoms of the metal elements that are the main components in the metal oxide can inhibit formation of oxygen vacancies in the metal oxide. Accordingly, generation of carriers due to oxygen vacancies is inhibited, which makes the off-state current of the transistor low. Furthermore, a change in the electrical characteristics of the transistor can be reduced to improve the reliability of the transistor.

Increasing the proportion of indium atoms to the sum of atoms of all the metal elements in the metal oxide can increase the field-effect mobility of the transistor. Typically, a transistor using single crystal indium oxide or polycrystal indium oxide for a semiconductor layer can have significantly increased field-effect mobility. A transistor using single crystal indium oxide or polycrystal indium oxide for a semiconductor layer can also have favorable frequency characteristics.

The oxide semiconductor layer of one embodiment of the present invention includes, for example, a metal oxide having crystallinity. Examples of the structure of a metal oxide having crystallinity include a CAAC structure, a polycrystal structure, and an nc structure. By using a metal oxide having crystallinity for the oxide semiconductor layer, the density of defect states in the oxide semiconductor layer can be reduced. This can improve the reliability of the transistor including the oxide semiconductor layer of one embodiment of the present invention, thereby improving the reliability of a semiconductor device including the transistor.

For the semiconductor device of this embodiment, a transistor including a different semiconductor material in its channel formation region may be used. Examples of the different semiconductor material include a single-element semiconductor and a compound semiconductor.

Examples of the single-element semiconductor that can be used as the semiconductor material include silicon and germanium. Examples of silicon that can be used as the semiconductor material include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic crystal structure. Other examples of the compound semiconductor include an organic semiconductor and a nitride semiconductor. Note that the above-described metal oxide is also one kind of the compound semiconductor. These semiconductor materials may contain an impurity as a dopant.

A layered material functioning as a semiconductor can also be used for the semiconductor layer. The layered material generally refers to a group of materials having a layered crystal structure. The layered material has high electrical conductivity in a unit layer, that is, high two-dimensional electrical conductivity. When a material that functions as a semiconductor and has high two-dimensional electrical conductivity is used for a channel formation region, the transistor can have high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a channel formation region of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

An indium oxide film that can be used for the semiconductor layer of the transistor included in the display device of one embodiment of the present invention is described.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga—Zn oxide (hereinafter, also referred to as IGZO) or zinc oxide.

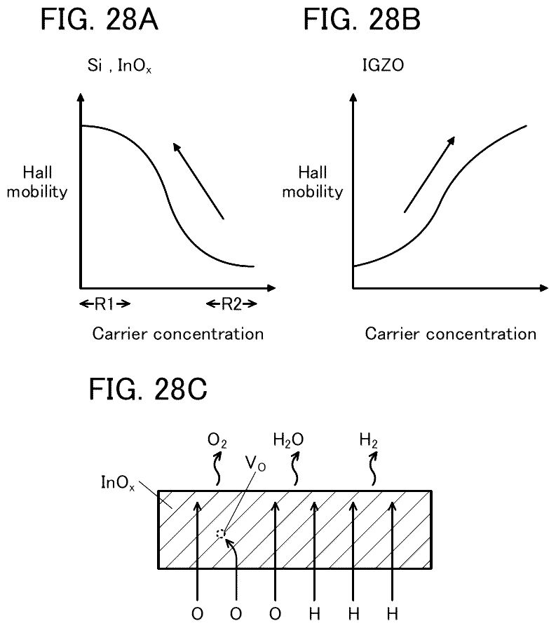

The dependence of the Hall mobility on the carrier concentration of indium oxide, silicon, and IGZO will be described. FIG. 28A is a schematic view showing the dependence of the Hall mobility on the carrier concentration of silicon (Si) and indium oxide (InO_{X}), and FIG. 28B is a schematic view showing the dependence of the Hall mobility on the carrier concentration of IGZO.

As indicated by an arrow in FIG. 28B, IGZO has a tendency in which the Hall mobility is higher as the carrier concentration is higher. By contrast, as indicated by an arrow in FIG. 28A, indium oxide has a tendency in which the Hall mobility is higher as the carrier concentration is lower (see Non-Patent Document 3). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 28A are based on the assumption of single crystal indium oxide; thus, the characteristics of non-single-crystal (e.g., polycrystal) indium oxide are sometimes different from those in FIG. 28A.

In FIG. 28A, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×1022 cm⁻³. The adequately increased carrier concentration will decrease the resistivity to 1×10⁻⁴(Ω·cm or lower.

A region of indium oxide where the carrier concentration falls within the range R2 can include an element that increases the carrier concentration. For example, the region preferably includes the same element as a source electrode and a drain electrode of a transistor. Examples of the element that increases the carrier concentration include titanium, zirconium, hafnium, tantalum, tungsten, molybdenum, tin, silicon, and boron. It is particularly preferable that an oxide of the element have conductivity or semiconductor properties.

In this manner, the region with a low carrier concentration and the region with a high carrier concentration of indium oxide are used as a channel formation region and source and drain regions, respectively, of a transistor. That is, indium oxide can be regarded as an oxide whose valence electron can be controlled. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 28A, are separately formed in an indium oxide film, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually.

With use of the above technical idea, a transistor containing indium oxide in this specification and the like has two or more, preferably three or more, further preferably four or more, and most preferably all of the following features (1) to (5): (1) high on-state current (i.e., high mobility); (2) low off-state current; (3) normally-off characteristics; (4) high reliability; and (5) high cutoff frequency (fT). For example, in this specification and the like, a transistor containing indium oxide has high mobility and low off-state current, and can be normally off. This transistor is different from a normally-on transistor having high mobility.

Next, an indium oxide film used for a transistor will be described. The indium oxide film preferably has crystallinity (i.e., has a crystal grain). Examples of a film having a crystal grain include a single crystal film, a polycrystal film, and an amorphous film having a crystal grain (also referred to as a microcrystal film). In particular, the indium oxide film is preferably a polycrystal film, further preferably a single crystal film. A single crystal film does not have a crystal grain boundary (also referred to as a grain boundary). Impurities that block the carrier flow (typically, an insulating impurity, an insulating oxide, or the like) are likely to be segregated at a crystal grain boundary. The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. In the case where the crystal grain boundary is neither included nor observed in a channel formation region of a transistor including a polycrystal indium oxide film, the channel formation region is positioned in a single crystal region included in the polycrystal film and thus the transistor can be regarded as a transistor containing single crystal indium oxide.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single crystal film. A semiconductor layer where the direction of a crystal axis is continuously changed with another crystal axis or a crystal orientation as a rotation axis in one crystal grain in a channel formation region can also be referred to as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A current path in a channel formation region is the shortest distance between a source electrode and a drain electrode. Thus, a crystal grain, a crystal grain boundary, a crystal axis, a crystal orientation, or the like in a channel formation region can be confirmed in observation of a cross section including a semiconductor layer, a source electrode, and a drain electrode.

The impurity concentration in an indium oxide film in a channel formation region is preferably as low as possible. Impurities in the indium oxide film in the channel formation region can function as a carrier scattering source and cause a reduction in field-effect mobility. Such impurities might inhibit crystal growth of the indium oxide film. Examples of the impurities for the indium oxide film include boron and silicon. The concentrations of these impurities in the indium oxide film are each preferably lower than or equal to 0.1%, further preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film in the channel formation region may contain an element that can form a trivalent cation like indium as long as the cubic crystal structure (bixbyite structure) is retained. Examples of the element include Group 13 elements such as gallium and aluminum and Group 3 elements in the periodic table. Since these elements exist mainly as trivalent cations in oxides, the carrier concentration of indium oxide can be kept low.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. As shown in FIG. 28C, oxygen (O) diffusing in an indium oxide film (denoted as InO_{X}) is transmitted through the indium oxide film and released as an oxygen molecule (O₂). When reacting with hydrogen contained in the film, oxygen is released as a water molecule (H₂O) in some cases. In the case where the film includes oxygen vacancies (V_{O}), the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

As shown in FIG. 28C, hydrogen diffuses in the indium oxide film. Hydrogen diffusing into the indium oxide film from the outside is transmitted through the indium oxide film and is released as a hydrogen molecule (H₂). When reacting with oxygen contained in the film, hydrogen is released as a water molecule.

A transistor including an indium oxide film is an accumulation-type transistor in which electrons are majority carriers. Assuming that the relaxation time of carriers is constant, the electron (carrier) mobility is higher as the effective mass of electrons (carriers) is smaller. That is, a transistor containing an indium oxide with a small effective mass of electrons can have high on-state current or high field-effect mobility.

Table 1 shows the effective mass in each of single crystal indium oxide (here, In₂O₃) and single crystal silicon (Si). As shown in Table 1, indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125° C., and can be lower than or equal to 1 aA (1×10⁻¹⁸ A) or lower than or equal to 1 zA (1×10⁻²¹ A) at room temperature (25° C.). Since indium oxide has a smaller effective mass of electrons and a larger effective mass of holes than silicon as shown in Table 1, a transistor containing indium oxide can have higher field-effect mobility and lower off-state current than a Si transistor.

TABLE 1
Effective mass of In₂O₃

| Electron | | | |
|---|---|---|---|
| [100]direction | [110]direction | [111]direction | Hole |
| 0.17 | 0.18 | 0.19 | 3.56 |

Effective mass of Si

| Electron | Hole |
|---|---|
| 0.26 | 0.17 |

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In this case, the crystallinity of the indium oxide film can be increased. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Aa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2% to 2%, which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO.

This embodiment can be combined with any of the other embodiments and examples as appropriate.

### Embodiment 4

In this embodiment, the semiconductor device 8000 of one embodiment of the present invention will be described. The semiconductor device 8000 can function as a memory device.

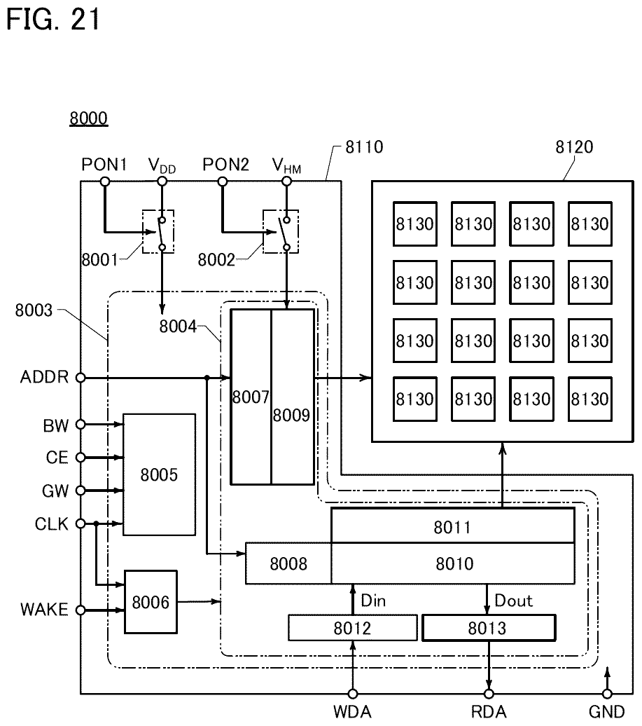

FIG. 21 is a block diagram illustrating a structure example of the semiconductor device 8000. The semiconductor device 8000 illustrated in FIG. 21 includes a driver circuit 8110 and a memory array 8120. The memory array 8120 includes at least one memory cell 8130. FIG. 21 illustrates an example in which the memory array 8120 includes a plurality of memory cells 8130 arranged in a matrix.

The memory device described in Embodiment 2 can be used for the memory cell 8130.

The driver circuit 8110 includes a power switch (PSW) 8001, a PSW 8002, and a peripheral circuit 8003. The peripheral circuit 8003 includes a peripheral circuit 8004, a control circuit 8005, and a voltage generator circuit 8006.

In the semiconductor device 8000, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 8005.

The control circuit 8005 is a logic circuit having a function of controlling the overall operation of the semiconductor device 8000. For example, the control circuit 8005 performs logical operation on the signals CE, GW, and BW to determine the operating mode (e.g., write operation or read operation) of the semiconductor device 8000. The control circuit 8005 generates a control signal for the peripheral circuit 8004 so that the operating mode is executed.

The voltage generator circuit 8006 has a function of generating negative voltage. The signal WAKE has a function of controlling the input of the signal CLK to the voltage generator circuit 8006. For example, when an H-level signal is applied as the signal WAKE, the signal CLK is input to the voltage generator circuit 8006, and the voltage generator circuit 8006 generates negative voltage.

The peripheral circuit 8004 is a circuit for writing and reading data to/from the memory cell 8130. The peripheral circuit 8004 includes a row decoder 8007, a column decoder 8008, a row driver 8009, a column driver 8010, a sense amplifier 8011, an input circuit 8012, and an output circuit 8013.

The row decoder 8007 and the column decoder 8008 have a function of decoding the signal ADDR. The row decoder 8007 is a circuit for specifying a row to be accessed. The column decoder 8008 is a circuit for specifying a column to be accessed. The row driver 8009 has a function of selecting the row specified by the row decoder 8007. The column driver 8010 has a function of writing data to the memory cell 8130, reading data from the memory cell 8130, and retaining the read data, for example.

The input circuit 8012 has a function of retaining the signal WDA. Data retained in the input circuit 8012 is output to the column driver 8010. Data output from the input circuit 8012 is data (Din) written to the memory cell 8130. Data (Dout) read from the memory cell 8130 by the column driver 8010 is output to the output circuit 8013. The output circuit 8013 has a function of retaining Dout. Moreover, the output circuit 8013 has a function of outputting Dout to the outside of the semiconductor device 8000. The data output from the output circuit 8013 is the signal RDA.

The PSW 8001 has a function of controlling the supply of VDD to the peripheral circuit 8003. The PSW 8002 has a function of controlling the supply of VHM to the row driver 8009. Here, in the semiconductor device 8000, a high power supply potential is VDD and a low power supply potential is GND (ground potential). In addition, VHM is a high power supply potential used for setting a word line to high level, and is higher than VDD. The on/off state of the PSW 8001 is controlled by the signal PON1, and the on/off state of the PSW 8002 is controlled by the signal PON2. The number of power domains to which VDD is supplied is one in the peripheral circuit 8003 in FIG. 21 but can be more than one. In that case, a power switch is provided for each power domain.

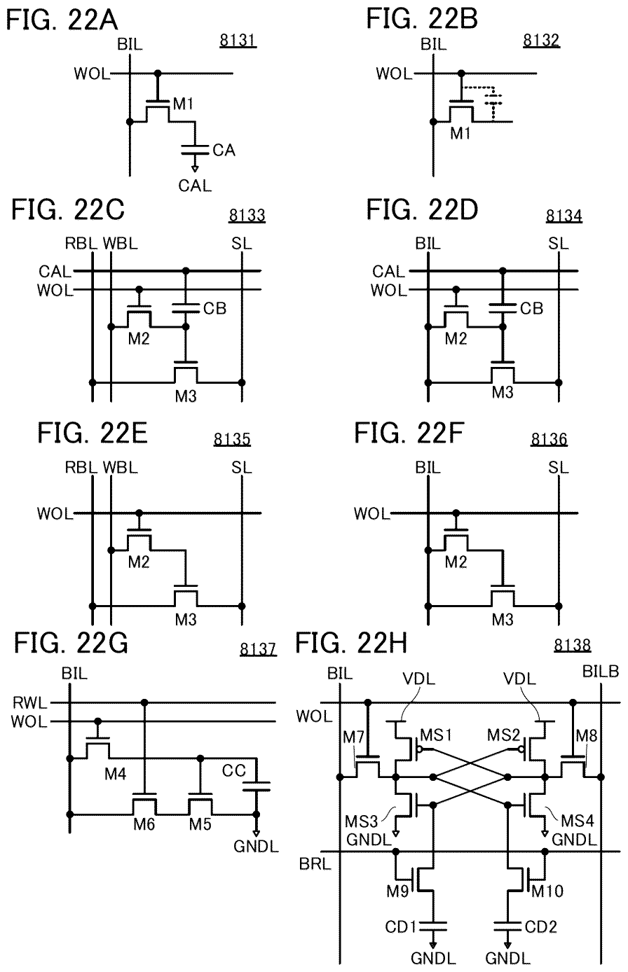

Other structure examples of other memory cells each of which can be used as the memory cell 8130 are described with reference to FIGS. 22A to 22H.

### [DOSRAM]

FIG. 22A illustrates a circuit structure example of a memory cell for a DRAM (Dynamic Random Access Memory). In this specification and the like, a DRAM using an OS transistor is referred to as a dynamic oxide semiconductor random access memory (DOSRAM). A memory cell 8131 includes the transistor M1 and the capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (referred to as a reference potential in some cases) is preferably applied to the wiring CAL.

Data writing and data reading are performed in such a manner that a high-level potential is applied to the wiring WOL to turn on the transistor M1 and establish electrical continuity between the wiring BIL and the first terminal of the capacitor CA (make a state where current can flow therethrough).

The memory cell that can be used as the memory cell 8130 is not limited to the memory cell 8131, and the circuit structure can be changed. For example, a memory cell 8132 illustrated in FIG. 22B may be used. The memory cell 8132 is an example including neither the capacitor CA nor the wiring CAL. The first terminal of the transistor M1 is in an electrically floating state.

In the memory cell 8132, a potential written through the transistor M1 is retained in a capacitor (also referred to as parasitic capacitance) between the first terminal and the gate, which is shown by a dashed line. With such a structure, the structure of the memory cell can be greatly simplified.

Note that an OS transistor is preferably used as the transistor M1. An OS transistor has a characteristic of extremely low off-state current. The use of an OS transistor as the transistor M1 enables extremely low leakage current of the transistor M1. That is, with use of the transistor M1, written data can be retained for a long time, and thus the frequency of refresh operation for the memory cell can be decreased. Alternatively, refresh operation for the memory cell can be omitted. In addition, owing to extremely low leakage current, multilevel data or analog data can be retained in the memory cells 8131 and 8132.

### [NOSRAM]

FIG. 22C illustrates a circuit structure example of a gain-cell memory cell including two transistors and one capacitor. A memory cell 8133 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retention, and data reading, a low-level potential (sometimes referred to as a reference potential) is preferably applied to the wiring CAL.

Data writing is performed in such a manner that a high-level potential is applied to the wiring WOL to turn on the transistor M2 and establish electrical continuity between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. Current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit structure example of the memory cell is illustrated in FIG. 22D. In a memory cell 8134, one wiring BIL is provided instead of the wiring WBL and the wiring RBL in the memory cell 8133, and the second terminal of the transistor M2 and the first terminal of the transistor M3 are electrically connected to the wiring BIL. In other words, one wiring BIL operates as the write bit line and the read bit line in the memory cell 8134.

A memory cell 8135 illustrated in FIG. 22E is an example in which the capacitor CB and the wiring CAL in the memory cell 8133 are omitted. A memory cell 8136 illustrated in FIG. 22F is an example in which the capacitor CB and the wiring CAL in the memory cell 8134 are omitted. Such structures enable high integration of memory cells.

Note that an OS transistor is preferably used as at least the transistor M2. In particular, an OS transistor is preferably used as each of the transistors M2 and M3.

Since the OS transistor has a characteristic of extremely low off-state current, written data can be retained for a long time with use of the transistor M2, and thus the frequency of refresh operation for the memory cell can be decreased. Alternatively, refresh operation for the memory cell can be omitted. In addition, owing to extremely low leakage current, multilevel data or analog data can be retained in the memory cells 8133, 8134, 8135, and 8136.

The memory cells 8133, 8134, 8135, and 8136 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with only n-type transistors.

FIG. 22G illustrates a gain memory cell 8137 including three transistors and one capacitor. The memory cell 8137 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4 and establish electrical continuity between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than the OS transistor depending on the crystal state of silicon used in a semiconductor layer, for example.

When OS transistors are used as the transistors M5 and M6, the memory cell can be configured with only n-type transistors.

### [OS-SRAM]

FIG. 22H illustrates an example of a static random access memory (SRAM) using an OS transistor. In this specification and the like, an SRAM using an OS transistor is referred to as an oxide semiconductor SRAM (OS-SRAM). A memory cell 8138 illustrated in FIG. 22H is a memory cell of an SRAM capable of backup operation.

The memory cell 8138 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. The gate of the transistor M9 is connected to a wiring BRL. A second terminal of the transistor M10 is connected to a first terminal of the capacitor CD2. The gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 8138, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistors M9 and M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is illustrated. First, the wiring BIL and the wiring BILB are precharged with a predetermined potential. Then, a high-level potential is applied to the wiring WOL and the wiring BRL. At this time, the potential of the first terminal of the capacitor CD1 is refreshed by the inverter loop in the memory cell 8138 and output to the wiring BILB. Furthermore, the potential of the first terminal of the capacitor CD2 is refreshed by the inverter loop in the memory cell 8138 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with use of the transistors M7 to M10, written data can be retained for a long time, and thus the frequency of refresh operation for the memory cell can be decreased. Alternatively, refresh operation for the memory cell can be omitted.

Note that the transistors MS1 to MS4 may be Si transistors.

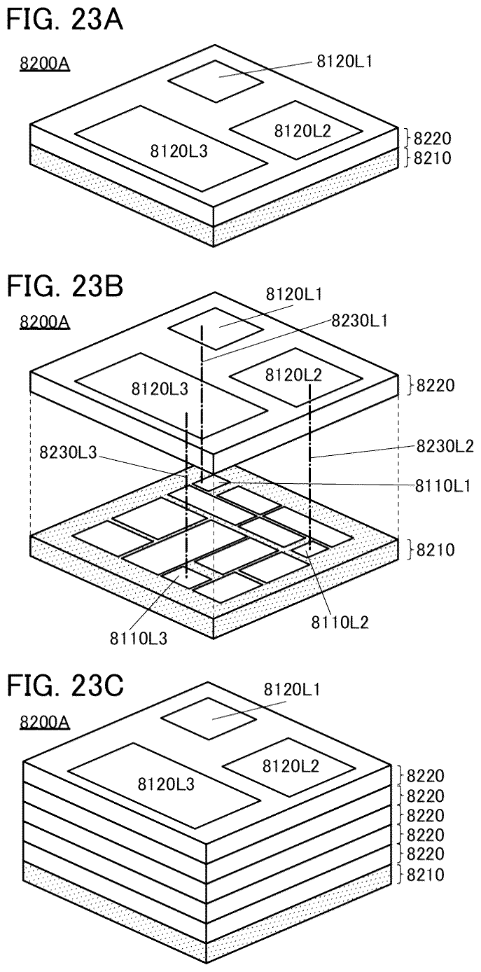

FIGS. 23A and 23C are perspective views of a semiconductor device 8200A. The semiconductor device 8200A includes a layer 8220 provided with memory arrays over the arithmetic device 8210. A memory array 8120L1, a memory array 8120L2, and a memory array 8120L3 are provided in the layer 8220. The arithmetic device 8210 and each of the memory arrays overlap with each other. For easy understanding of the structure of the semiconductor device 8200A, the arithmetic device 8210 and the layer 8220 are separately illustrated in FIG. 23B. Note that CPU (Central Processing Unit), GPU (Graphics Processing Unit), and the like can be used for the arithmetic device 8210, for example.

Overlapping the arithmetic device 8210 and the layer 8220 including the memory arrays can shorten the connection distance therebetween. Accordingly, the communication speed therebetween can be increased. Moreover, a short connection distance leads to lower power consumption.

As a method for stacking the layer 8220 including the memory arrays and the arithmetic device 8210, either of the following methods may be employed: a method in which the layer 8220 including the memory arrays is stacked directly on the arithmetic device 8210, which is also referred to as monolithic stacking, and a method in which the arithmetic device 8210 and the layer 8220 are formed over two different substrates, the substrates are bonded to each other, and the arithmetic device 8210 and the layer 8220 are connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 8210 does not include the cache and the memory arrays 8120L1, 8120L2, and 8120L3 provided in the layer 8220 are each used as a cache. In this case, for example, the memory array 8120L1, the memory array 8120L2, and the memory array 8120L3 can be used as an L1 cache (also referred to as a level 1 cache), an L2 cache (also referred to as a level 2 cache), and an L3 cache (also referred to as a level 3 cache), respectively. Among the three memory arrays, the memory array 8120L3 has the highest capacity and the lowest access frequency. The memory array 8120L1 has the lowest capacity and the highest access frequency.

Note that in the case where the cache provided in the arithmetic device 8210 is used as the L1 cache, the memory arrays provided in the layer 8220 can each be used as the lower-level cache or the main memory. The main memory has higher capacity and lower access frequency than the cache.

As illustrated in FIG. 23B, a driver circuit 8110L1, a driver circuit 8110L2, and a driver circuit 8110L3 are provided. The driver circuit 8110L1 is connected to the memory array 8120L1 through a connection electrode 8230L1. Similarly, the driver circuit 8110L2 is connected to the memory array 8120L2 through a connection electrode 8230L2, and the driver circuit 8110L3 is connected to the memory array 8120L3 through a connection electrode 8230L3.

Note that although the case where three memory arrays function as caches is described here, the number of memory cell arrays may be one, two, or four or more.

In the case where the memory array 8120L1 is used as a cache, the driver circuit 8110L1 may function as part of the cache interface or the driver circuit 8110L1 may be connected to the cache interface. Similarly, each of the driver circuits 8110L2 and 8110L3 may function as part of the cache interface or be connected thereto.

Although FIGS. 23A and 23B illustrate an example in which one layer 8220 provided with the memory arrays is provided over the arithmetic device 8210, two or more layers 8220 provided with the memory arrays may be provided as illustrated in FIG. 23C.

At least part of this embodiment can be implemented as appropriate in combination with any of the other embodiments described in this specification.

### Embodiment 5

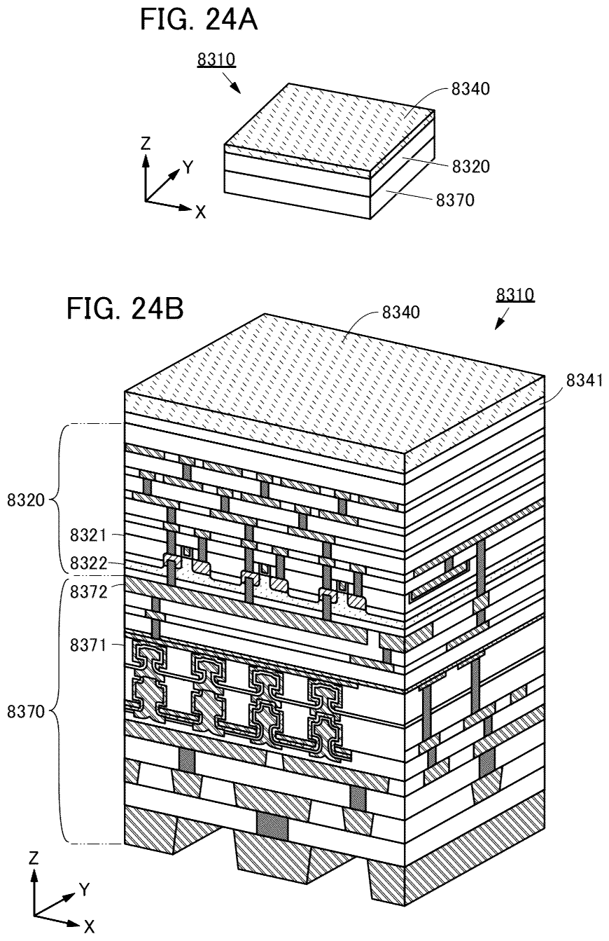

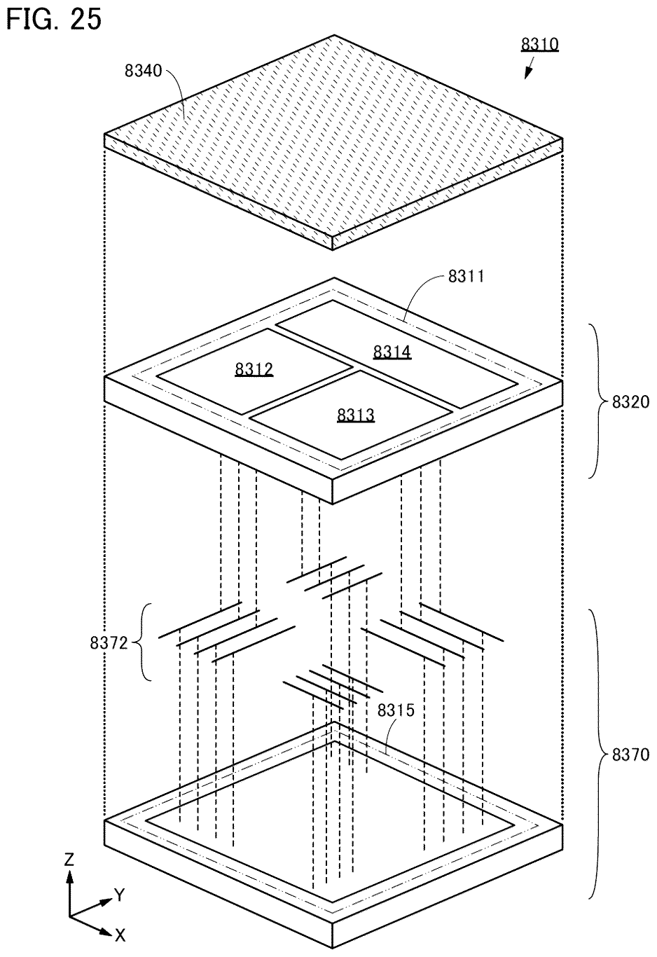

A semiconductor device of one embodiment of the present invention will be described. FIG. 24A is a schematic perspective view of a semiconductor device 8310 of one embodiment of the present invention. FIG. 24B is a schematic perspective view of part of the semiconductor device 8310. FIG. 25 is a schematic perspective view illustrating a structure of the semiconductor device 8310.

In FIGS. 24A and 24B and FIG. 25, the semiconductor device 8310 includes an element layer 8370 under an element layer 8320 including a substrate 8322 that is a semiconductor substrate, and a support substrate 8340 over the element layer 8320 with an insulating layer 8341 therebetween. The element layer 8320 includes a plurality of transistors 8321 included in a functional circuit 8311. The element layer 8370 includes a plurality of transistors 8371 included in a switch circuit 8315. The transistor 8371 functions as a switch for controlling conduction and non-conduction between a line for supplying power from the outside and a conductive layer 8372 functioning as a power supply line.

As the transistor 8371, the transistor described in Embodiment 1 can be used.

The transistor 8321 included in the element layer 8320 is formed on a surface (also referred to as a “first surface”) side of the substrate 8322. The element layer 8370 is formed on the rear surface (also referred to as a surface opposite to the surface or a “second surface”) side of the substrate 8322. Thus, the transistor 8371 included in the element layer 8370 is formed on the second surface side of the substrate 8322.

In FIG. 25, a CPU 8312, a GPU 8313, and a memory 8314 are illustrated as examples of the functional circuit 8311.

Note that the functional circuit 8311 is not limited to the CPU 8312, the GPU 8313, and the memory 8314, and one or more of these can be used. In addition, the functional circuit can include a circuit having other functions.

In order to increase the operation speed and the mounting density and to realize power saving of the semiconductor device 8310, miniaturization and thinning of a transistor, a wiring, and the like and a reduction in power supply potential are required for the functional circuit 8311. The switch circuit 8315 is capable of controlling whether to supply or stop voltage supplied from the outside to each circuit included in the functional circuit 8311. Thus, supply of a power supply potential to a circuit in a standby state can be stopped, so that power consumption can be reduced.

In addition, the transistor included in the switch circuit 8315 is required to have high withstand voltage. One of effective ways of increasing the withstand voltage of the transistor is to increase the thickness of a gate insulating film. In this manner, the transistor 8321 and the transistor 8371 are required to have different performances. Thus, different measures for improving the characteristics are required for the transistor 8321 and the transistor 8371.

Furthermore, the functional circuit 8311 is required to be miniaturized and thinned. Thus, when the switch circuit 8315 is formed with the same process node as the functional circuit 8311, not only a lead wiring but also a wiring for supplying power (power supply line) is thin, so that sufficient power cannot be supplied to the functional circuit 8311. When the wiring resistance increases because of miniaturization, a power supply potential is likely to be uneven in the functional circuit 8311 due to a voltage drop. To stably supply power to the functional circuit 8311, the wiring included in the switch circuit 8315 preferably has a lower wiring resistance than the wiring included in the functional circuit 8311. In particular, the wiring functioning as a power supply line preferably has a lower wiring resistance than the wiring included in the functional circuit 8311. One of effective ways of reducing the wiring resistance is to increase the cross-sectional area of a conductive layer functioning as a wiring. Note that in order to increase the cross-sectional area of the conductive layer, it is necessary to increase one or both of the width and the height of the conductive layer. In view of the above, different process nodes are suitably used for the functional circuit 8311 and the switch circuit 8315.

In the semiconductor device 8310 of one embodiment of the present invention, the functional circuit 8311 and the switch circuit 8315 are provided in different element layers, whereby different improvement measures can be taken for the functional circuit 8311 and the switch circuit 8315. The functional circuit 8311 and the switch circuit 8315 can be formed with different process nodes.

In one embodiment of the present invention, a plurality of conductive layers 8372 functioning as power supply lines and the switch circuit 8315 can be placed under the functional circuit 8311, so that the area occupied by the semiconductor device 8310 can be reduced. The element layer 8370 provided to overlap with the element layer 8320 is preferably formed by a thin film formation technique such as a CVD method or a sputtering method. Thus, the transistor 8371 included in the element layer 8370 is preferably a thin film transistor.

At least some of the plurality of conductive layers 8372 included in the element layer 8370 can function as a power supply line. In the case where the element layer 8370 includes a clock signal generation circuit, at least some of the plurality of conductive layers 8372 can function as a clock signal line. One or both of power supply supplied from the outside and a clock signal can be supplied to the functional circuit 8311 included in the element layer 8320 through at least some of the plurality of conductive layers 8372.

For example, it is possible to manufacture a die (a semiconductor chip) including the functional circuit 8311 and a die including the switch circuit 8315 separately to be mechanically bonded to each other by a three-dimensional integration technique. However, in the three-dimensional integration technique, it is difficult to reduce the pitch of a connection portion due to the difficulty of improving the alignment accuracy because the dies are mechanically bonded to each other and the difficulty of reducing the size of a bump used for connecting the dies, for example. As a result, there is a problem in that the wiring lead distance for supplying power to an intended portion of the functional circuit 8311 is difficult to be shortened.

In one embodiment of the present invention, the element layer 8370 including the switch circuit 8315 is formed on the rear surface side of the substrate 8322 by a thin film formation technique and a photolithography technique, for example. Thus, the semiconductor device 8310 of one embodiment of the present invention is a semiconductor device having a monolithic stacked-layer structure.

When the element layer 8370 is formed with use of a thin film formation technique, alignment with high accuracy at a photolithography level can be achieved. Furthermore, the conductive layer functioning as a power supply line can be connected to an intended portion of the functional circuit 8311 with an extremely short distance. Thus, a required power can be supplied to an intended portion of the functional circuit 8311. In the semiconductor device 8310 of one embodiment of the present invention, the connection distance between the switch circuit 8315 and the functional circuit 8311 is short; thus, power loss due to power transmission is reduced, so that power consumption can be reduced.

At least part of this embodiment can be implemented as appropriate in combination with any of the other embodiments described in this specification.

### Embodiment 6

In this embodiment, application examples of the semiconductor device of one embodiment of the present invention will be described. The semiconductor device of one embodiment of the present invention can include a transistor with high on-state current and a small occupation area; thus, the semiconductor device is suitable for, for example, an electronic component, an electronic device, a large computer, a device for space, and a data center.

### [Electronic Component]

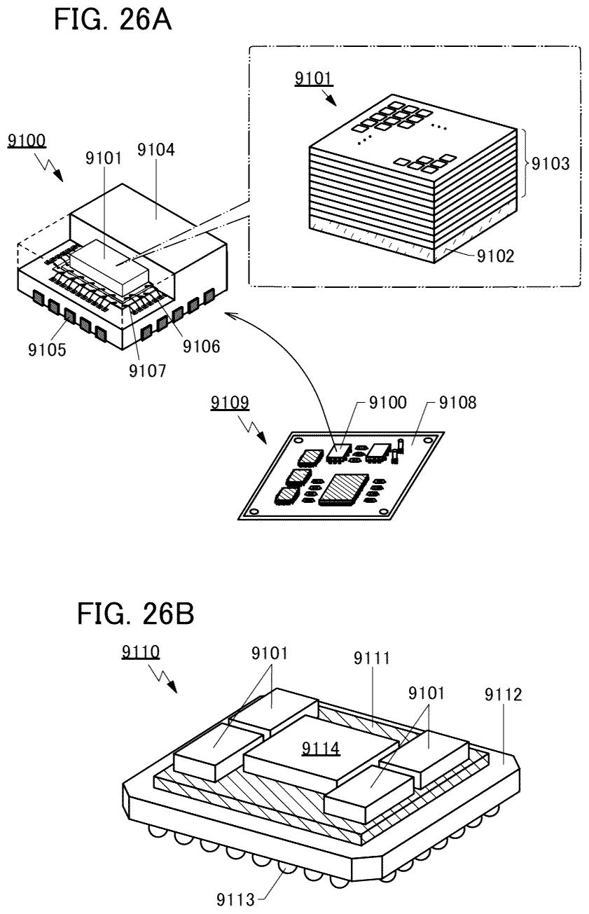

FIG. 26A is a perspective view of a substrate (a circuit board 9109) provided with an electronic component 9100. The electronic component 9100 illustrated in FIG. 26A includes a semiconductor device 9101 in a mold 9104. FIG. 26A omits some components to show the inside of the electronic component 9100. The electronic component 9100 includes a land 9105 outside the mold 9104. The land 9105 is electrically connected to an electrode pad 9106, and the electrode pad 9106 is electrically connected to the semiconductor device 9101 through a wire 9107. The electronic component 9100 is mounted on a printed circuit board 9108, for example. A plurality of such electronic components are combined and electrically connected to each other on the printed circuit board 9108, which forms the circuit board 9109.

The semiconductor device 9101 includes a driver circuit layer 9102 and a memory layer 9103. The memory layer 9103 has a structure where a plurality of memory cell arrays are stacked. A stacked-layer structure of the driver circuit layer 9102 and the memory layer 9103 can be a monolithic stacked-layer structure. In the monolithic stacked-layer structure, layers can be connected to each other without using a through electrode technique such as a through silicon via (TSV) technique and a bonding technique such as Cu-to-Cu direct bonding. Monolithically stacking the driver circuit layer 9102 and the memory layer 9103 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 9103 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 9103 is formed with Si transistors, the monolithic stacked-layer structure is difficult to form compared with the case where the memory layer 9103 is formed with OS transistors. Therefore, an OS transistor is superior to a Si transistor in the monolithic stacked-layer structure.

The semiconductor device 9101 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 26B is a perspective view of an electronic component 9110. The electronic component 9110 is an example of a system in package (SiP) or a multi-chip module (MCM). In the electronic component 9110, an interposer 9111 is provided over a package substrate 9112 (printed circuit board), and a semiconductor device 9114 and a plurality of semiconductor devices 9101 are provided over the interposer 9111.

The electronic component 9110 using the semiconductor device 9101 as a high bandwidth memory (HBM) is illustrated as an example. The semiconductor device 9114 can be used for an integrated circuit such as a CPU, a GPU, or a field programmable gate array (FPGA).

As the package substrate 9112, a ceramic substrate, a plastic substrate, or a glass epoxy substrate can be used, for example. As the interposer 9111, a silicon interposer or a resin interposer can be used, for example.

The interposer 9111 includes a plurality of wirings and has a function of connecting a plurality of integrated circuits with different terminal pitches. The plurality of wirings are provided in a single layer or multiple layers. In addition, the interposer 9111 has a function of connecting an integrated circuit provided on the interposer 9111 to an electrode provided on the package substrate 9112. Accordingly, the interposer is referred to as a “redistribution substrate” or an “intermediate substrate” in some cases. Furthermore, a through electrode is provided in the interposer 9111 and the through electrode is used to connect an integrated circuit and the package substrate 9112 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are connected with use of a silicon interposer, a TSV, and the like, a space for a width of the terminal pitch and the like is needed. Accordingly, in the case where the size of the electronic component 9110 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 9110. In the case of providing a heat sink, the heights of integrated circuits provided on the interposer 9111 are preferably equal to each other. For example, in the electronic component 9110 described in this embodiment, the heights of the semiconductor devices 9101 and 9114 are preferably equal to each other.

To mount the electronic component 9110 on another substrate, an electrode 9113 may be provided on a bottom portion of the package substrate 9112. FIG. 26B illustrates an example where the electrode 9113 is formed of a solder ball. Solder balls are provided in a matrix on the bottom portion of the package substrate 9112, so that ball grid array (BGA) mounting can be achieved. Alternatively, the electrode 9113 may be formed of a conductive pin. When conductive pins are provided in a matrix on the bottom portion of the package substrate 9112, pin grid array (PGA) mounting can be achieved.

The electronic component 9110 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

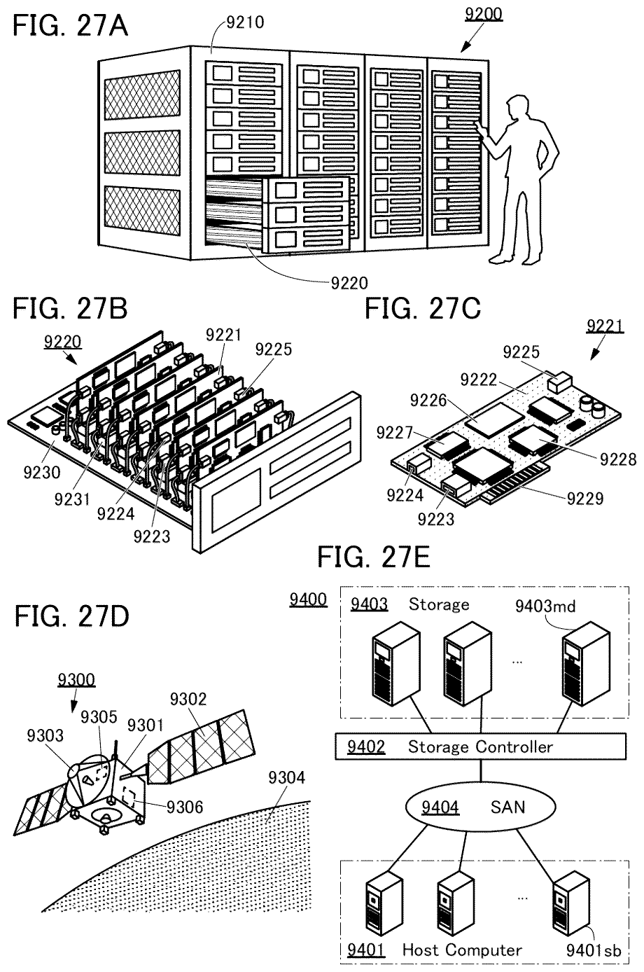

FIG. 27A is a perspective view of a large computer 9200. In the large computer 9200 illustrated in FIG. 27A, a plurality of rack mount computers 9220 are stored in a rack 9210. Note that the large computer 9200 may be referred to as a supercomputer.

The computer 9220 can have a structure illustrated in a perspective view in FIG. 27B, for example. In FIG. 27B, the computer 9220 includes a motherboard 9230, and the motherboard 9230 includes a plurality of slots 9231 and a plurality of connection terminals. A PC card 9221 is inserted in the slot 9231. In addition, the PC card 9221 includes a connection terminal 9223, a connection terminal 9224, and a connection terminal 9225, each of which is connected to the motherboard 9230.

The PC card 9221 illustrated in FIG. 27C is an example of a processing board provided with a CPU, a GPU, a memory device, and the like. The PC card 9221 includes a board 9222. The board 9222 includes a connection terminal 9223, a connection terminal 9224, a connection terminal 9225, a semiconductor device 9226, a semiconductor device 9227, a semiconductor device 9228, and a connection terminal 9229. Note that FIG. 27C also illustrates semiconductor devices other than the semiconductor devices 9226, 9227, and 9228, and the following description of the semiconductor devices 9226, 9227, and 9228 can be referred to for these semiconductor devices.

The connection terminal 9229 has a shape with which the connection terminal 9229 can be inserted in the slot 9231 of the motherboard 9230, and the connection terminal 9229 functions as an interface for connecting the PC card 9221 and the motherboard 9230.

The semiconductor device 9226 includes a terminal (not illustrated) for inputting and outputting signals, and when the terminal is inserted in a socket (not illustrated) of the board 9222, the semiconductor device 9226 and the board 9222 can be connected to each other.

Examples of the semiconductor device 9227 include an FPGA, a GPU, and a CPU. As the semiconductor device 9227, the electronic component 9110 can be used, for example.

An example of the semiconductor device 9228 is a memory device or the like. As the semiconductor device 9228, the electronic component 9110 can be used, for example.

The large computer 9200 can also function as a parallel computer. When the large computer 9200 is used as a parallel computer, large-scale computation necessary for artificial intelligence learning and inference can be performed, for example.

### [Device for Space]

The semiconductor device of one embodiment of the present invention can be suitably used as a device for space.

The semiconductor device of one embodiment of the present invention includes an OS transistor. A change in electrical characteristics due to exposure to radiation is smaller in an OS transistor than in a Si transistor. That is, the OS transistor is highly resistant to radiation and thus has high reliability and can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Note that although outer space refers to, for example, space at an altitude greater than or equal to 100 km, outer space described in this specification can include one or more of thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

FIG. 27D illustrates an artificial satellite 9300 as an example of a device for space. The artificial satellite 9300 includes a body 9301, a solar panel 9302, an antenna 9303, a secondary battery 9305, and a control device 9306. In FIG. 27D, a planet 9304 in outer space is illustrated as an example.

Although not illustrated in FIG. 27D, a battery management system (also referred to as BMS) or a battery control circuit may be provided in the secondary battery 9305. The battery management system or the battery control circuit preferably uses the OS transistor, in which case low power consumption and high reliability are achieved even in outer space.

The control device 9306 has a function of controlling the artificial satellite 9300. The control device 9306 is formed with one or more selected from a CPU, a GPU, and a memory device, for example. Note that the semiconductor device including the OS transistor of one embodiment of the present invention is suitably used for the control device 9306.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs setting a storage and a server for retaining a huge amount of data, stable power supply for retaining data, cooling equipment for retaining data, an increase in building size, and the like.

With use of the semiconductor device of one embodiment of the present invention for a storage system in a data center, power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 27E illustrates a storage system that can be used in a data center. A storage system 9400 illustrated in FIG. 27E includes a plurality of servers 9401sb as a host 9401 (indicated as “Host Computer” in the diagram). The storage system 9400 includes a plurality of memory devices 9403md as a storage 9403 (indicated as “Storage” in the diagram). In the illustrated example, the host 9401 and the storage 9403 are connected to each other through a storage area network 9404 (indicated as “SAN” in the diagram) and a storage control circuit 9402 (indicated as “Storage Controller” in the diagram).

The host 9401 corresponds to a computer that accesses data stored in the storage 9403. The host 9401 may be connected to another host 9401 through a network.

The data access speed, i.e., the time taken for storing and outputting data, of the storage 9403 is shortened by using a flash memory, but is still considerably longer than the data access speed of a DRAM that can be used as a cache memory in a storage. In the storage system, in order to solve the problem of low access speed of the storage 9403, a cache memory is normally provided in the storage to shorten the time taken for data storage and output.

The above-described cache memory is used in the storage control circuit 9402 and the storage 9403. The data transmitted between the host 9401 and the storage 9403 is stored in the cache memories in the storage control circuit 9402 and the storage 9403 and then output to the host 9401 or the storage 9403.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

At least part of this embodiment can be implemented as appropriate in combination with any of the other embodiments described in this specification.

### Example 1

In this example, a device of one embodiment of the present invention was fabricated and its structure and the like were evaluated.

### <Fabrication of Semiconductor Device (S-1 and T-1)>

The structure illustrated in FIG. 3A was fabricated by a method described below. In the fabricated structure, the insulating layer 140 was omitted, and the conductive layer 110 and the insulating layer 180 were provided over the substrate 101. Samples formed here are referred to as Sample S-1 and Sample T-1.

First, the conductive layer 110 was formed over the substrate 101. A silicon wafer was used as the substrate 101. As the conductive layer 110, a tungsten layer was formed to a thickness of 20 nm by a sputtering method.

Next, as the insulating layer 180a, a silicon nitride layer was formed to a thickness of 5 nm over the substrate 101 and the conductive layer 110 by an ALD method. Then, as the insulating layer 180b, a silicon oxide layer was formed to a thickness of 80 nm by a sputtering method. Subsequently, as the insulating layer 180c, a silicon nitride layer was formed to a thickness of 10 nm by a sputtering method.

Next, an opening portion was formed in the insulating layers 180c, 180b, and 180a with use of a resist mask. In the formation of the opening portion, dry etching using a mixed gas of CH₂F₂, O₂, CHF₃, CF₄, and Ar was mainly performed. The resist mask can be removed in a process of the dry etching treatment and the following O₂ ashing treatment.

Next, in Sample S-1, etching treatment was performed on the insulating layer 180b using a buffered hydrofluoric acid solution. As the buffered hydrofluoric acid solution, an aqueous solution in which 6.7 wt % of ammonium hydrogen fluoride and 12.7 wt % of ammonium fluoride were mixed was used. By the etching treatment, the insulating layer 180b is recessed, so that the opening portion 190 having narrow upper and lower portions as illustrated in FIG. 3A can be formed. Sample T-1 was not subjected to the etching treatment.

Next, a conductive film to be the conductive layer 115 was formed in the opening portion in the insulating layer 180 and over the insulating layer 180. As the conductive film, a titanium nitride film was formed to a thickness of 6 nm by a metal CVD method. Then, an aluminum oxide film was formed over the conductive film to be the conductive layer 115. A hard mask can be formed by processing the aluminum oxide film.

Next, the aluminum oxide film was processed using a resist mask to form an aluminum oxide layer. Then, the conductive film to be the conductive layer 115 was processed using the aluminum oxide layer as a mask, so that the conductive layer 115 was formed. The conductive film to be the conductive layer 115 was processed by dry etching. Next, the aluminum oxide layer was removed. Here, as illustrated in FIG. 1D, the conductive layer 115 also covers part of the top surface of the insulating layer 180.

Next, the insulating layer 130 was formed. The insulating layer 130 had a three-layer stacked structure of an aluminum oxide layer formed to a thickness of 1 nm by an ALD method, a silicon oxide layer formed to a thickness of 4 nm over the aluminum oxide layer by an ALD method, and a hafnium oxide layer formed to a thickness of 2 nm over the silicon oxide layer by an ALD method.

Next, a titanium nitride film was formed to a thickness of 5 nm by a metal CVD method as a conductive film to be the conductive layer 120a, and a tungsten film was formed to a thickness of 100 nm by a metal CVD method as a conductive film to be the conductive layer 120b.

Then, a silicon oxynitride layer was formed to a thickness of 100 nm. Next, with use of the silicon oxynitride layer as a sacrificial layer, the top surface of the conductive film to be the conductive layer 120b was planarized by CMP. Subsequently, the conductive layer 120b and the conductive layer 120a were formed using a resist mask. Through the above process, Sample S-1 and Sample T-1 were formed.

### <Cross-Sectional Observation>

The formed samples were thinned by a focused ion beam (FIB) and each of the cross sections was observed by scanning transmission electron microscopy (STEM). The STEM observation was performed at an acceleration voltage of 200 kV using a scanning transmission electron microscope HD-2300 manufactured by Hitachi High-Technologies Corporation.

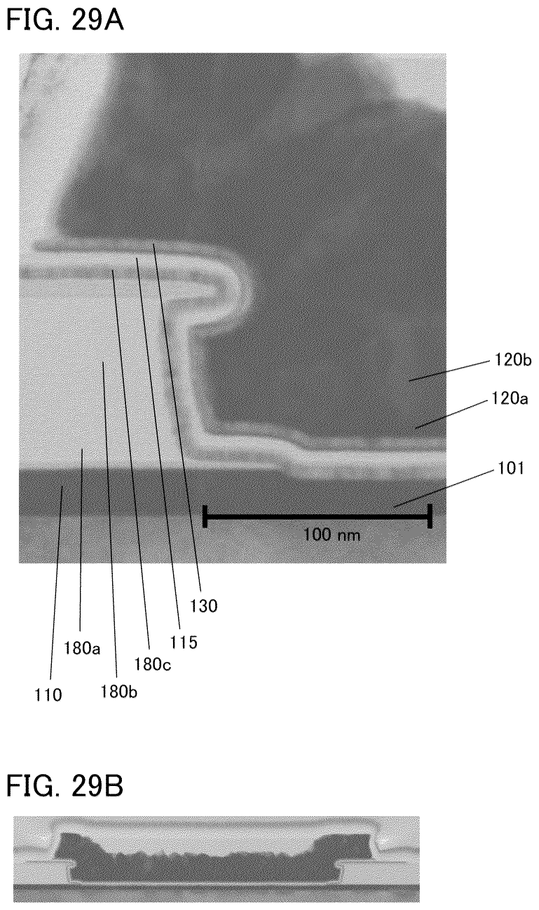

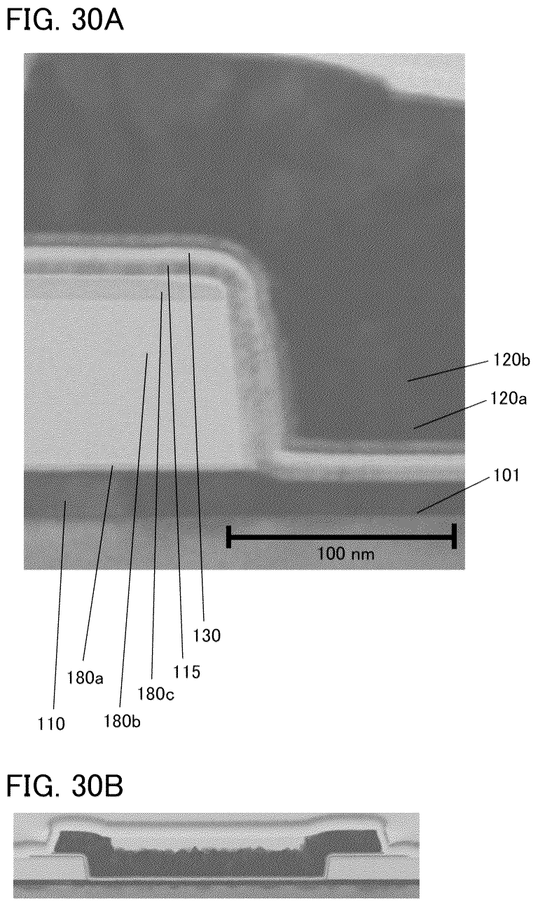

FIG. 29A shows a cross-sectional STEM image of Sample S-1, and FIG. 30A shows a cross-sectional STEM image of Sample T-1. FIG. 29A and FIG. 30A are each a transmission electron image (TE image) at a magnification of 150000 times.

The observation was performed on the cross section of the opening portion having a width of approximately 1 μm. FIG. 29B and FIG. 30B show the observation results of the portions in FIG. 29A and FIG. 30A, respectively at a lower magnification.

In the observation of Sample S-1, the upper portion and the lower portion of the opening portion in the insulating layer 180 were narrowed. Furthermore, the conductive layer 115 and the insulating layer 130 favorably covered the protruding portion of the upper portion and the protruding portion of the lower portion of the insulating layer 180.

### Example 2

In this example, a semiconductor device of one embodiment of the present invention was fabricated and its structure and the like were evaluated.

### <Fabrication of Semiconductor Device (S-2)>

Part of the structure illustrated in FIGS. 17A and 17B and the like was fabricated by a method described below. In the fabricated structure, the conductive layer 240a was not formed. The sample formed here is referred to as Sample S-2.

First, the conductive layer 220 was formed over the substrate 101. A silicon wafer was used as the substrate 101. The conductive layer 220 had a stacked-layer structure of a titanium nitride layer (the conductive layer 220a) formed to a thickness of 5 nm by a sputtering method and a tungsten layer (the conductive layer 220b) formed to a thickness of 20 nm over the titanium nitride layer by a sputtering method.

Next, as the insulating layer 280a, a silicon nitride layer was formed to a thickness of 5 nm over the substrate 101 and the conductive layer 220 by an ALD method. Then, as the insulating layer 280b, a silicon oxide layer was formed to a thickness of 80 nm by a sputtering method. Subsequently, as the insulating layer 280c, a silicon nitride layer was formed to a thickness of 10 nm by a sputtering method.

Next, an opening portion was formed in the insulating layers 280c, 280b, and 280a with use of a resist mask. In the formation of the opening portion, dry etching using a mixed gas of CH₂F₂, O₂, CHF₃, CF₄, and Ar was mainly performed. The resist mask can be removed in the process of the dry etching treatment and the following O₂ ashing treatment.

Then, etching treatment was performed on the insulating layer 280b using a buffered hydrofluoric acid solution. The insulating layer 280b can be recessed by the etching treatment.

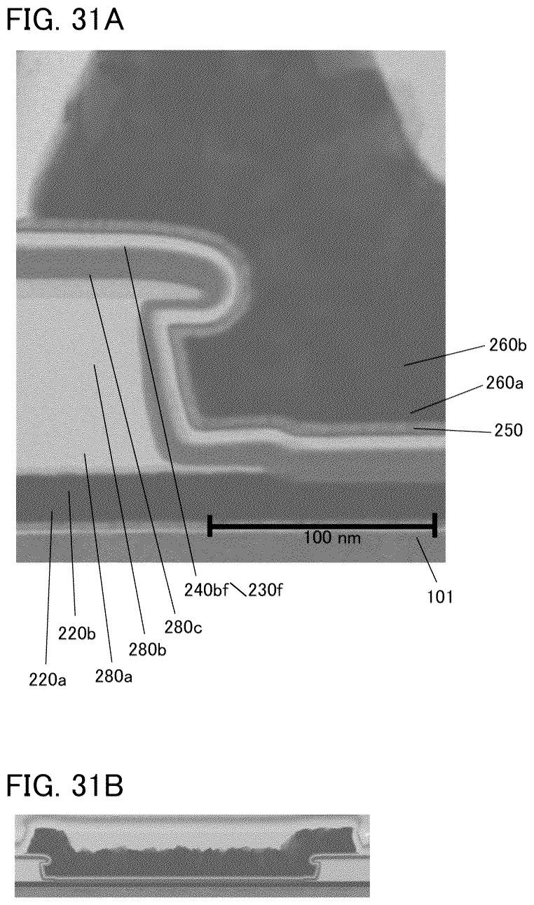

Next, a conductive film to be the conductive layer 240b(denoted as the conductive film 240bf in FIG. 31A referred to below) was formed in the opening portion in the insulating layer 280 and over the insulating layer 280, and then the oxide semiconductor film 230f was formed. As the conductive film, an indium tin oxide layer containing silicon was formed to a thickness of 5 nm by a sputtering method. As the oxide semiconductor film 230f, a three-layer stacked film of an In—Zn oxide layer formed to a thickness of 2 nm by an ALD method, an In—Sn—Zn oxide layer formed to a thickness of 5 nm over the In—Zn oxide layer by a sputtering method, and an In—Zn oxide layer formed to a thickness of 3 nm over the In—Sn—Zn oxide layer by an ALD method was formed. The first and third In—Zn oxide layers were formed to have an atomic ratio of In:Zn=2:1. The second In—Sn—Zn oxide layer was formed using a target with an atomic ratio of In:Sn:Zn=4:0.1:1.

Here, if the conductive film to be the conductive layer 240b and the oxide semiconductor film 230f are subjected to patterning, the conductive layer 240b and the oxide semiconductor layer 230 can be formed; however, the patterning was omitted in this example.

Next, the insulating layer 250 was formed. The insulating layer 250 had a three-layer stacked structure of an aluminum oxide layer formed to a thickness of 1 nm by an ALD method, a silicon oxide layer formed to a thickness of 4 nm over the aluminum oxide layer by an ALD method, and a hafnium oxide layer formed to a thickness of 2 nm over the silicon oxide layer by an ALD method.

Then, a titanium nitride film was formed to a thickness of 5 nm by a metal CVD method as a conductive film to be the conductive layer 260a, and a tungsten film was formed to a thickness of 100 nm by a metal CVD method as a conductive film to be the conductive layer 260b.

Next, a silicon oxynitride layer was formed to a thickness of 100 nm. Then, with use of the silicon oxynitride layer as a sacrificial layer, the top surface of the conductive film to be the conductive layer 260b was planarized by CMP. Subsequently, the conductive layer 260b and the conductive layer 260a were formed using a resist mask. Through the above process, Sample S-2 was formed.

### <Cross-Sectional Observation>

The fabricated sample was thinned by a focused ion beam (FIB) and the cross section was observed by scanning transmission electron microscopy (STEM). The STEM observation was performed at an acceleration voltage of 200 kV using a scanning transmission electron microscope HD-2300 manufactured by Hitachi High-Technologies Corporation.

FIG. 31A shows a cross-sectional STEM image of Sample S-2. FIG. 31A is a transmission electron image (TE image) at a magnification of 150000 times.

The observation was performed on the cross section of the opening portion having a width of approximately 1 μm. FIG. 31B shows the observation result of the portion shown in FIG. 31A at a lower magnification.

In the observation of Sample S-2, the upper portion and the lower portion of the opening portion in the insulating layer 280 were narrowed. Furthermore, the oxide semiconductor film 230f favorably covered the protruding portion of the upper portion and the protruding portion of the lower portion of the insulating layer 280. This is probably because an ALD method that provides good coverage was used as a film formation method of the oxide semiconductor film 230f. Meanwhile, it is suggested that the conductive film 240bf was extremely thin or was not formed in the opening portion in the insulating layer 280b. This is probably because a highly anisotropic sputtering method was used as a film formation method of the conductive film 240bf.

### Example 3

In this example, a semiconductor device of one embodiment of the present invention was fabricated and its structure and the like were evaluated.

### <Fabrication of Semiconductor Device (S-3)>

Part of the structure illustrated in FIGS. 17A and 17B and the like was fabricated by a method described below. The sample formed here is referred to as Sample S-3.

First, the insulating layer 210 was formed over the substrate 101, and the conductive layer 220 was formed over the insulating layer 210. A silicon wafer was used as the substrate 101. As the insulating layer 210, a silicon oxide layer was formed to a thickness of 100 nm by thermal oxidation of the silicon wafer. The conductive layer 220 had a stacked-layer structure of a titanium nitride layer (the conductive layer 220a) formed to a thickness of 5 nm by a sputtering method and a tungsten layer (the conductive layer 220b) formed to a thickness of 20 nm over the titanium nitride layer by a sputtering method.

Next, as the insulating layer 280a, a silicon nitride layer was formed to a thickness of 5 nm by an ALD method over the substrate 101, the insulating layer 210, and the conductive layer 220. Then, as the insulating layer 280b, a silicon oxide layer was formed to a thickness of 80 nm by a sputtering method. Subsequently, as the insulating layer 280c, a silicon nitride layer was formed to a thickness of 10 nm by a sputtering method.

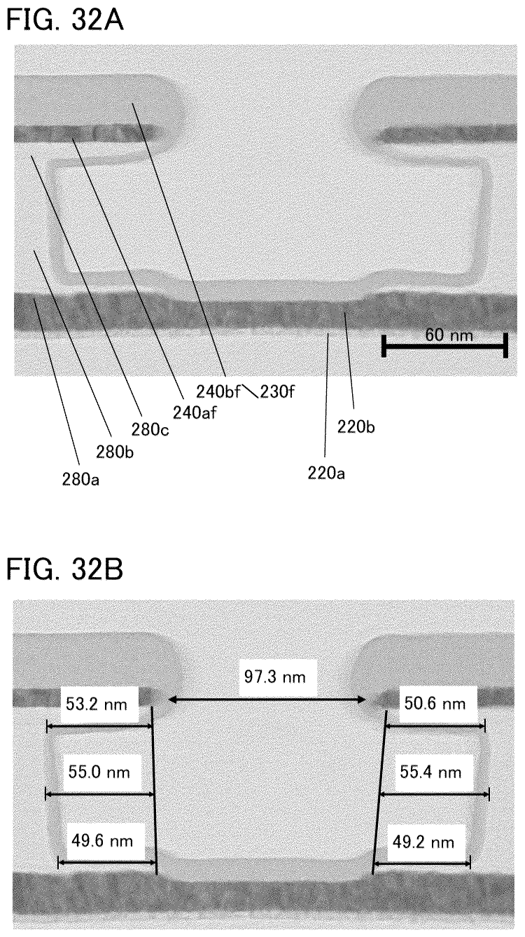

Next, as a conductive film to be the conductive layer 240a(denoted as the conductive film 240af in FIG. 32A referred to below), a tungsten film was formed to a thickness of 10 nm by a sputtering method.

Then, an opening portion was formed in the conductive film to be the conductive layer 240a and the insulating layers 280c, 280b, and 280a with use of a mask layer having a three-layer structure of a spin on carbon (SOC) layer, a spin on glass (SOG) layer over the SOC layer, and a resist layer over the SOG layer. In the formation of the opening portion in the conductive film to be the conductive layer 240, dry etching using a mixed gas of Cl₂, O₂, and CF₄ was performed. In the formation of the opening portion in the insulating layer 280, dry etching using a mixed gas of CH₂F₂, 02, CHF₃, CF₄, and Ar was mainly performed. The mask layer can be removed in the process of the dry etching treatment.

Then, etching treatment was performed on the insulating layer 280b using a buffered hydrofluoric acid solution. The insulating layer 280b can be recessed by the etching treatment.

Next, the conductive film to be the conductive layer 240b(denoted as the conductive film 240bf in FIG. 32A referred to below) was formed in the opening portion in the insulating layer 280, in the opening portion in the conductive film to be the conductive layer 240a, and over the conductive film to be the conductive layer 240a, and then the oxide semiconductor film 230f was formed. As the conductive film to be the conductive layer 240b, an indium tin oxide layer containing silicon was formed to a thickness of 15 nm by a sputtering method. As the oxide semiconductor film 230f, a two-layer stacked film of an In—Zn oxide layer formed to a thickness of 5 nm by an ALD method and an In—Sn—Zn oxide layer formed to a thickness of 5 nm over the In—Zn oxide layer by a sputtering method was used. The first In—Zn oxide layer was formed to have an atomic ratio of In:Zn=4:1. The second In—Sn—Zn oxide layer was formed using a target with an atomic ratio of In:Sn:Zn=4:0.1:1.

Here, if the conductive film to be the conductive layer 240b, the conductive film to be the conductive layer 240a, and the conductive film to be the oxide semiconductor film 230f are subjected to patterning, the conductive layer 240b, the conductive layer 240a, and the oxide semiconductor layer 230 can be formed; however, the patterning was omitted in this example.

Through the above process, Sample S-3 was formed.

### <Cross-Sectional Observation>

The formed sample was thinned by a focused ion beam (FIB) and the cross section was observed by scanning transmission electron microscopy (STEM). The STEM observation was performed at an acceleration voltage of 200 kV using a scanning transmission electron microscope HD-2700 manufactured by Hitachi High-Technologies Corporation.

FIG. 32A shows a cross-sectional STEM image of Sample S-3. FIG. 32A is a transmission electron image (TE image) at a magnification of 500000 times.

The portion subjected to observation is an opening portion in which the upper narrowed portion has a width of approximately 97 nm. Even in the case where the opening portion was minute, the narrowed portions were formed in the upper portion and the lower portion of the opening portion in the insulating layer 280, and the protruding portion of the upper portion and the protruding portion of the lower portion of the insulating layer 280 were favorably covered with the oxide semiconductor film 230f. This is probably because an ALD method that provides good coverage was used as a film formation method of the oxide semiconductor film 230f. Meanwhile, it is suggested that the conductive film 240bf was extremely thin or was not formed in the opening portion in the insulating layer 280b. This is probably because a highly anisotropic sputtering method was used as a film formation method of the conductive film 240bf. The amount of recession of the insulating layer 280b by the etching was measured. FIG. 32B is a diagram where measurement result is added to the STEM image shown in FIG. 32A. The amount of recession in the upper portion of the insulating layer 280b was 53.2 nm (on the left side in the diagram) and 50.6 nm (on the right side in the diagram), the amount of recession at approximately half the height of the insulating layer 280b was 55.0 nm (on the left side in the diagram) and 55.4 nm (on the right side in the diagram), and the amount of recession in the lower portion of the insulating layer 280b was 49.6 nm (on the left side in the diagram) and 49.2 nm (on the right side in the diagram). Accordingly, the width of the opening portion in the insulating layer 280b was able to be approximately twice as large as that of the opening portion in each of the insulating layer 280a and insulating layer 280c.

### Example 4

In this example, a semiconductor device of one embodiment of the present invention was fabricated and its structure and the like were evaluated.

### <Fabrication of Semiconductor Device (S-4)>

Part of the semiconductor device illustrated in FIGS. 9A and 9B was fabricated by a method described below. In the fabricated structure, the oxide semiconductor layer 230 and the conductive layers 240a and 240b were not formed. The sample formed here is referred to as Sample S-4.

First, the conductive layer 220 was formed over the substrate 101. A silicon wafer was used as the substrate 101. The conductive layer 220 had a stacked-layer structure of a titanium nitride layer (the conductive layer 220a) formed to a thickness of 5 nm by a sputtering method, a tungsten layer (the conductive layer 220b) formed to a thickness of 50 nm over the titanium nitride layer by a sputtering method, and an indium tin oxide layer (the conductive layer 220c) formed to a thickness of 20 nm over the tungsten layer by a sputtering method.

Next, the insulating layer 280a was formed over the substrate 101 and the conductive layer 220. The insulating layer 280a had a stacked-layer structure of a silicon nitride layer formed to a thickness of 5 nm by an ALD method and a silicon nitride layer formed to a thickness of 10 nm over the silicon nitride layer by a sputtering method. Then, as the insulating layer 280b, a silicon oxide layer was formed to a thickness of 80 nm by a sputtering method.

Subsequently, heat treatment was performed at 400° C. in a nitrogen atmosphere for one hour.

Next, as the insulating layer 280c, a silicon nitride layer was formed to a thickness of 10 nm by a sputtering method.

Then, an opening portion was formed in the insulating layers 280c, 280b, and 280a with use of a resist mask. In the formation of the opening portion in the insulating layer 280, dry etching using a mixed gas of CH₂F₂, O₂, CHF₃, CF₄, and Ar was mainly performed. The mask layer can be removed in the process of the dry etching treatment.

Next, etching treatment was performed on the insulating layer 280b using a buffered hydrofluoric acid solution. The insulating layer 280b can be recessed by the etching treatment.

Subsequently, the insulating layer 250 was formed in the opening portion in the insulating layer 280 and over the insulating layer 280. The insulating layer 250 had a four-layer stacked structure of an aluminum oxide layer formed to a thickness of 1 nm by an ALD method, a silicon oxide layer formed to a thickness of 2 nm over the aluminum oxide layer by an ALD method, a hafnium oxide layer formed to a thickness of 2 nm over the silicon oxide layer by an ALD method, and a silicon nitride layer formed to a thickness of 1 nm over the hafnium oxide layer by an ALD method.

Next, a titanium nitride film was formed to a thickness of 5 nm by a metal CVD method as the conductive film to be the conductive layer 260a, and a tungsten film was formed to a thickness of 100 nm by a metal CVD method as the conductive film to be the conductive layer 260b.

Subsequently, a silicon oxynitride layer was formed to a thickness of 100 nm. Then, with use of the silicon oxynitride layer as a sacrificial layer, the top surface of the conductive film to be the conductive layer 260b was planarized by CMP. Subsequently, the conductive layers 260b and 260a were formed using a resist mask. Through the above process, Sample S-4 was formed.

### <Cross-Sectional Observation>

The formed sample was thinned by a focused ion beam (FIB) and the cross section was observed by scanning transmission electron microscopy (STEM). The STEM observation was performed at an acceleration voltage of 200 kV using a scanning transmission electron microscope HD-2300 manufactured by Hitachi High-Technologies Corporation.

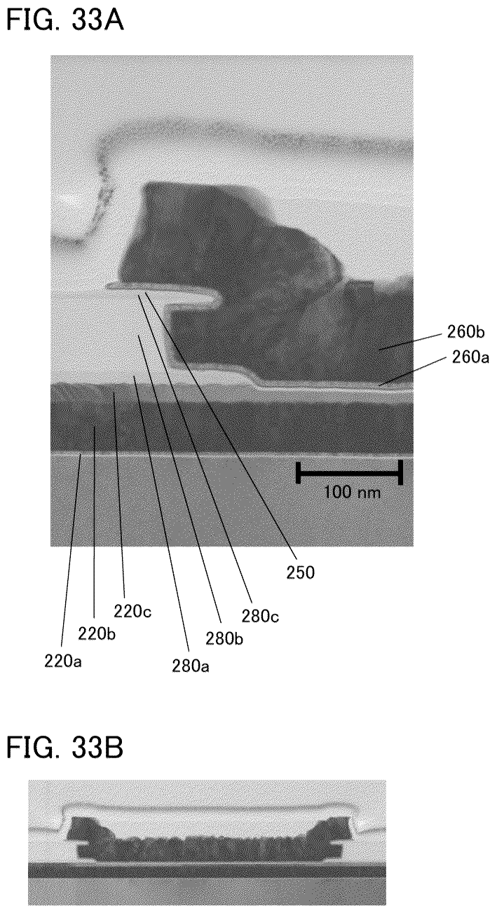

FIG. 33A shows a cross-sectional STEM image of Sample S-4. FIG. 33A is a transmission electron image (TE image) at a magnification of 250000 times.

The observation was performed on the cross section of the opening portion with a width of approximately 1 μm. FIG. 33B shows the observation result at a lower magnification of the portion in FIG. 33A.

In the observation of Sample S-4, the upper portion and the lower portion of the opening portion in the insulating layer 280 were narrowed. Furthermore, a reduction in the thickness of the conductive layer 220c was suppressed and the conductive layer 220c was left even after the formation of the opening portion in the insulating layer 280.

This application is based on Japanese Patent Application Serial No. 2024-184255 filed with Japan Patent Office on Oct. 18, 2024, the entire contents of which are hereby incorporated by reference.

What is claimed is:

1. A device comprising:
a first insulating layer;
a first conductive layer over the first insulating layer;
a second insulating layer over the first insulating layer and the first conductive layer; and
a capacitor over the first conductive layer,
wherein the capacitor comprises a second conductive layer, a third insulating layer, and a third conductive layer,
wherein the second insulating layer comprises an opening portion reaching the first conductive layer and comprising a narrowed upper portion,
wherein the second insulating layer comprises a first portion protruding inward from the opening portion in the upper portion of the opening portion,
wherein the second conductive layer comprises a second portion in contact with a top surface of the first conductive layer, a third portion in contact with a side surface of the opening portion in the second insulating layer, and a fourth portion in contact with a bottom surface of the first portion,
wherein the third insulating layer comprises, in the opening portion, a fifth portion in contact with the third portion of the second conductive layer and a sixth portion in contact with the fourth portion,
wherein the third conductive layer comprises a portion positioned in the opening portion, and
wherein the fifth portion and the sixth portion of the third insulating layer are sandwiched between the second conductive layer and the third conductive layer.

2. The device according to claim 1,
wherein the second insulating layer has a stacked-layer structure of a first layer and a second layer over the first layer,
wherein a width of the opening portion is larger in the first layer than in the second layer, and
wherein the second layer comprises the first portion of the second insulating layer.

3. The device according to claim 2,
wherein the first layer comprises silicon oxide, and
wherein the second layer comprises silicon nitride.

4. The device according to claim 1,
wherein a lower portion of the opening portion is narrowed,
wherein the second insulating layer comprises a seventh portion protruding inward from the opening portion in the lower portion of the opening portion,
wherein the second insulating layer has a stacked-layer structure of a first layer, a second layer over the first layer, and a third layer over the second layer,
wherein a width of the opening portion is larger in the second layer than in the first layer and the third layer,
wherein the third layer comprises the first portion of the second insulating layer, and wherein the first layer comprises the seventh portion of the second insulating layer.

5. The device according to claim 4,
wherein the second layer comprises silicon oxide, and
wherein the first layer and the third layer each comprise silicon nitride.

6. A semiconductor device comprising:
a first insulating layer;
a transistor over the first insulating layer; and
a second insulating layer over the first insulating layer,
wherein the transistor comprises a first conductive layer over the first insulating layer, a semiconductor layer, a second conductive layer over the second insulating layer, a third insulating layer, and a third conductive layer,
wherein the second insulating layer comprises a first opening portion reaching the first conductive layer and comprising a narrowed upper portion and lower portion,
wherein the second conductive layer comprises a second opening portion overlapping with the first opening portion in a plan view,
wherein the second insulating layer comprises a first portion protruding inward from the first opening portion in the upper portion of the first opening portion and a second portion protruding inward from the first opening portion in the lower portion of the first opening portion,
wherein the semiconductor layer comprises a third portion in contact with a top surface of the first conductive layer, a fourth portion in contact with a side surface of the first opening portion in the second insulating layer, a fifth portion in contact with a bottom surface of the first portion, a sixth portion in contact with a top surface of the second portion, and a seventh portion in contact with a side surface of the second opening portion in the second conductive layer,
wherein the third insulating layer comprises a portion in contact with the semiconductor layer in the first opening portion,
wherein the third conductive layer comprises, in the first opening portion, a portion facing the semiconductor layer with the third insulating layer therebetween,
wherein the second conductive layer has a stacked-layer structure of a first layer and a second layer over the first layer,
wherein the first layer comprises one or more of a metal, an alloy of the metal, and a metal nitride, and
wherein the second layer comprises an oxide.

7. The semiconductor device according to claim 6,
wherein the second insulating layer has a stacked-layer structure of a third layer, a fourth layer over the third layer, and a fifth layer over the fourth layer,
wherein a width of the first opening portion is larger in the fourth layer than in the third layer and the fifth layer,
wherein the fifth layer comprises the first portion of the second insulating layer, and
wherein the third layer comprises the second portion of the second insulating layer.

8. The semiconductor device according to claim 7,
wherein the fourth layer comprises silicon oxide, and
wherein the third layer and the fifth layer each comprise silicon nitride.

9. A method for manufacturing a semiconductor device, the method comprising the steps of:
forming a first conductive layer over a first insulating layer;
forming a second insulating layer, a third insulating layer, and a fourth insulating layer sequentially over the first insulating layer and the first conductive layer;
forming a second conductive layer over the fourth insulating layer;
forming an opening portion reaching the first conductive layer with use of first etching treatment in the second conductive layer, the fourth insulating layer, the third insulating layer, and the second insulating layer;
performing etching of the third insulating layer with use of second etching treatment such that a width of the opening portion is larger in the third insulating layer than in the second insulating layer and the fourth insulating layer;
forming a semiconductor layer;
forming a fifth insulating layer over the semiconductor layer, and
forming a third conductive layer over the fifth insulating layer,
wherein the first etching treatment is anisotropic, and
wherein the second etching treatment is isotropic.

10. The method for manufacturing the semiconductor device, according to claim 9,
wherein the first etching treatment is dry etching treatment, and
wherein the second etching treatment is wet etching treatment.
